(19) United States
(12) Patent Application Publication
(10) Pub. No.: US 2018/0040358 A1
(43) Pub. Date: Feb. 8, 2018

(54) NONVOLATILE MEMORY

(71) Applicant: KABUSHIKI KAISHA TOSHIBA, Minato-ku (JP)

(72) Inventors: Hiroki NOGUCHI, Yokohama (JP); Shinobu FUJITA, Tokyo (JP)

(73) Assignee: KABUSHIKI KAISHA TOSHIBA, Minato-ku (JP)

(21) Appl. No.: 15/453,626

(22) Filed: Mar. 8, 2017

(30) Foreign Application Priority Data
Aug. 5, 2016 (JP) 2016-155106

(51) Int. Cl. G11C 11/16; H01L 43/08; H01L 27/22

(52) U.S. Cl. CPC G11C 11/161; H01L 27/228; H01L 43/08; G11C 11/1675

(57) ABSTRACT

According to one embodiment, a nonvolatile memory includes a first conductive line including a first portion, a second portion, a third portion between the first and second portions, and a fourth portion between the second and third portions, a first storage element including a first terminal connected to the third portion and a second terminal, a first transistor including a third terminal connected to the second terminal, a fourth terminal, and a first electrode controlling a first current path, a second storage element including a fifth terminal connected to the fourth portion and a sixth terminal, and a second transistor including a seventh terminal connected to the sixth terminal, an eighth terminal, and a second electrode controlling a second current path.

### CROSS-REFERENCE TO RELATED APPLICATIONS

This application is based upon and claims the benefit of priority from Japanese Patent Application No. 2016-155106, filed Aug. 5, 2016, the entire contents of which are incorporated herein by reference.

### FIELD

Embodiments described herein relate generally to a nonvolatile memory.

### BACKGROUND

Currently, cash memories and main memories used in various systems are mainly volatile memories such as a static random access memory (SRAM) and a dynamic random access memory (DRAM). However, they have a problem that power consumption is large. Thus, an attempt of replacing the volatile memories used in various systems and, furthermore, storage memories with high-speed and low-power nonvolatile RAM has been reviewed.

### BRIEF DESCRIPTION OF THE DRAWINGS

FIG. 1 is a diagram showing an example of a memory system.

FIG. 2 is a diagram showing an example of the memory system.

FIG. 3 is a diagram showing an example of the memory system.

FIG. 4 is a diagram showing a summary of sequential access and random access.

FIG. 5 is a table showing a status of a nonvolatile RAM at sequential/random access.

FIG. 6 is a diagram showing an example of an I/O width (bit width) inside the nonvolatile RAM.

FIG. 7 is a diagram showing an example of SOT-MRAM.

FIG. 8 is a diagram showing an example of an equivalent circuit of a sub-array.

FIG. 9 is an illustration showing an example of a device structure of a cell unit.

FIG. 10 is an illustration showing an example of the device structure of the cell unit.

FIG. 11 is an illustration showing an example of the device structure of the cell unit.

FIG. 12 is an illustration showing an example of a device structure of a memory cell.

FIG. 13 is an illustration showing an example of the device structure of the memory cell.

FIG. 14 is an illustration showing an example of the device structure of the memory cell.

FIG. 15 is a diagram showing an example of a word line decoder/driver.

FIG. 16A is a diagram showing an example of a read/write circuit.

FIG. 16B is a diagram showing an example of the read/write circuit.

FIG. 17 is a diagram showing an example of a sense circuit.

FIG. 18A is an illustration showing an example of a (first) write operation of multi-bit access.

FIG. 18B is an illustration showing an example of a (first) write operation of the multi-bit access.

FIG. 19A is an illustration showing an example of a (second) write operation of the multi-bit access.

FIG. 19B is an illustration showing an example of a (second) write operation of the multi-bit access.

FIG. 20A is an illustration showing an example of a (first) write operation of single-bit access.

FIG. 20B is an illustration showing an example of a (first) write operation of the single-bit access.

FIG. 21A is an illustration showing an example of a (second) write operation of the single-bit access.

FIG. 21B is an illustration showing an example of a (second) write operation of the single-bit access.

FIG. 22 is an illustration showing an example of a read operation of the multi-bit access.

FIG. 23 is an illustration showing an example of a read operation of the single-bit access.

FIG. 24 is a diagram simply showing SOT-MRAM of FIG. 7.

FIG. 25 is a diagram showing a modified example of SOT-MRAM of FIG. 24.

FIG. 26 is a diagram showing a modified example of SOT-MRAM of FIG. 24.

FIG. 27 is a diagram showing a modified example of SOT-MRAM of FIG. 24.

FIG. 28 is a diagram showing a modified example of SOT-MRAM of FIG. 24.

FIG. 29 is a diagram showing an example of a D/S_A driver of FIGS. 27 and 28.

FIG. 30 is a diagram showing an example of a D/S_B driver of FIGS. 27 and 28.

FIG. 31 is a diagram showing an example of a D/S_A sinker of FIGS. 27 and 28.

FIG. 32 is a diagram showing an example of a D/S_B driver of FIGS. 27 and 28.

FIG. 33 is a diagram showing an example of SOT-MRAM.

FIG. 34A is a diagram showing an example of an equivalent circuit of a sub-array.

FIG. 34B is a diagram showing an example of an equivalent circuit of a sub-array.

FIG. 35 is an illustration showing an example of a device structure of a cell unit.

FIG. 36 is an illustration showing an example of the device structure of the cell unit.

FIG. 37 is an illustration showing an example of the device structure of the cell unit.

FIG. 38 is a diagram showing an example of the word line decoder/driver.

FIG. 39 is a diagram showing an example of the read/write circuit.

FIG. 40 is an illustration showing an example of a (first) write operation of the multi-bit access.

FIG. 41 is an illustration showing an example of a (second) write operation of the multi-bit access.

FIG. 42 is an illustration showing an example of a (first) write operation of the single-bit access.

FIG. 43 is an illustration showing an example of a (second) write operation of the single-bit access.

FIG. 44 is an illustration showing an example of a read operation of the multi-bit access.

FIG. 45 is an illustration showing an example of a read operation of the single-bit access.

FIG. 46 is a diagram showing an example of SOT-MRAM.

FIG. 47 is a diagram showing an example of the word line decoder/driver.

FIG. 48 is a diagram showing an example of the sub-decoder/driver.

FIG. 49 is an illustration for comparison of the examples in FIGS. 7, 33 and 46.

FIG. 50 is a diagram simply showing SOT-MRAM of FIG. 33.

FIG. 51 is a diagram showing a modified example of SOT-MRAM of FIG. 50.

FIG. 52 is a diagram showing a modified example of SOT-MRAM of FIG. 50.

FIG. 53 is a diagram showing a modified example of SOT-MRAM of FIG. 50.

FIG. 54 is a diagram showing a modified example of SOT-MRAM of FIG. 50.

### DETAILED DESCRIPTION

In general, according to one embodiment, a nonvolatile memory comprising: a first conductive line extending in a first direction, and including a first portion, a second portion, a third portion provided between the first and second portions, and a fourth portion provided between the second and third portions; a first storage element including a first terminal and a second terminal, the first terminal being connected to the third portion; a first transistor including a third terminal, a fourth terminal, and a first electrode controlling a first current path between the third and fourth terminals, the third terminal being connected to the second terminal; a second storage element including a fifth terminal and a sixth terminal, the fifth terminal being connected to the fourth portion; a second transistor including a seventh terminal, an eighth terminal, and a second electrode controlling a second current path between the seventh and eighth terminals, the seventh terminal being connected to the sixth terminal; a second conductive line extending in the first direction and connected to the first and second electrodes; a third conductive line extending in a second direction crossing to the first direction and connected to the fourth terminal; and a fourth conductive line extending in the second direction and connected to the eighth terminal.

Embodiments will be described hereinafter with reference to the accompanying drawings.

(Memory System)

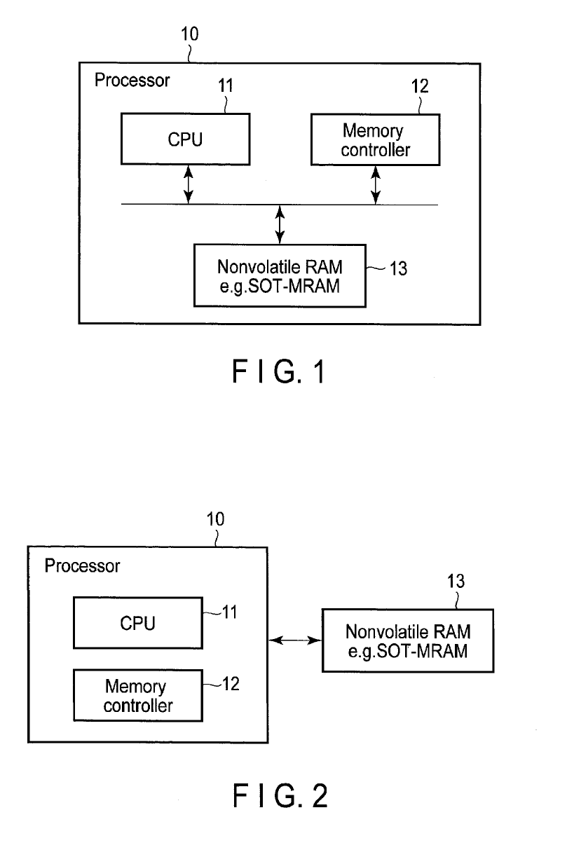

FIGS. 1 to 3 show examples of a memory system.

The memory system to which the embodiments are applied comprises a CPU (host) 11, a memory controller 12 and a nonvolatile RAM 13.

This memory system is employed in, for example, personal computers, electronic devices including cellular telephone terminals, image pickup devices including digital still cameras and video cameras, tablet computers, smartphones, game consoles, car navigation systems, printer devices, scanner devices, server systems and the like.

In the example of FIG. 1, a processor 10 comprises the CPU 11, the memory controller 12, and the nonvolatile RAM 13. In other words, the memory controller 12 and the nonvolatile RAM 13 are embedded in the processor (chip) 10.

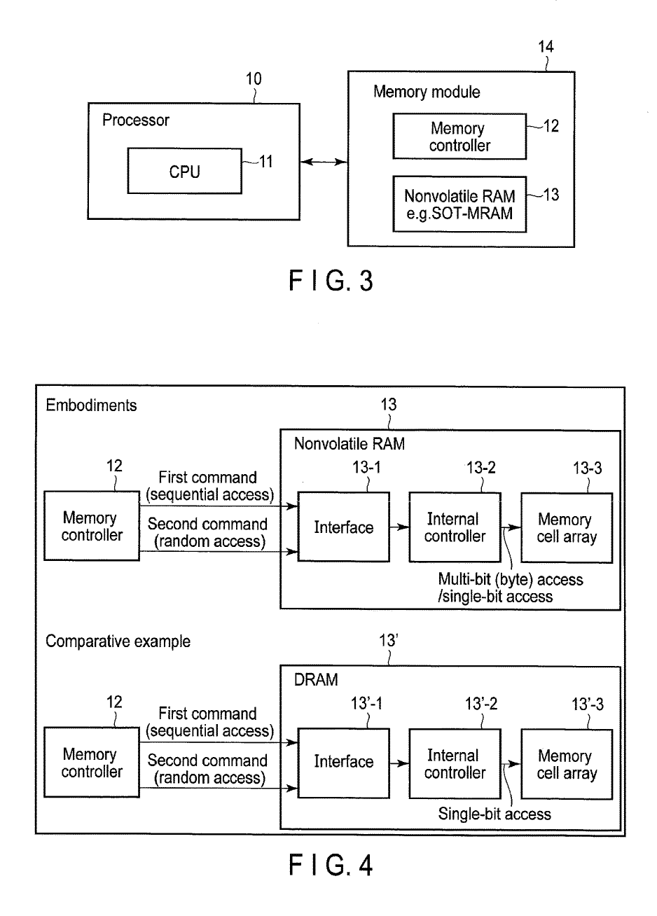

In contrast, in the example of FIG. 2, the processor 10 comprises the CPU 11 and the memory controller 12. In other words, the nonvolatile RAM 13 is provided independently of the processor (chip) 10, as a general chip. In addition, in the example of FIG. 3, the memory controller 12 and the nonvolatile RAM 13 are provided independently of the processor (chip) 10, as general chips. In this case, the memory controller 12 and the nonvolatile RAM 13 are, for example, mounted in a memory module 14.

The CPU 11 comprises, for example, CPU cores. The CPU cores are the elements which can execute different data processing parallel to each other. The memory controller 12 mainly controls a read operation and a write operation for the nonvolatile RAM 13.

The nonvolatile RAM 13 is a memory which can switch a multi-bit access (first mode) and a single-bit access (second mode).

The multi-bit access indicates accessing memory cells in a memory cell array in parallel and the single-bit access indicates accessing one memory cell in the memory cell array.

For example, a spin orbit torque (SOT)-magnetic random access memory (MRAM) is one of memories that can switch the multi-bit access and the single-bit access. The SOT-MRAM will be explained later.

FIG. 4 shows a summary of a sequential access and a random access.

In the memory system shown in FIGS. 1 to 3, the memory controller 12 can issue the first command to execute the sequential access and the second command to execute the random access.

The sequential access is a mode of sequentially accessing (multi-bit) memory cells. For example, burst transfer employed in DRAM, a storage class memory (SCM) and the like is a type of the sequential access.

In the burst transfer, the memory controller 12 can omit, for example, transfer of a column address to the nonvolatile RAM (embodiments) 13 or transfer of a column address to the DRAM (comparative example) 13′ by issuing the first command (burst transfer command). A band width (data amount which can be transferred in a certain period) between the CPU and the memory (nonvolatile RAM or DRAM) can be therefore improved.

The random access is a mode of accessing one (single-bit) memory cell. In the random access, the memory controller 12 issues the second command (random access command) and transfers a row address and a column address to the nonvolatile RAM (embodiments) 13 or the DRAM (comparative example) 13′.

In the random access, latency (i.e., a period from the time when the CPU requests a certain amount of data to the time when the CPU receives the data) is reduced as compared with the sequential access since the data required by the CPU alone is accessed.

Thus, the memory controller 12 issues the first command to instruct the sequential access when the band width is considered with a higher priority or the second command to instruct the random access when the latency is considered with a higher priority.

In the embodiments, the nonvolatile RAM 13 can switch the first mode to execute the multi-bit access and the second mode to execute the single-bit access, in response to the first command and the second command.

For example, when the memory controller 12 issues the first command, the first command is transferred to an internal controller 13-2 via an interface 13-1. When the internal controller 13-2 confirms the first command, the internal controller 13-2 executes the multi-bit access to a memory cell array 13-3.

In addition, when the memory controller 12 issues the second command, the second command is transferred to the internal controller 13-2 via the interface 13-1. When the internal controller 13-2 confirms the second command, the internal controller 13-2 executes the single-bit access to a memory cell array 13-3.

Thus, the multi-bit access is executed inside the nonvolatile RAM 13 when the sequential access is instructed, and the single-bit access is executed inside the nonvolatile RAM 13 when the random access is instructed. An access efficiency inside the nonvolatile RAM 13 can be thereby increased.

In other words, increase in the band width (increase in the data transfer efficiency) can be first obtained as an effect of the sequential access by making the multi-bit access correspond to the sequential access. In addition to this, the time required for the read operation or the write operation is reduced and the access efficiency inside the nonvolatile RAM 13 is increased by executing the multi-bit access inside the nonvolatile RAM 13, in the embodiments.

In contrast, in the comparative example, the DRAM 13′ comprises an interface 13′-1 corresponding to the first command and the second command but an internal controller 13′-2 can only execute the single-bit access.

Therefore, even when the memory controller 12 issues the first command, the internal controller 13′-2 executes the single-bit access to the memory cell array 13′-3. In other words, when the sequential access (access to memory cells) is instructed, the internal controller 13′-2 must repeat access operations (operations of generating the column address and accessing the memory in response to the burst length).

If the sequential access is thus instructed in the comparative example, the time required for the read operation or the write operation is long and the access efficiency inside the DRAM 13′ is degraded since the access operations are executed inside the DRAM 13′.

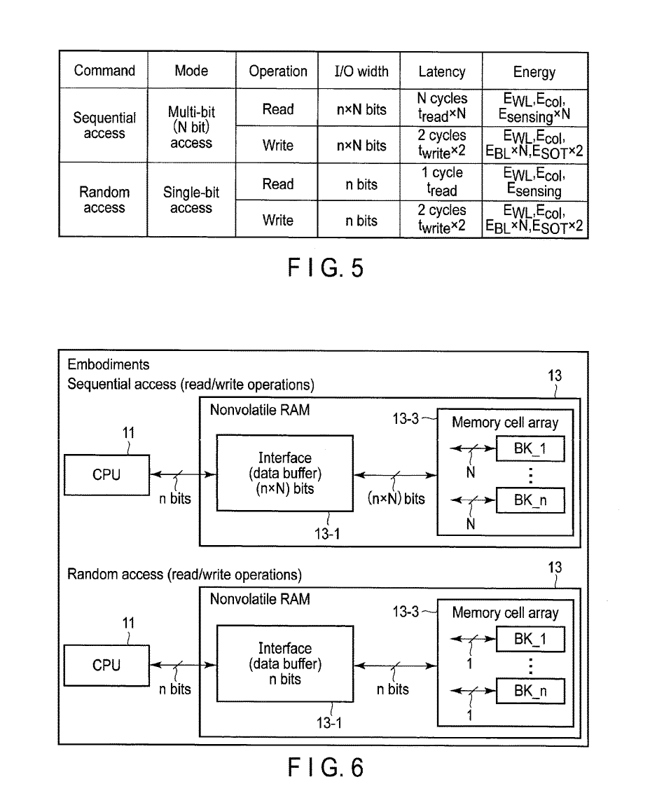

FIG. 5 shows a status of the nonvolatile RAM at sequential/random access.

When the first command to instruct the sequential access is issued, the nonvolatile RAM executes the multi-bit access. The multi-bit access is N-bit access to access N bits (N memory cells) parallel. N is a natural number of 2 or larger. When N is eight, the N-bit access is a byte access.

The I/O width at the N-bit access is, for example, n×N. n is the number of blocks (memory cores) in which the read operation or the write operation can be executed parallel. n is, for example, 64, 128, 256, and the like. The I/O width indicates the data amount which can be transferred between the interface 13-1 and the memory cell array 13-3 within a certain period, inside the nonvolatile RAM.

As shown in FIG. 6, for example, if the memory cell array 13-3 includes n blocks (memory cores) BK_1, . . . BK_n, the interface (data buffer) 13-1 in the nonvolatile RAM 13-1 can latch n×N bits in the read operation at the N-bit access.

In this case, n×N bits are transferred from the memory cell array 13-3 to the interface 13-1 via the internal bus (I/O width=n×N bits) in the read operation. The access efficiency in the nonvolatile RAM 13 is therefore improved in the read operation at the N-bit access.

However, the read operation in each of blocks BK_k (k is one of 1 to n) is executed in, for example, N cycles (N-time read operations). This is because one block BK_k includes one sense amplifier for convenience of layout. Since only one sense amplifier is included in each block BK_k, N cycles are required to read N bits from each block BK_k. This will be explained later.

However, each block BK_k includes, for example, a register and N bits read in N cycles are temporarily stored in the register. For this reason, n×N bits are transferred from the memory cell array 13-3 to the interface 13-1 via the internal bus (I/O width=n×N bits) in the read operation at the N-bit access as explained above.

Latency of the read operation at the N-bit access is t_{read}×N. t_{read} represents the latency in one cycle of the read operation (latency in reading one bit).

In addition, energy generated in the read operation at the N-bit access includes E_{WL}, E_{col}, and E_{sensing}×N. However, E_{WL} represents energy for activating the row (word line), E_{col} represents energy for activating the column (column select line), and E_{sensing} represents energy required to read the data by the sense amplifier.

In addition, as shown in FIG. 6, for example, if the memory cell array 13-3 includes n blocks (memory cores) BK_1, . . . BK_n, the interface (data buffer) 13-1 in the nonvolatile RAM 13-1 can latch n×N bits in the write operation at the N-bit access, too.

In this case, n×N bits are transferred from the interface 13-1 to the memory cell array 13-3 via the internal bus (I/O width=n×N bits) in the write operation. In addition, in each block BK_k (k is one of 1 to n) of the memory cell array 13-3, N bits transferred from the interface 13-1 are temporarily stored in the register. Therefore, in the write operation at the N-bit access, too, the access efficiency in the nonvolatile RAM 13 is improved, similarly to the read operation.

However, the write operation in each of the blocks BK_k is executed in, for example, two cycles (two write operations). This corresponds to a case where the nonvolatile RAM 13 is, for example, an SOT-MRAM.

In SOT-MRAM, for example, the same data (for example, 0) is written to N bits (N memory cells) in each block BK_k, in the first write operation. After this, N bits (N memory cells) in each block BK_k are held or changed as data (0 or 1) corresponding to the write data (N bits transferred from the interface 13-1), in the second write operation. This will be explained later.

The write operation in each block BK_k is executed in two cycles in, for example, SOT-MRAM but, if a nonvolatile memory capable of executing the operation in one cycle or the other cycles exists, the embodiments can also be implemented by using it.

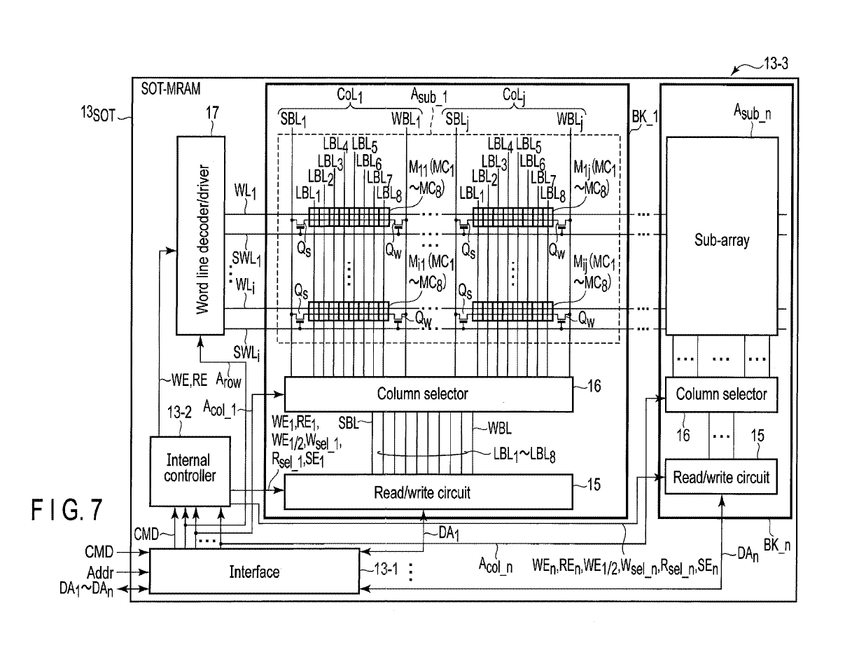

An example of latency and energy of the write operation at the N-bit access will be explained. In this example, the nonvolatile RAM 13 is SOT-MRAM shown in FIG. 7 which will be explained later, and the write operation is completed in two cycles.

The latency of the write operation at the N-bit access is t_{write}×2. However, t_{write} is the latency in one cycle of the write operation.

In addition, the energy generated in the write operation at the N-bit access includes E_{WL}, E_{col}, E_{BL}×N, and E_{SOT}×2. However, E_{WL} represents energy for activating the row (word line), E_{col} represents energy for activating the column (column select line), E_{BL} represents energy required for the voltage assist in SOT-MRAM, and E_{SOT} represents energy required to generate a write current in SOT-MRAM.

The voltage assist and generation of the write current in SOT-MRAM will be explained later.

The important matter is that the I/O width (n×N bits) in the read operation and the I/O width (n×N bits) in the write operation are the same as each other at the N-bit access. Since both the I/O widths are the same as each other, an algorithm in the read operation and an algorithm in the write operation can be partially made common, and control of the read operation and the write operation using the controller in the nonvolatile RAM can be simplified.

In contrast, when the second command to instruct the random access is issued, the nonvolatile RAM executes the single-bit access. The I/O width at the single-bit access is, for example, n.

As shown in FIG. 6, for example, if the memory cell array 13-3 includes n blocks (memory cores) BK_1, . . . BK_n, the interface (data buffer) 13-1 in the nonvolatile RAM 13-1 can latch n bits in the read operation at the single-bit access.

In this case, n bits are transferred from the memory cell array 13-3 to the interface 13-1 via the internal bus (I/O width=n bits) in the read operation. The access efficiency in the nonvolatile RAM 13 is therefore improved in the read operation at the single-bit access.

The latency of the read operation at the single-bit access is t_{read}. In addition, the energy generated in the read operation at the single-bit access includes E_{WL}, E_{col}, and E_{sensing}.

As shown in FIG. 6, for example, if the memory cell array 13-3 includes n blocks (memory cores) BK_1, . . . BK_n, the interface (data buffer) 13-1 in the nonvolatile RAM 13-1 can latch n bits in the write operation at the single-bit access.

In this case, n bits are transferred from the interface 13-1 to the memory cell array 13-3 via the internal bus (I/O width=n bits) in the write operation. In addition, in each block BK_k (k is one of 1 to n) of the memory cell array 13-3, 1 bit transferred from the interface 13-1 is temporarily stored in the register. Therefore, in the write operation at the single-bit access, too, the access efficiency in the nonvolatile RAM 13 is improved, similarly to the read operation.

However, the write operation in each block BK_k is executed in, for example, two cycles (two write operations), similarly to the case of the N-bit access. This corresponds to a case where the nonvolatile RAM 13 is, for example, an SOT-MRAM.

In SOT-MRAM, for example, predetermined data (for example, 0) is written to 1 bit (one memory cell) which is an interest of write, in each block BK_k, in the first write operation. After this, 1 bit (one memory cell) which is the interest of write in each block BK_k, is held or changed as data (0 or 1) corresponding to the write data (1 bit transferred from the interface 13-1), in the second write operation.

N−1 bits other than 1 bit which is an interest of write are masked so as not to be the interest of write in both the first and second write operations. At the single-bit access, for example, 1 bit which is the interest of write and N−1 bits which is to be masked are determined based on the data stored in the register. This will be explained later.

An example of latency and energy of the write operation at the single-bit access in the embodiments will be explained. In this example, the nonvolatile RAM 13 is SOT-MRAM and the write operation is completed in two cycles.

The latency and energy of the write operation at the single-bit access are the same as the latency and energy of the write operation at the N-bit access. The latency of the write operation at the single-bit access is t_{write}×2. In addition, the energy generated in the write operation at the single-bit access includes E_{WL}, E_{col}, E_{BL}×N, and E_{SOT}×2.

The important matter is that the I/O width (n bits) in the read operation and the I/O width (n bits) in the write operation are the same as each other at the single-bit access, too. Since both the I/O widths are the same as each other, an algorithm in the read operation and an algorithm in the write operation can be partially made common, and control of the read operation and the write operation using the controller in the nonvolatile RAM can be simplified.

(SOT-MRAM)

The SOT-MRAM will be explained as a nonvolatile RAM to which the embodiments can be applied.

### First Example

FIG. 7 shows a first example of the SOT-MRAM.

The SOT-MRAM 13_{SOT} comprises an interface 13-1, an internal controller 13-2, a memory cell array 13-3 and a word line decoder/driver 17. The memory cell array 13-3 comprises n blocks (memory cores) BK_1 to BK_n. n is a natural number of 2 or larger.

A command CMD is transferred to the internal controller 13-2 via the interface 13-1. The command CMD includes, for example, a first command to instruct the sequential access and a second command to instruct the random access.

When the internal controller 13-2 receives the command CMD, the internal controller 13-2 outputs, for example, control signals WEₗ, to WEₙ, REₗ to REₙ, WE1/2, Wₛₑₗ_{_}₁ to Wₛₑₗ_{_}ₙ, Rₛₑₗ_{_}₁ to Rₛₑₗ_{_}ₙ, and SE₁ to SEₙ, to execute the command CMD. The meaning and roles of the control signals will be explained later.

An address signal Addr is transferred to the internal controller 13-2 via the interface 13-1. The address signal Addr is divided into a row address A_{row} and column addresses A_{col}_{_}₁ to A_{col}_{_}ₙ in the interface 13-1. The row address A_{row} is transferred to the word line decoder/driver 17. The column addresses A_{col}_{_}₁ to A_{col}_{_}ₙ are transferred to n blocks BK_1 to BK_n.

DA₁ to DAₙ are read data or write data transmitted or received in the read operation or the write operation. The I/O width (bit width) between the interface 13-1 and each of the blocks BK_k (k is one of 1 to n) is N bits at the N-bit access or 1 bit at the single-bit access as explained above.

Each of the blocks BK_k includes a sub-array A_{sub}_{_}ₖ, a read/write circuit 15, and a column selector 16.

The column selector 16 selects one of j columns (j is a natural number of 2 or larger) CoL₁ to CoLⱼ and connects the selected column CoLₚ (p is one of 1 of j) to the read/write circuit 15. If the selected column CoLₚ is CoL₁, for example, conductive lines LBL₁ to LBL₈, SBL₁ and WBL₁ are electrically connected to the read/write circuit 15 via the column selector 16, as conductive lines LBL₁ to LBL₈, SBL and WBL.

The sub-array A_{sub}_{_}ₖ comprises, for example, memory cells M₁₁ (MC₁ to MC₈) to M₁ⱼ (MC₁ to MC₈), and Mᵢ₁ (MC₁ to MC₈) to Mᵢⱼ (MC₁ to MC₈).

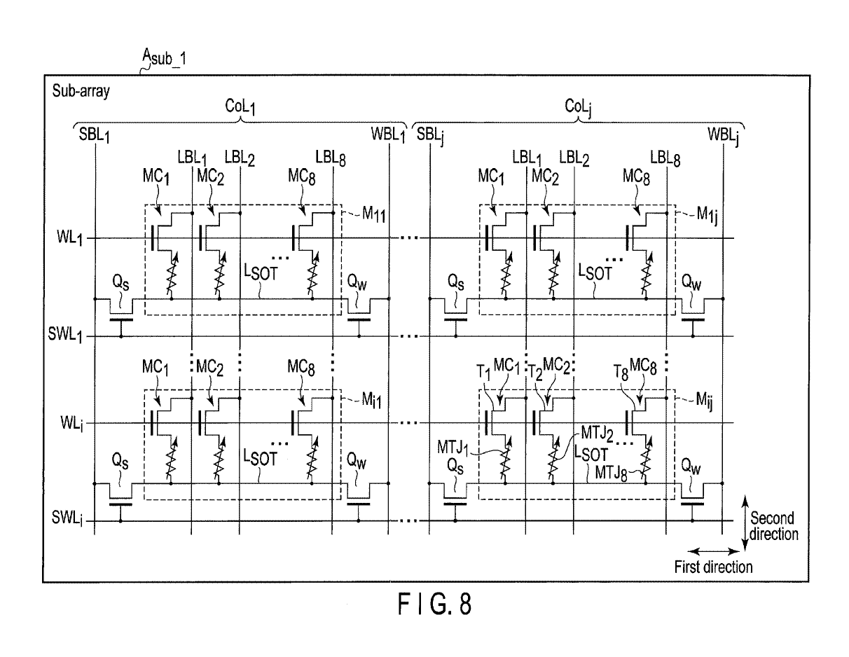

An example of the sub-array A_{sub}_{_}ₖ will be explained with an equivalent circuit of a sub-array A_{sub}_{_}₁ shown in FIG. 8.

M₁₁ (MC₁ to MC₈) to M₁ⱼ (MC₁ to MC₈), Mᵢ₁ (MC₁ to MC₈) to Mᵢⱼ (MC₁ to MC₈), WL₁ to WLᵢ, SWL₁ to SWLᵢ, SBL₁ to SBLⱼ, WBL₁ to WBLⱼ, LBL₁ to LBL₈, Q_{W}, and Q_{S} shown in FIG. 8 correspond to M₁₁ (MC₁ to MC₈) to M₁ⱼ (MC₁ to MC₈), Mᵢ₁ (MC₁ to MC₈) to Mᵢⱼ (MC₁ to MC₈), WL₁ to WLᵢ, SWL₁ to SWLᵢ, SBL₁ to SBLⱼ, WBL₁ to WBLⱼ, LBL₁ to LBL₈, Q_{W}, and Q_{S} shown in FIG. 7, respectively.

Conductive lines L_{SOT} extend in the first direction. The cell unit Mᵢⱼ corresponds to the conductive line L_{SOT} and comprises the memory cells MC₁ to MC₈. The number of memory cells MC₁ to MC₈ corresponds to N of the N-bit access. The number of memory cells MC₁ to MC₈ is eight in the present example but is not limited to this. For example, the number of memory cells MC₁ to MC₈ may be two or larger.

The memory cells MC₁ to MC₈ comprise storage elements MTJ₁ to MTJ₈ and transistors T₁ to T₈, respectively.

Each of the storage elements MTJ₁ to MTJ₈ is a magnetoresistive element. For example, each of the storage elements MTJ₁ to MTJ₈ comprises a first magnetic layer (storage layer) having a variable magnetization direction, a second magnetic layer (reference layer) having an invariable magnetization direction, and a nonmagnetic layer (tunnel barrier layer) between the first and second magnetic layers, and the first magnetic layer is in contact with the conductive line L_{SOT}.

In this case, the conductive line L_{SOT} desirably has the material and the thickness which enable the magnetization direction of the first magnetic layers of the storage elements MTJ₁ to MTJ₈ to be controlled by spin orbit coupling or the Rashba effect. For example, the conductive line L_{SOT} contains tantalum (Ta), tungsten (W), platinum (Pt) and the like and has a thickness in a range of 5 to 20 mm (for example, approximately 10 nm). The conductive line L_{SOT} may be formed in a multilayer structure of two or more layers including a layer of metals such as hafnium (Hf), magnesium (Mg), titanium (Ti) and the like in addition to a layer of the metals such as tantalum (Ta), tungsten (W), platinum (Pt) and the like. Furthermore, the conductive line L_{SOT} may be formed in a multilayer structure of two or more layers including layers formed of single metallic elements of the above but different in crystal structure or a layer in which a single metallic element of the above is oxidized or nitrided.

Each of transistors T₁ to T₈ is, for example, an N-channel field effect transistor (FET). The transistors T₁ to T₈ are desirably so called vertical transistors which are disposed above the semiconductor substrate and in which channels (current paths) intersect the surface of the semiconductor substrate in the vertical direction.

The storage element MTJ_{d} (d is one of 1 to 8) comprises a first terminal (storage layer) and a second terminal (reference layer), and the first terminal is connected to the conductive line L_{SOT}. The transistor Td comprises a third terminal (source/drain), a fourth terminal (source/drain), a channel (current path) between the third and fourth terminals, and a control electrode (gate) which controls occurrence of a channel, and the third terminal is connected to a second terminal.

The conductive lines WL₁ to WLᵢ extend in the first direction and are connected to the control electrodes of the transistors T₁ to T₈. The conductive lines LBL₁ to LBL₈ extend in the second direction intersecting the first direction and are connected to the fourth terminals of the transistors T₁ to T₈, respectively.

Each of the conductive lines L_{SOT} has first and second end portions.

Each of the transistors Q_{S} comprises a channel (current path) connected between the first end portion of the conductive line L_{SOT} and the conductive lines SBL₁ to SBLⱼ, and a control terminal (gate) which controls generation of the channel. Each of the transistors Q_{W} comprises a channel (current path) connected between the second end portion of the conductive line L_{SOT} and the conductive lines SBL₁ to SBLⱼ, and a control terminal (gate) which controls generation of the channel.

The conductive lines SWL₁ to SWLᵢ extend in the first direction and are connected to the control electrodes of the transistors Q_{S} and Q_{W}. The conductive lines SBL₁ to SBLⱼ and WBL₁ to WBLⱼ extend in the second direction.

In the present embodiments, the transistor Q_{S} is connected to the first end portion of the conductive line L_{SOT} and the transistor Q_{W} is connected to the second end portion of the conductive line L_{SOT}, but one of them may be omitted.

According to the present embodiments, the architecture or the layout for putting SOT-MRAM to practical use is implemented. The nonvolatile MRAM which can be used in various systems can be thereby implemented.

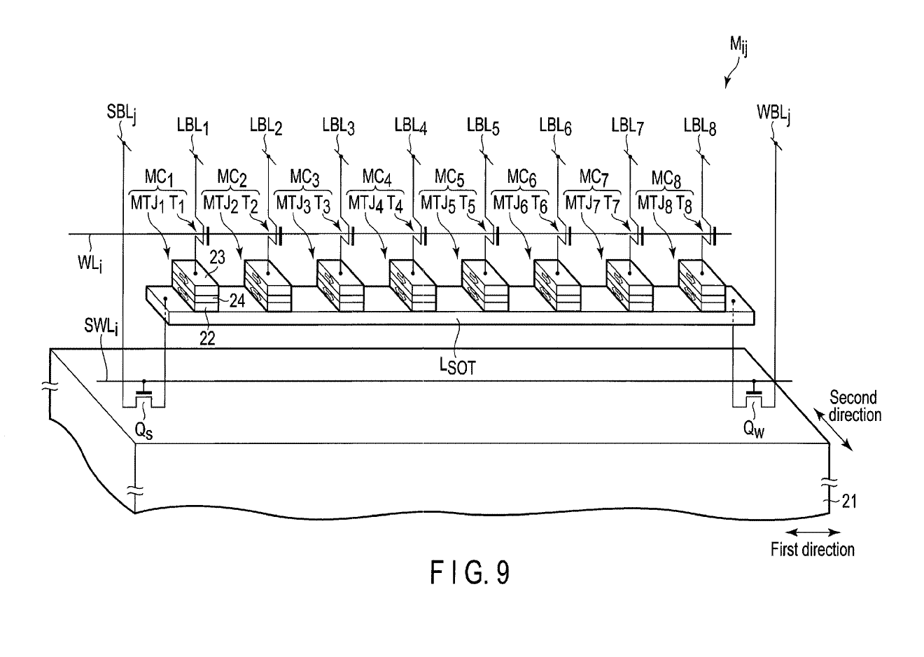

FIGS. 9 to 14 show examples of a device structure of SOT-MRAM.

In these figures, Mᵢⱼ (MC₁ to MC₈, MTJ₁ to MTJ₈, T₁ to T₈), WLᵢ, SWLᵢ, SBLⱼ, WBLⱼ, LBL₁ to LBL₈, Q_{W}, and Q_{S} correspond to M1j (MC₁ to MC₈, MTJ₁ to MTJ₈, T₁ to T₈), WLᵢ, SWLᵢ, SBLⱼ, WBLⱼ, LBL₁ to LBL₈, Q_{W}, and Q_{S} shown in FIGS. 7 and 8, respectively.

In the example shown in FIG. 9, the conductive line L_{SOT} is disposed above the semiconductor substrate 21, and each of the transistors Q_{S} and Q_{W} is disposed as what is called a horizontal transistor (FET) in the surface area of the semiconductor substrate 21. The horizontal transistor is a transistor having a channel (current path) extending along the surface of the semiconductor substrate 11.

The storage elements MTJ₁ to MTJ₈ are disposed on the conductive line L_{SOT} and the transistors T₁ to T₈ are disposed on the storage elements MTJ₁ to MTJ₈, respectively. The transistors T₁ to T₈ are so called vertical transistors. The conductive lines LBL₁ to LBL₈, SBLⱼ and WBLⱼ are disposed on the transistors T₁ to T₈.

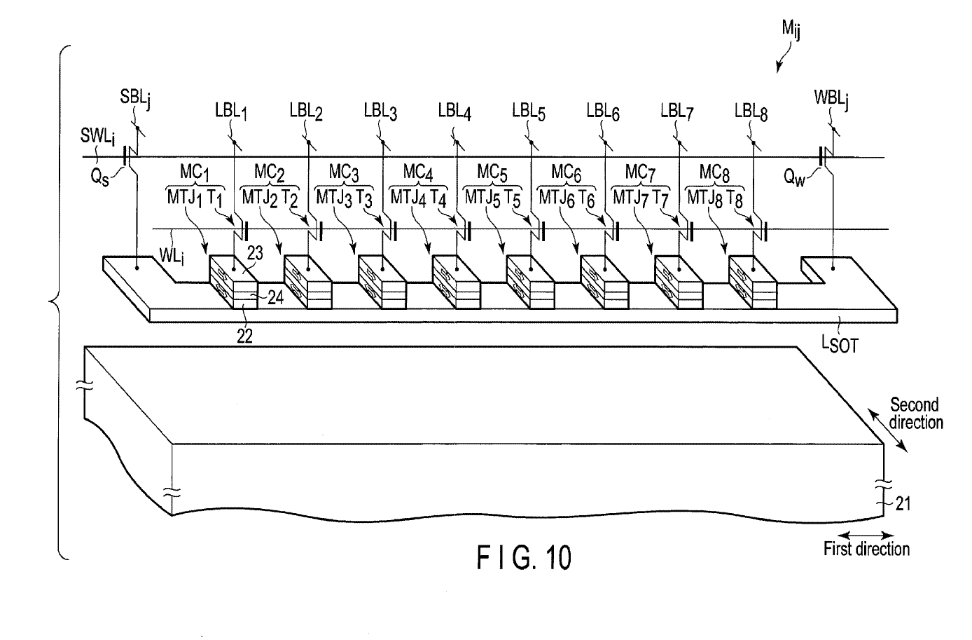

In the example shown in FIG. 10, the conductive line L_{SOT} is disposed above the semiconductor substrate 21, and the transistors Q_{S} and Q_{W} and the storage elements MTJ₁ to MTJ₈ are disposed on the conductive line L_{SOT}. The transistors T₁ to T₈ are disposed on the storage elements MTJ₁ to MTJ₈, respectively. The transistors Q_{S}, Q_{W}, and T₁ to T₈ are so called vertical transistors.

In addition, the conductive lines LBL₁ to LBL₈ are disposed on the transistors T₁ to T₈, and the conductive lines SBLⱼ and WBLⱼ are disposed on the transistors Q_{S} and Q_{W}.

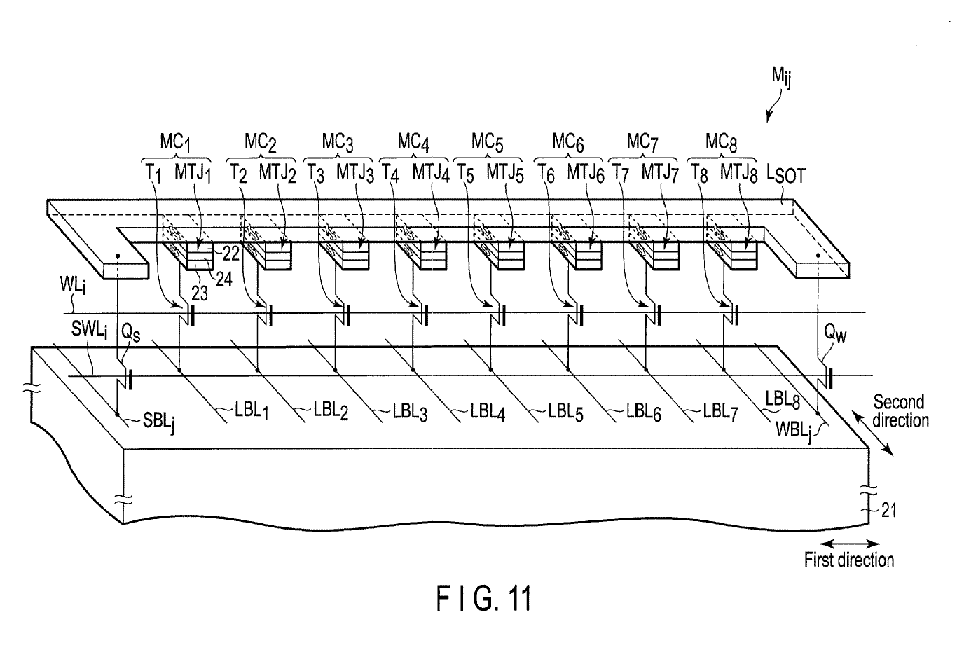

In the example shown in FIG. 11, the conductive lines LBL₁ to LBL₈, SBLⱼ and WBLⱼ are disposed above a semiconductor substrate 21. The transistors T₁ to T₈ are disposed on the conductive lines LBL₁ to LBL₈, and the transistors Q_{S} and Q_{W} are disposed on the conductive lines SBLⱼ and WBLⱼ. The storage elements MTJ₁ to MTJ₈ are disposed on the transistors T₁ to T₈, respectively.

The conductive line L_{SOT} is disposed on the transistors T₁ to T₈, Q_{S} and Q_{W}. The transistors Q_{S}, Q_{W}, and T₁ to T₈ are so called vertical transistors.

In the examples of FIGS. 9 to 11, each of the storage elements MTJ₁ to MTJ₈ comprises a first magnetic layer (storage layer) 22 having a variable magnetization direction, a second magnetic layer (reference layer) 23 having an invariable magnetization direction, and a nonmagnetic layer (tunnel barrier layer) 24 between the first magnetic layer 22 and the second magnetic layer 23, and the first magnetic layer 22 is in contact with the conductive line L_{SOT}.

In addition, each of the first magnetic layer 22 and the second magnetic layer 23 has an easy-axis of magnetization in an in-plane direction along the surface of the semiconductor substrate 21 and in the second direction intersecting the first direction in which the conductive line L_{SOT} extends.

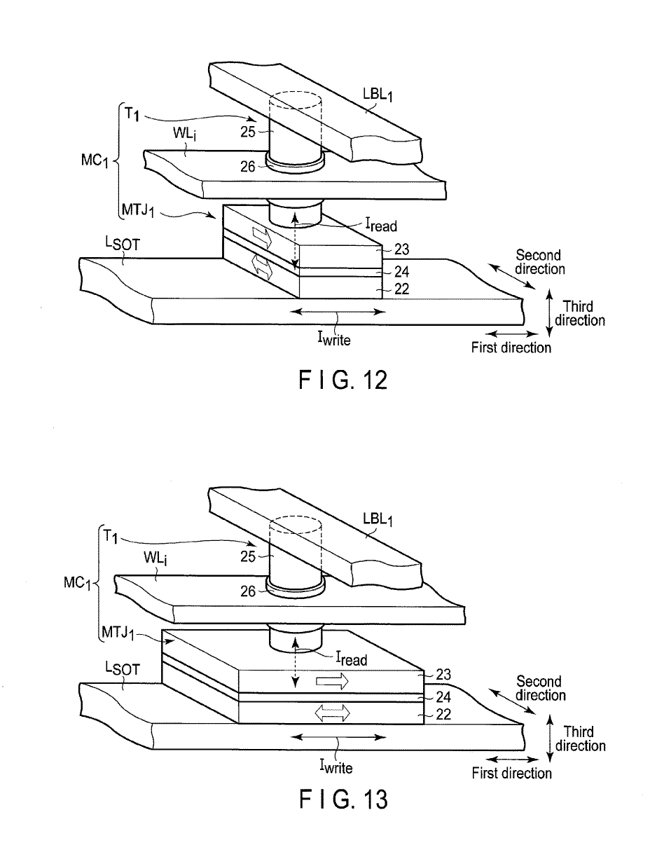

For example, FIG. 12 shows an example of the device structure of the memory cell MC₁ shown in FIGS. 9 and 10. In this example, the transistor T₁ comprises a semiconductor pillar (for example, a silicon pillar) 25 extending in the third direction intersecting the first and second directions, i.e., the direction intersecting the surface of the semiconductor substrate 21, a gate insulating layer (for example, silicon oxide) 26 covering a side surface of the semiconductor pillar 25, and the conductive line WLᵢ covering the semiconductor pillar 25 and the gate insulating layer 26.

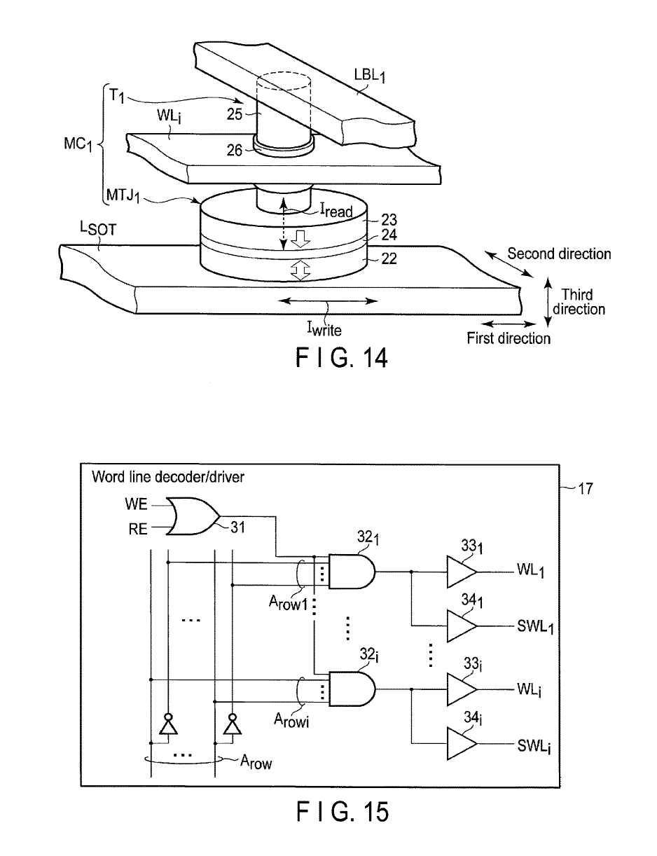

The easy-axis of magnetization of each of the first magnetic layer 22 and the second magnetic layer 23 is the second direction in the example shown in FIG. 12 but may be the first direction as indicated in the example shown in FIG. 13 or the third direction as indicated in the example shown in FIG. 14. The storage element MTJ₁ shown in FIGS. 12 and 13 is called a magnetoresistive element of an in-plane magnetization type, and the storage element MTJ₁ shown in FIG. 14 is called a magnetoresistive element of a vertical magnetization type.

The device structure shown in FIGS. 12 to 14 may be turned upside down to obtain the memory cell MC₁ shown in FIG. 11.

A characteristic of the memory cell MC₁ shown in FIGS. 12 to 14 is that a current path of a read current I_{read} used in the read operation is different from a current path of a write current I_{write} used in the write operation.

For example, the read current I_{read} flows from the conductive line LBL₁ to the conductive line L_{SOT} or from the conductive line L_{SOT} to the conductive line LBL₁ in the read operation. In contrast, the write current I_{write} flows from the right side to the left side or from the left side to the right side inside the conductive line L_{SOT} in the write operation.

In the spin-transfer-torque (STT)-MRAM, the current path of the read current I_{read} used in the read operation is the same as the current path of the write current I_{write} used in the write operation. In this case, margin of the read current I_{read} and the write current I_{write} must be sufficiently secured in consideration of thermal stability Δ and the like to prevent occurrence of the write phenomenon in the read operation.

However, both the read current I_{read} and the write current I_{write} become small due to microminiaturization of a memory cell or the like, and the margin of both the currents can hardly be sufficiently secured.

According to the SOT-MRAM of the present example, since the current path of the read current I_{read} is different from the current path of the write current I_{write}, the margin of both the currents can be sufficiently secured in consideration of thermal stability Δ and the like even if the read current I_{read} and the write current I_{write} become small due to microminiaturization of a memory cell or the like.

FIG. 15 shows an example of the word line decoder/driver shown in FIG. 7.

The word line decoder/driver 17 has a function of activating or deactivating the conductive lines WL₁ to WLᵢ and SWL₁ to SWLᵢ in the read operation or the write operation.

Activation of the conductive lines WL₁ to WLᵢ indicates applying an ON potential to turn on (i.e., to urge the current paths to be generated in) the transistors T₁ to T₈ to the conductive lines WL₁ to WLᵢ. Activation of the conductive lines SWL₁ to SWLᵢ indicates applying an ON potential to turn on (i.e., to urge the current paths to be generated in) the transistors Q_{S} and Q_{W} to the conductive lines SWL₁ to SWLᵢ.

Deactivation of the conductive lines WL₁ to WLᵢ indicates applying an OFF potential to turn off (i.e., to urge no current paths to be generated in) the transistors T₁ to T₈ to the conductive lines WL₁ to WLᵢ. Deactivation of the conductive lines SWL₁ to SWLᵢ indicates applying an OFF potential to turn off (i.e., to urge no current paths to be generated in) the transistors Q_{S} and Q_{W} to the conductive lines SWL₁ to SWLᵢ.

An OR circuit 31 and AND circuits 321 to 32i are decoder circuits.

In the read operation, for example, a read enable signal RE from the internal controller 13-2 shown in FIG. 7 becomes active (1). In the write operation, a write enable signal WE from the internal controller 13-shown in FIG. 7 becomes active (1).

The row address signal A_{row} has, for example, R bits (R is a natural number of 2 or more) and has a relationship i (number of rows)=2^{R}.

In the read operation or the write operation, an output signal of one of the AND circuits 32₁ to 32ᵢ becomes active (1) when the row address signal A_{row} is input to the word line decoder/driver 17. For example, if the row address signal A_{row} is 00 . . . 00 (all 0), the output signal of the AND circuit 32₁ becomes active. If the row address signal A_{row} is 11 . . . 11 (all 1), the output signal of the AND circuit 32ᵢ becomes active.

Drive circuits 33₁ to 33ᵢ and drive circuits 34₁ to 34ᵢ correspond to the AND circuits 32₁ to 32ᵢ, respectively.

If the output signal of the AND circuit 32₁ is active (1), the drive circuit 33₁ outputs the ON potential to the conductive line WL₁ and the drive circuit 34₁ outputs the ON potential to the conductive line SWL₁. If the output signal of the AND circuit 32₁ is nonactive (0), the drive circuit 33₁ outputs the OFF potential to the conductive line WL₁ and the drive circuit 34₁ outputs the OFF potential to the conductive line SWL₁.

Similarly to this, if the output signal of the AND circuit 32ᵢ is active (1), the drive circuit 33ᵢ outputs the ON potential to the conductive line WLᵢ and the drive circuit 34ᵢ outputs the ON potential to the conductive line SWLᵢ. If the output signal of the AND circuit 32ᵢ is nonactive (0), the drive circuit 33ᵢ outputs the OFF potential to the conductive line WLᵢ and the drive circuit 34ᵢ outputs the OFF potential to the conductive line SWLᵢ.

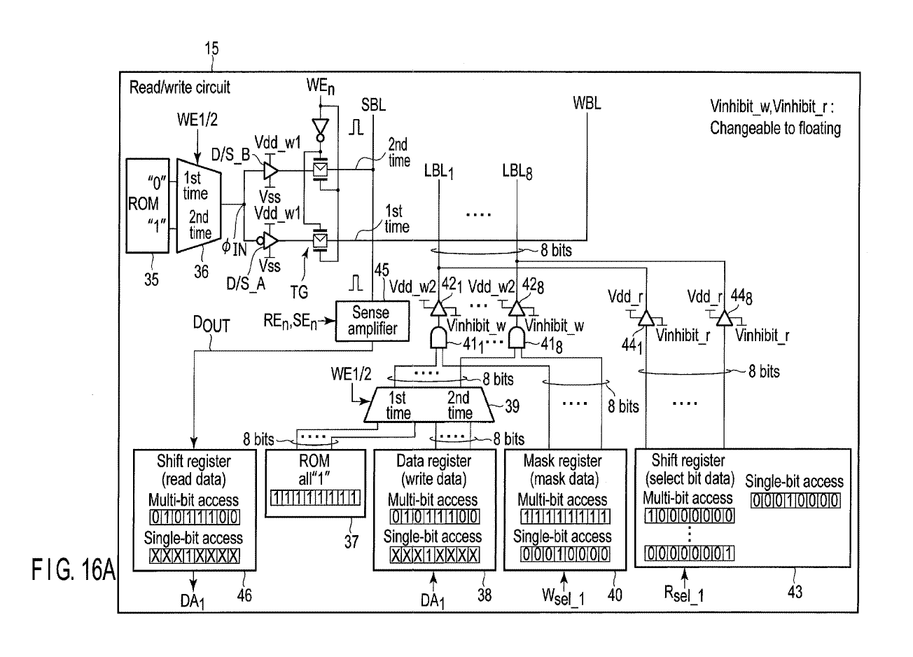

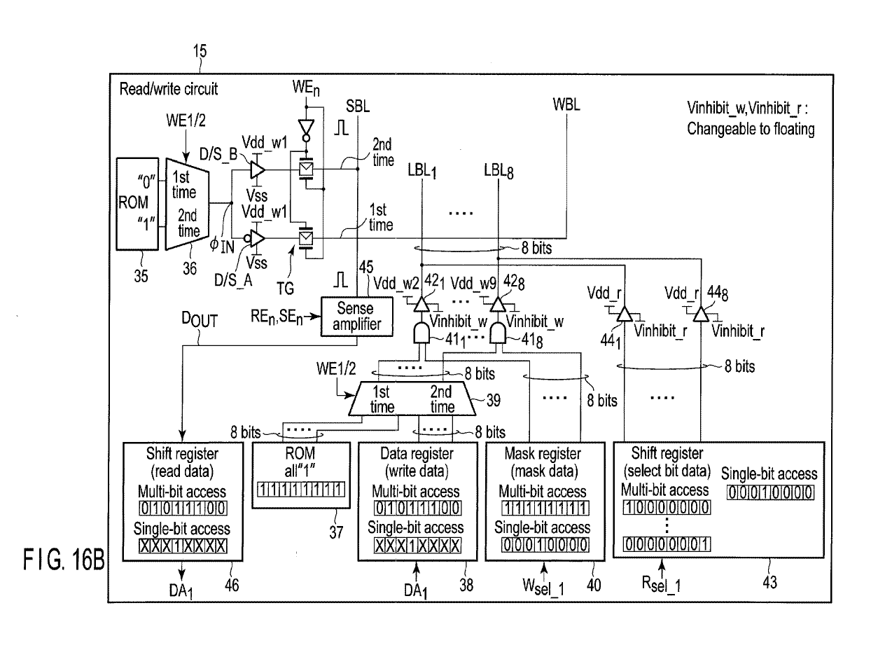

FIG. 16A shows an example of the read/write circuit shown in FIG. 7.

In the read operation or the write operation, the read/write circuit 15 selects one of the multi-bit access and the single-bit access, based on an instruction from the internal controller 13-2 shown in FIG. 7.

The read/write circuit 15 comprises a read circuit and a write circuit.

The write circuit comprises ROMs 35 and 37, selectors (multiplexers) 36 and 39, write drivers/sinkers D/S_A and D/S_B, a transfer gate TG, a data register 38, a mask register 40, AND circuits 41₁ to 41₈, and voltage assist drivers 42₁ to 42₈.

The write drivers/sinkers D/S_A and D/S_B have a function of urging one of a first write current and a second write current in mutually opposite directions to be generated in, for example, the conductive line L_{SOT} shown in FIGS. 9 to 11.

The first write current is a current for, for example, writing 0 to the storage elements MTJ₁ to MTJ₈ shown in FIGS. 9 to 11, i.e., setting a relationship between the magnetization directions of the first magnetic layer 22 and the second magnetic layer 23 of the storage elements MTJ₁ to MTJ₈ shown in FIGS. 9 to 11 to be in a parallel state, by the spin orbit coupling or the Rashba effect.

The second write current is a current for, for example, writing 1 to the storage elements MTJ₁ to MTJ₈ shown in FIGS. 9 to 11, i.e., setting the relationship between the magnetization directions of the first magnetic layer 22 and the second magnetic layer 23 of the storage elements MTJ₁ to MTJ₈ shown in FIGS. 9 to 11 to be in an antiparallel state, by the spin orbit coupling or the Rashba effect.

The voltage assist drivers 42₁ to 42₈ have a function of permitting/inhibiting the 0/1-write operation using the first and second write currents.

For example, when the voltage assist drivers 42₁ to 42₈ permit the 0/1-write operation, the voltage assist drivers 42₁ to 42₈ selectively apply an assist potential V_{dd}_{_}_{W2} for facilitating the 0/1-write operation to, for example, the conductive lines LBL₁ to LBL₈ shown in FIGS. 9 to 11. In this case, since a voltage for destabilizing the magnetization direction of the first magnetic layer (storage layer) 22 shown in FIGS. 9 to 11 is generated in the storage elements MTJ₁ to MTJ₈, the magnetization direction of the first magnetic layer 22 can easily be inversed.

When the voltage assist drivers 42₁ to 42₈ permit the 0/1-write operation as shown in FIG. 16B, the voltage assist drivers 42₁ to 42₈ may selectively apply assist potentials V_{dd}_{_}_{W2} to V_{dd}_{_}_{W9} for facilitating the 0/1-write operation to, for example, the conductive lines LBL₁ to LBL₈ shown in FIGS. 9 to 11, respectively. In other words, the assist potentials applied to the conductive lines LBL₁ to LBL₈ shown in FIGS. 9 to 11 may be different from each other.

When the voltage assist drivers 42₁ to 42₈ inhibit the 0/1-write operation, the voltage assist drivers 42₁ to 42₈ selectively apply an inhibit potential V_{inhibit}_{_}_{W} for urging the 0/1-write operation to be hardly executed to, for example, the conductive lines LBL₁ to LBL₈ shown in FIGS. 9 to 11. In this case, since a voltage for destabilizing the magnetization direction of the first magnetic layer (storage layer) 22 shown in FIGS. 9 to 11 is not generated in the storage elements MTJ₁ to MTJ₈ or since a voltage for stabilizing the magnetization direction of the first magnetic layer 22 is generated in the storage elements MTJ₁ to MTJ₈, the magnetization direction of the first magnetic layer 22 can hardly be inversed.

When the voltage assist drivers 42₁ to 42₈ inhibit the 0/1-write operation, the voltage assist drivers 42₁ to 42₈ may set the conductive lines LBL₁ to LBL₈ to be in a floating state instead of applying the inhibit potential V_{inhibit}_{_}_{W} to the conductive lines LBL₁ to LBL₈.

The read circuit comprises shift registers 43 and 46, read drivers 44₁ to 44₈ and a sense circuit 45.

The read drivers 44₁ to 44₈ have a function of selectively applying, for example, a select potential V_{dd}_{_}ᵣ for urging the read current to be generated to the conductive lines LBL₁ to LBL₈ shown in FIGS. 9 to 11. In this case, since the read current flows from one conductive line LBL_{d} (d is one of 1 to 8) to which the select potential V_{dd}_{_}ᵣ is applied to the conductive line L_{SOT} shown in FIGS. 9 to 11, data is read from the storage element MTJ_{d} which is to be read.

The read drivers 44₁ to 44₈ may apply a nonselect potential V_{inhibit}_{_}ᵣ which does not urge the read current to be generated, to remaining seven conductive lines other than the conductive line LBL_{d}, of the conductive lines LBL₁ to LBL₈ or may set seven conductive lines to be in a floating state instead.

One sense circuit 45 is provided in, for example, one read/write circuit 15. In other words, only one sense circuit 45 is provided in one block (memory core) BK_k.

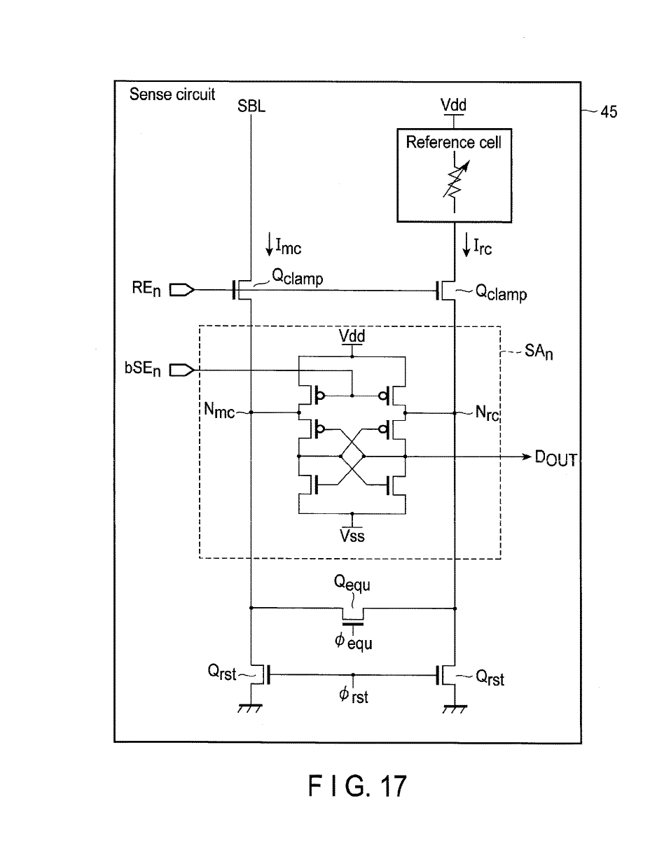

The sense circuit 45 comprises, for example, a sense amplifier SAₙ, a clamp transistor (for example, N-channel FET) Q_{clamp}, an equalizing transistor (for example, N-channel FET) Q_{equ}, and a reset transistor (for example, N-channel FET) Qᵣₛₜ as shown in FIG. 17.

When the control signal REₙ from the internal controller 13-2 shown in FIG. 7 is active (high level), the clamp transistor Q_{clamp} is turned on. In addition, when the control signal REₙ from the internal controller 13-2 shown in FIG. 7 is active (high level), i.e., when the control signal bSEₙ is active (low level), the sense amplifier SAₙ becomes in an operated state.

The sense amplifier SAₙ is a current sense type of comparing a cell current (read current) I_{mc} flowing from the memory cell which is to be read to the conductive line SBL with a reference current I_{rc} flowing to the reference cell, in the present example, but is not limited to this. The sense amplifier SAₙ may adopt, for example, a sense amplifier circuit of a voltage sense type or a self-reference type.

In addition, when the control l signal φₑₐᵤ is active (high level), the equalizing transistor Q_{equ} is turned on and, for example, potentials of two input/output nodes N_{mc} and N_{rc} of the sense amplifier SAₙ are equalized. In addition, when the control signal φᵣₛₜ is active (high level), the reset transistor Qᵣₛₜ is turned on.

Next, an example of the read operation and an example of the write operation using the word line decoder/driver 17 shown in FIG. 15 and the read/write circuit 15 shown in FIG. 16 will be explained.

*Write Operation

[Multi-Bit Access]

When the internal controller 13-2 shown in FIG. 7 receives, for example, the write command CMD of the sequential access, the internal controller 13-2 controls the write operation using the multi-bit access. The internal controller 13-2 executes the write operation using the multi-bit access by the first write operation and the second write operation.

The first write operation is an operation of writing the same data (for example, 0) at multi-bits (for example, 8 bits) which are the interests of write.

First, the write enable signal WE becomes 1 and the output signal of the OR circuit 31 becomes 1 in the word line decoder/driver 17 shown in FIG. 15. For example, if all the bits of the row address signal A_{row} are 1 (11 . . . 11), the output signal of the AND circuit 32i becomes 1. The conductive lines WLᵢ and SWLᵢ are therefore activated by the drivers 33ᵢ and 34₁.

Next, the internal controller 13-2 shown in FIG. 7 sets, for example, the control signal WE1/2 at 0. The control signal WE1/2 is a signal for selecting one of the first write operation and the second write operation and, for example, when the control signal WE1/2 is 0, the first write operation is selected.

In this case, the selector 36 selects and outputs 0 from the ROM 35 as the ROM data, in the read/write circuit 15 shown in FIG. 16A. Therefore, the write driver/sinker D/S_A outputs, for example, the drive potential V_{dd}_{_}_{W1} as the write pulse signal and the write driver/sinker D/S_B outputs, for example, the ground potential Vₛₛ.

In addition, in the write operation, the transfer gate TG is on since the control signal WEₙ becomes active (high level).

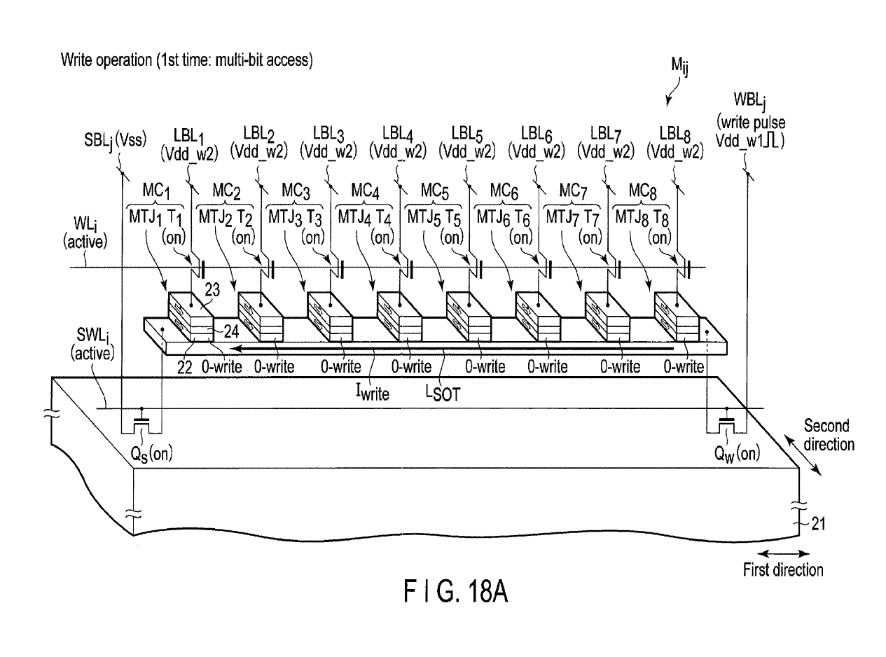

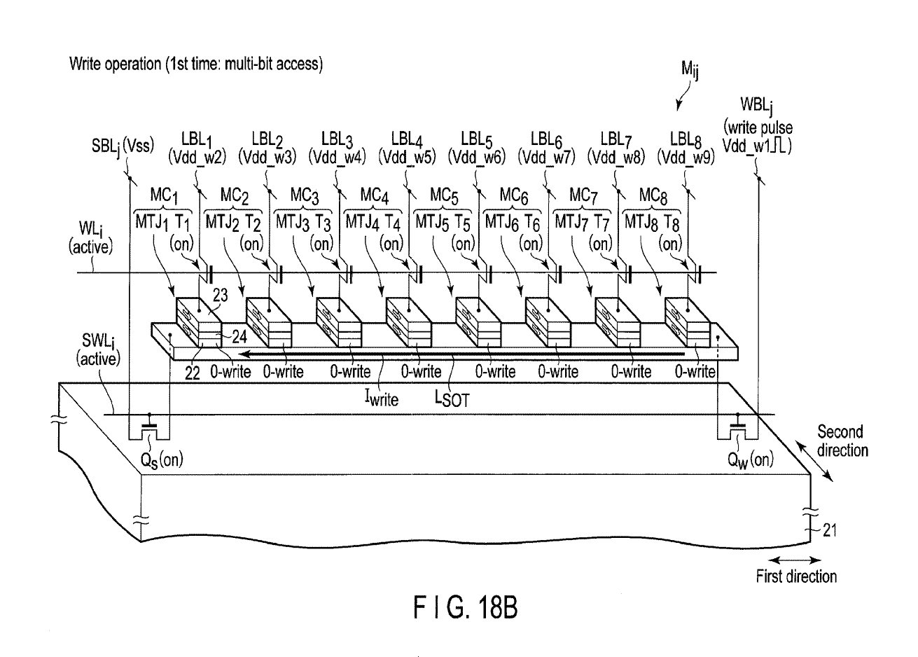

Therefore, the write pulse signal is applied to the conductive line WBL via the transfer gate TG and the ground potential Vₛₛ is applied to the conductive line SBL via the transfer gate TG. At this time, if the column selected by the column selector 16 shown in FIG. 7 is assumed to be CoLⱼ, the write current (first write current) I_{write} flows from the conductive line WBLⱼ to the conductive line SBLⱼ, i.e., from the right side to the left side in the conductive line L_{SOT}, as shown in, for example, FIG. 18A.

In addition, the selector 39 selects and outputs all 1 (11111111) from the ROM 37 as the ROM data, in the read/write circuit 15 shown in FIG. 16A. In addition, the internal controller 13-2 shown in FIG. 7 sets the value of the mask register 40 at all 1 (11111111) by using, for example, the control signal Wₛₑₗ_{_}₁. at the multi-bit access.

All the AND circuits 41₁ to 41₈ therefore output 1 as the output signals. At this time, all the high-voltage assist drivers 42₁ to 42₈ output, for example, the assist potential V_{dd}_{_}_{W2} to the conductive lines LBL₁ to LBL₈.

In other words, for example, the write current (first write current) I_{write} flows from the conductive line WBLⱼ to the conductive line SBLⱼ in a state in which the assist potential V_{dd}_{_}_{W2} is applied to all the conductive lines LBL₁ to LBL₈, as shown in FIG. 18A.

As a result, the same data is written at all the multi-bits (for example, 8 bits) that are the interests of write, in the first write operation. However, it is assumed that 0 is written, i.e., all the storage elements MTJ₁ to MTJ₈ become in a parallel state in the first write operation.

In addition, the assist potentials applied to the respective conductive lines LBL₁ to LBL₈ may be mutually different potentials V_{dd}_{_}_{W2} to V_{dd}_{_}_{W9} by preparing a plurality of (for example, eight) power lines as shown in FIG. 16B and FIG. 18B.

The second write operation is an operation of urging the same data (for example, 0) written at multi-bits (for example, 8 bits) which are the interests of write, to be held (for example, if the write data is 0) or to be changed from 0 to 1 (for example, if the write data is 1) in accordance with the write data.

First, the conductive lines WLᵢ and SWLᵢ are held in the activated state in the word line decoder/driver 17 shown in FIG. 15.

Next, the internal controller 13-2 shown in FIG. 7 sets, for example, the control signal WE1/2 at 1. For example, when the control signal WE1/2 is 1, the second write operation is selected.

In this case, the selector 36 selects and outputs 1 from the ROM 35 as the ROM data, in the read/write circuit 15 shown in FIG. 16A. Therefore, the write driver/sinker D/S_B outputs, for example, the drive potential V_{dd}_{_}_{W1} as the write pulse signal and the write driver/sinker D/S_A outputs, for example, the ground potential Vₛₛ.

The drive potential of the write pulse signal output from the write driver/sinker D/S_A circuit in the first write operation and the drive potential of the write pulse signal output from the write driver/sinker D/S_B in the second write operation may be different drive potentials. In addition, the ground potential of the write pulse signal output from the write driver/sinker D/S_B circuit in the first write operation and the ground potential of the write pulse signal output from the write driver/sinker D/S_B in the second write operation may be different ground potentials.

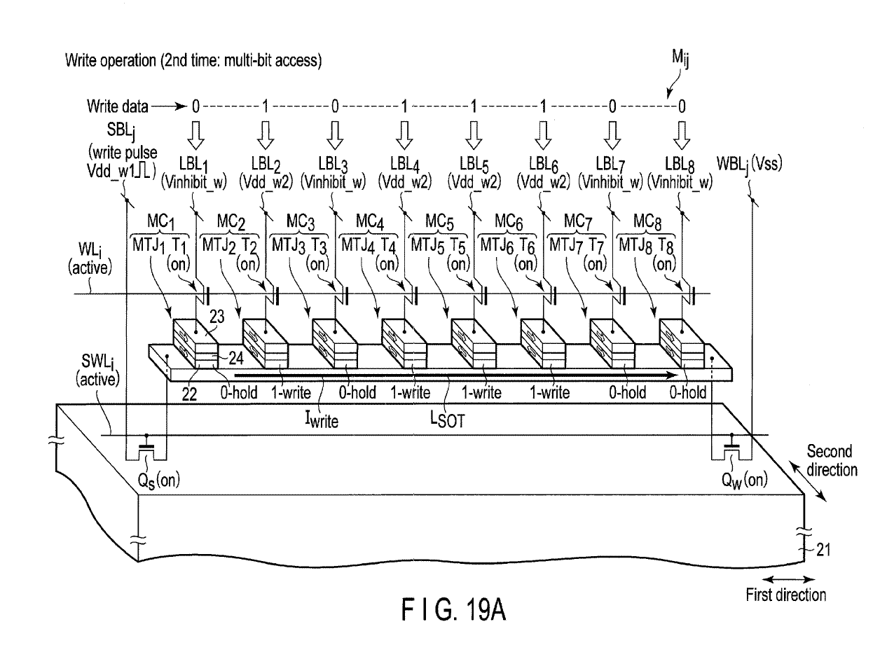

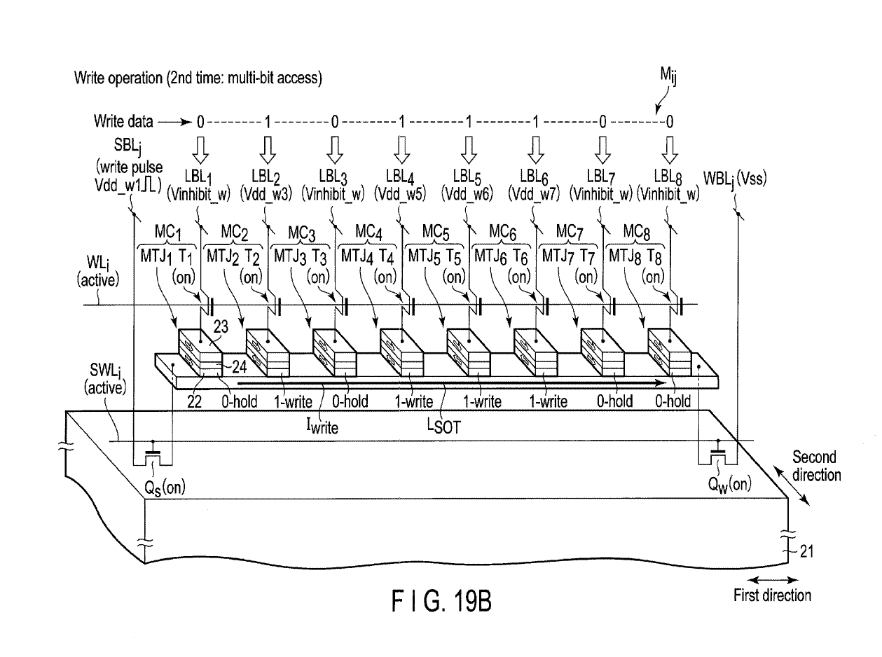

The write pulse signal is applied to the conductive line SBL via the transfer gate TG and the ground potential Vₛₛ is applied to the conductive line WBL via the transfer gate TG. At this time, if the column selected by the column selector 16 shown in FIG. 7 is assumed to be CoLⱼ, the write current (second write current) I_{write} flows from the conductive line SBLⱼ to the conductive line WBLⱼ, i.e., from the right side to the left side in the conductive line L_{SOT}, as shown in, for example, FIG. 19A.

In addition, the selector 39 selects and outputs the write data (for example, 01011100) stored in the data register 38, in the read/write circuit 15 shown in FIG. 16A. The write data is preliminarily stored in the data register 38 before the second write operation is executed. In addition, the internal controller 13-2 shown in FIG. 7 sets the value of the mask register 40 at all 1 (11111111) by using, for example, the control signal Wₛₑₗ_{_}₁, at the multi-bit access.

The AND circuits 41₁ to 41₈ therefore output the output signal (for example, 01011100) corresponding to the write data. At this time, for example, each of the voltage assist drivers 42₁ to 42₈ outputs the assist potential V_{dd}_{_}_{W2} when the write data is 1 or outputs the inhibit potential V_{inhibit}_{_}_{W} when the write data is 0.

In other words, for example, if the write data is 01011100, the write current (second write current) I_{write} flows from the conductive line SBLⱼ to the conductive line WBLⱼ in a state in which the inhibit potential V_{inhibit}_{_}_{W} is applied to the conductive lines LBL₁, LBL₃, LBL₇ and LBL₈ and the assist potential V_{dd}_{_}_{W2} is applied to the conductive lines LBL₂, LBL₄, LBL₅ LBL₆, as shown in FIG. 19A.

As a result, 0 is held, i.e., 0 is written as the data of the storage elements MTJ₁, MTJ₃, MTJ₇ and MTJ₈, of the multi-bits (for example, 8 bits) which are the interests of write, in the second write operation. In addition, 0 is changed to 1, i.e., 1 is written as the data of the storage elements MTJ₂, MTJ₄, MTJ₅ and MTJ₆, of the multi-bits (for example, 8 bits) which are the interests of write.

In addition, the assist potentials applied to the conductive lines LBL₂, LBL₄, LBL₅ and LBL₆ may be V_{dd}_{_}_{W3}, V_{dd}_{_}_{W5}, V_{dd}_{_}_{W6} and V_{dd}_{_}_{W7}, respectively, as shown in FIG. 16B and FIG. 19B. The inhibit potentials V_{inhibit}_{_}_{W} applied to the conductive lines LBL₁, LBL₃, LBL₇ and LBL₈ may also be mutually different potentials. In addition, if the efficiency of the voltage effect of the voltage assist is adequately high, the inhibit potential V_{inhibit} can be replaced with a floating potential.

However, it is assumed that 1 is selectively written to the storage elements MTJ₁ to MTJ₈, i.e., the state of the storage elements MTJ₁ to MTJ₈ is selectively changed from the parallel state to the antiparallel state, in the second write operation.

[Single-Bit Access]

When the internal controller 13-2 shown in FIG. 7 receives, for example, the write command CMD of the random access, the internal controller 13-2 controls the write operation using the single-bit access. The internal controller 13-2 executes the write operation using the single-bit access by the first write operation and the second write operation.

The first write operation is an operation of writing predetermined data (for example, 0) at the single bit which is the interest of write.

First, the output signal of the OR circuit 31 becomes 1 in the word line decoder/driver 17 shown in FIG. 15. For example, if all the bits of the row address signal A_{row} are 1 (11 . . . 11), the output signal of the AND circuit 32i becomes 1. The conductive lines WLᵢ and SWLᵢ are therefore activated by the drivers 33ᵢ and 34ᵢ.

Next, the internal controller 13-2 shown in FIG. 7 sets, for example, the control signal WE1/2 at 0. For example, when the control signal WE1/2 is 0, the first write operation is selected.

In this case, the selector 36 selects and outputs 0 from the ROM 35 as the ROM data, in the read/write circuit 15 shown in FIG. 16A. Therefore, the write driver/sinker D/S_A outputs, for example, the drive potential V_{dd}_{_}_{W1} as the write pulse signal and the write driver/sinker D/S_B outputs, for example, the ground potential Vₛₛ.

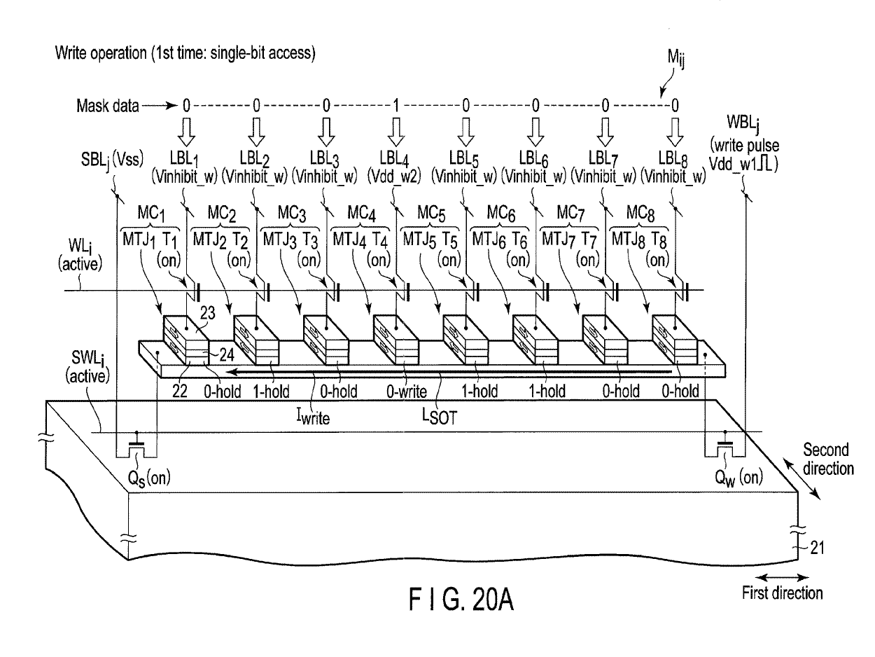

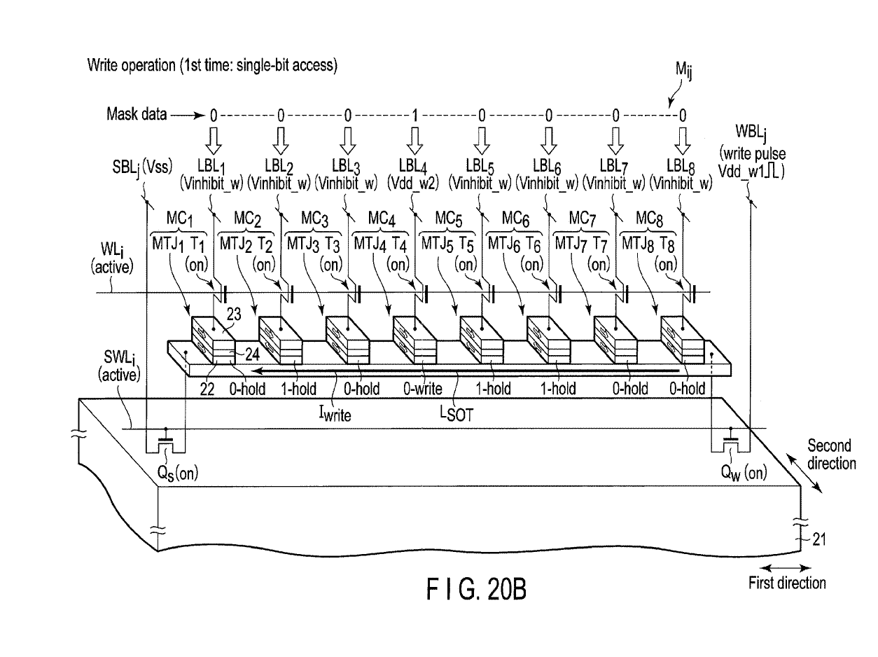

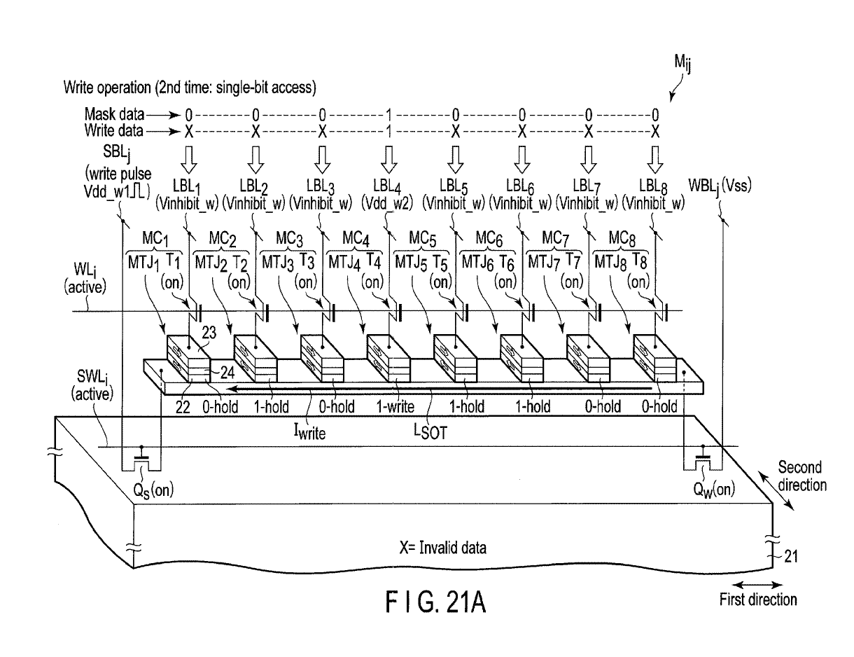

The write pulse signal is applied to the conductive line WBL via the transfer gate TG and the ground potential Vₛₛ is applied to the conductive line SBL via the transfer gate TG. At this time, if the column selected by the column selector 16 shown in FIG. 7 is assumed to be CoLⱼ, the write current (first write current) I_{write} flows from the conductive line WBLⱼ to the conductive line SBLⱼ, i.e., from the right side to the left side in the conductive line L_{SOT}, as shown in, for example, FIG. 20A.

In addition, the selector 39 selects and outputs all 1 (11111111) from the ROM 37 as the ROM data, in the read/write circuit 15 shown in FIG. 16A. In addition, the internal controller 13-2 shown in FIG. 7 sets selected one bit, of eight bits stored in the mask register 40, at 1 by using, for example, the control signal Wₛₑₗ_{_}₁, at the single-bit access.

For example, when the storage element MTJ₄ is an interest of write, 1 bit corresponding to the conductive line LBL₄ connected to the storage element MTJ₄, of 8 bits stored in the mask register 40, is set at 1. In this case, 8 bits stored in the mask register 40 becomes, for example, 00010000.

Therefore, the AND circuit 41₄, of the AND circuits 41₁ to 41₈, outputs 1 as the output signal and the remaining AND circuits 41₁ to 41₃ and 41₅ to 41₈ output 0 as the output signals. At this time, the voltage assist driver 42₄, of the high-voltage assist drivers 42₁ to 42₈ outputs the assist potential V_{dd}_{_}_{W2} to the conductive line LBL₄, and the remaining voltage assist drivers 42₁ to 42₃ and 42₅ to 42₈ output the inhibit potential V_{inhibit}_{_}_{W} to the conductive lines LBL₁ to LBL₃ and LBL₅ to LBL₈.

In other words, for example, the write current (first write current) I_{write} flows from the conductive line WBLⱼ to the conductive line SBL₁ in a state in which the assist potential V_{dd}_{_}_{W2} is applied to the conductive line LBL₄ and the inhibit potential V_{inhibit}_{_}_{W} is applied to the conductive lines LBL₁ to LBL₃ and LBL₅ to LBL₈, as shown in FIG. 20A.

As a result, the single bit which is the interest of write, for example, predetermined data (for example, 0) is written to the storage element MTJ₄, in the first write operation.

In addition, the already written data is held in remaining seven bits that are not the interests of write, for example, the storage elements MTJ₁ to MTJ₃ and MTJ₅ to MTJ₈, by the above mask processing. In other words, the data in the storage elements MTJ₁ to MTJ₃ and MTJ₅ to MTJ₈ is not changed to 0, but the data in the storage elements MTJ₁ to MTJ₃ and MTJ₅ to MTJ₈ is protected, in the first write operation.

As shown in FIG. 16B and FIG. 20B, the write current (first write current) I_{write} may flow from the conductive line WBLⱼ to the conductive line SBLⱼ in a state in which the assist potential V_{dd}_{_}_{W5} is applied to the conductive line LBL₄, by preparing the mutually different potentials V_{dd}_{_}_{W2} to V_{dd}_{_}_{W9} as the assist potentials applied to the conductive lines LBL₁ to LBL₈. The inhibit potentials V_{inhibit}_{_}_{W} applied to the conductive lines LBL₁ to LBL₃ and LBL₅ to LBL₈ may also be mutually different potentials. In addition, if the efficiency of the voltage effect of the voltage assist is adequately high, the inhibit potential V_{inhibit} can be replaced with a floating potential.

The second write operation is an operation of urging the predetermined data (for example, 0) written at the single bit which is the interest of write, to be held (for example, if the write data is 0) or to be changed from 0 to 1 (for example, if the write data is 1) in accordance with the write data.

First, the conductive lines WLᵢ and SWLᵢ are held in the activated state in the word line decoder/driver 17 shown in FIG. 15.

Next, the internal controller 13-2 shown in FIG. 7 sets, for example, the control signal WE1/2 at 1. For example, when the control signal WE1/2 is 1, the second write operation is selected.

In this case, the selector 36 selects and outputs 1 from the ROM 35 as the ROM data, in the read/write circuit 15 shown in FIG. 16A. Therefore, the write driver/sinker D/S_B outputs, for example, the drive potential V_{dd}_{_}_{W1} as the write pulse signal and the write driver/sinker D/S_A outputs, for example, the ground potential Vₛₛ.

The drive potential of the write pulse signal output from the write driver/sinker D/S_A circuit in the first write operation and the drive potential of the write pulse signal output from the write driver/sinker D/S_B in the second write operation may be different drive potentials. In addition, the ground potential of the write pulse signal output from the write driver/sinker D/S_B circuit in the first write operation and the ground potential of the write pulse signal output from the write driver/sinker D/S_B in the second write operation may be different ground potentials.

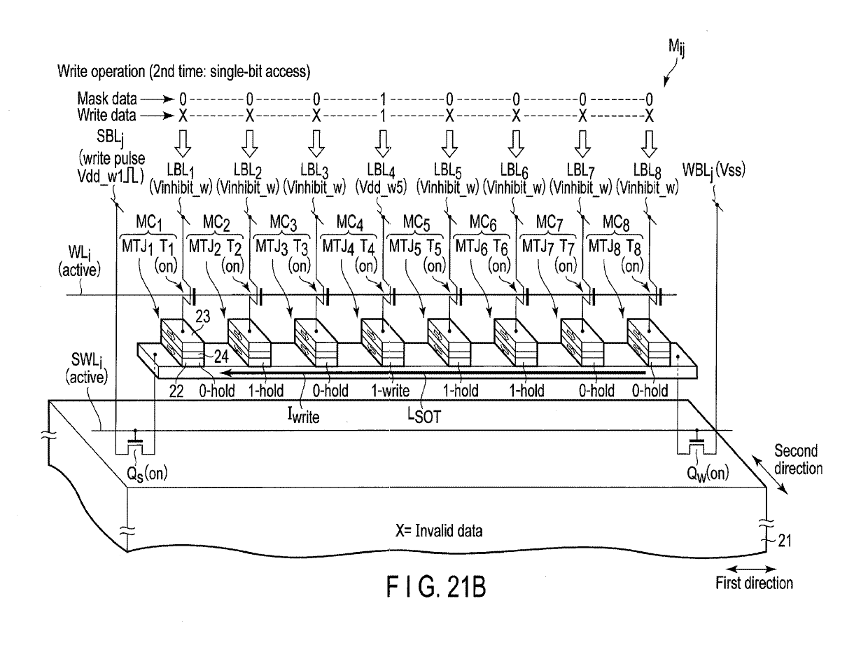

The write pulse signal is applied to the conductive line SBL via the transfer gate TG and the ground potential Vₛₛ is applied to the conductive line WBL via the transfer gate TG. At this time, if the column selected by the column selector 16 shown in FIG. 7 is assumed to be CoLⱼ, the write current (second write current) I_{write} flows from the conductive line SBLⱼ to the conductive line WBLⱼ, i.e., from the left side to the right side in the conductive line L_{SOT}, as shown in, for example, FIG. 21A.

In addition, the selector 39 selects and outputs the write data (for example, xxx1xxxx) stored in the data register 38, in the read/write circuit 15 shown in FIG. 16A. In this example, x represents invalid data. The write data is preliminarily stored in the data register 38 before the second write operation is executed. In addition, the internal controller 13-2 shown in FIG. 7 sets selected one bit, of eight bits stored in the mask register 40, at 1 by using, for example, the control signal Wₛₑₗ_{_}₁, at the single-bit access.

For example, when the storage element MTJ₄ is an interest of write in the first write operation, 1 bit corresponding to the conductive line LBL₄ connected to the storage element MTJ₄, of 8 bits stored in the mask register 40, is set at 1 in the second write operation, too. In other words, 8 bits stored in the mask register 40 becomes, for example, 00010000.

The AND circuit 41₄, of the AND circuits 41₁ to 41₈, therefore outputs the output signal (for example, 1) corresponding to the write data. At this time, for example, the voltage assist driver 42₄ outputs the assist potential V_{dd}_{_}_{W2} when the write data is 1 or outputs the inhibit potential V_{inhibit}_{_}_{W} when the write data is 0.

In addition, the AND circuits 41₁ to 41₃ and 41₅ to 41₈, of the AND circuits 41₁ to 41₈, output 0. At this time, the voltage assist drivers 42₁ to 42₃ and 42₅ to 42₈ output, for example, the inhibit potential V_{inhibit}_{_}_{W}.

In other words, for example, if the write data is xxx1xxxx and the mask data is 00010000, the write current (second write current) I_{write} flows from the conductive line SBLⱼ to the conductive line WBLⱼ in a state in which the inhibit potential V_{inhibit}_{_}_{W} is applied to the conductive lines LBL₁ to LBL₃ and LBL₅ to LBL₈ and the assist potential V_{dd}_{_}_{W2} is applied to the conductive lines LBL₄, as shown in FIG. 21A.

As a result, the predetermined data (for example, 0) is changed to 1, i.e., 1 is written as the single bit which is the interest of write, for example, the data of the storage element MTJ₄, in the second write operation. In contrast, when the write data is 0, the predetermined data (for example, 0) is held, i.e., 0 is written as the data of the storage elements MTJ₄.

In addition, the already written data is held in remaining seven bits that are not the interests of write, for example, the storage elements MTJ₁ to MTJ₃ and MTJ₅ to MTJ₈, by the above mask processing. In other words, the data in the storage elements MTJ₁ to MTJ₃ and MTJ₅ to MTJ₈ is not changed to 1, but the data in the storage elements MTJ₁ to MTJ₃ and MTJ₅ to MTJ₈ is protected, in the second write operation, too.

As shown in FIG. 16B and FIG. 21B, the write current (second write current) I_{write} may flow from the conductive line SBLⱼ to the conductive line WBLⱼ in a state in which the assist potential V_{dd}_{_}_{W5} is applied to the conductive line LBL₄, by preparing the mutually different potentials V_{dd}_{_}_{W2} to V_{dd}_{_}_{W9} as the assist potentials applied to the conductive lines LBL₁ to LBL₈. The inhibit potentials V_{inhibit}_{_}_{W} applied to the conductive lines LBL₁ to LBL₃ and LBL₅ to LBL₈ may also be mutually different potentials. In addition, if the efficiency of the voltage effect of the voltage assist is adequately high, the inhibit potential V_{inhibit} can be replaced with a floating potential.

A single voltage assist driver may be provided instead of the voltage assist drivers and a destination of its output may be changed to one of the conductive lines LBL₁ to LBL₈ sequentially. In this case, the multi-bit access can be executed in the write type close to a single-bit access type which will be explained later.

*Read Operation

[Multi-Bit Access]

When the internal controller 13-2 shown in FIG. 7 receives, for example, the read command CMD of the sequential access, the internal controller 13-2 controls the read operation using the multi-bit access.

First, the read enable signal RE becomes 1 and the output signal of the OR circuit 31 becomes 1 in the word line decoder/driver 17 shown in FIG. 15. For example, if all the bits of the row address signal A_{row} are 1 (11 . . . 11), the output signal of the AND circuit 32ᵢ becomes 1. The conductive lines WLᵢ and SWLᵢ are therefore activated by the drivers 33ᵢ and 34ᵢ.

Next, the internal controller 13-2 shown in FIG. 7 sets selected one bit of eight bits stored in the shift register 43 to be 1 sequentially by using, for example, the control signal Rₛₑₗ_{_}₁. In this case, the read drivers 44₁ to 44₈ sequentially output the select potential V_{dd}_{_}ᵣ.

For example, the conductive lines LBL₁ to LBL₈ are selected one by one at the select potential V_{dd}_{_}ᵣ and seven conductive lines other than the conductive line LBL_{d} (d is one of 1 to 8) set at the select potential V_{dd}_{_}ᵣ are set at the nonselect potential V_{inhibit}_{_}ᵣ. In addition, φᵣₛₜ in FIG. 17 becomes active and the conductive line SBL is set at the ground potential Vₛₛ.

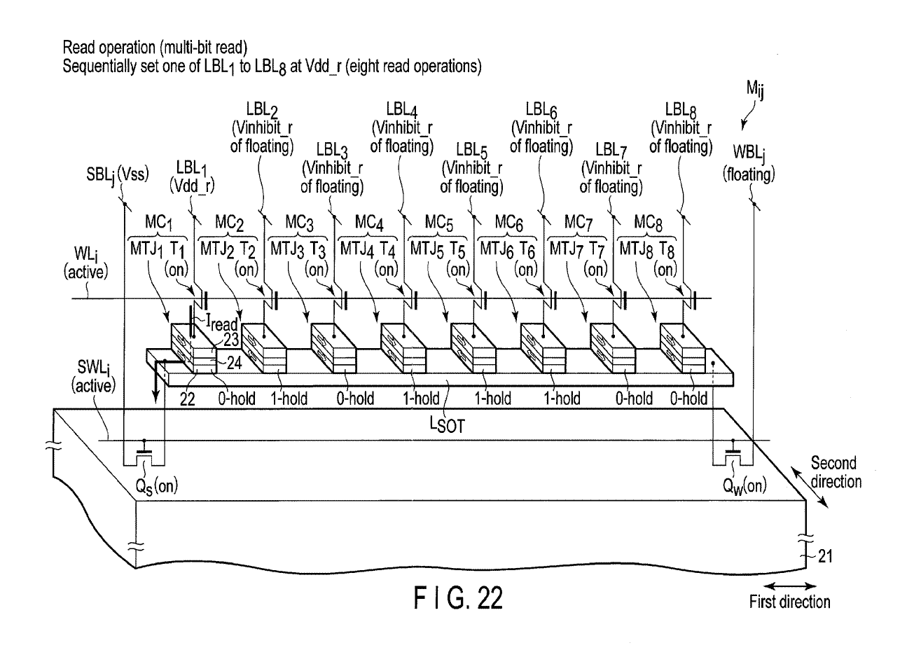

In this case, for example, if the conductive line LBL₁ is set at the select potential V_{dd}_{_}ᵣ, the read current I_{read} flows from the conductive line LBL₁ to the conductive line L_{SOT} via the storage element MTJ₁, as shown in FIG. 22. The data of the storage element MTJ₁ is thereby stored in the shift register 46 via the sense circuit 45 shown in FIG. 16A or 16B.

Similarly to this, the data of the storage elements MTJ₂ to MTJ₈ is sequentially stored in the shift register 46 via the sense circuit 45 shown in FIG. 16A or 16B by sequentially setting the conductive lines LBL₂ to LBL₈ at the select potential V_{dd}_{_}ᵣ.

As a result, the multi-bits (for example, 8 bits) that are the interests of sequential access are stored in the shift register 46 as the read data (for example, 01011100), by eight read operations. The multi-bits are wholly transferred to the interface 13-2 shown in FIG. 7 as the read data DA₁.

The select potentials sequentially applied to the conductive lines LBL₁ to LBL₈ can be different potentials by preparing a plurality of (for example, eight) power lines. In this case, the influence that the parasitic resistance differs in accordance with the location of the selected storage element on the conductive line L_{SOT} can be canceled.

If the efficiency of the voltage effect of the voltage assist is adequately high, the floating potential can also be used as the nonselect potential. In this case, a plurality of read drivers do not need to be mounted, and the select potential V_{dd}_{_}ᵣ can be output to the predetermined conductive line and the read operation can be executed by changing one of the conductive lines LBL₁ to LBL₈ sequentially as the destination of the output of the single read driver.

[Single-Bit Access]

When the internal controller 13-2 shown in FIG. 7 receives, for example, the read command CMD of the random access, the internal controller 13-2 controls the read operation using the single-bit access.

First, the read enable signal RE becomes 1 and the output signal of the OR circuit 31 becomes 1 in the word line decoder/driver 17 shown in FIG. 15. For example, if all the bits of the row address signal A_{row} are 1 (11 . . . 11), the output signal of the AND circuit 32ᵢ becomes 1. The conductive lines WLᵢ and SWLᵢ are therefore activated by the drivers 33ᵢ and 34ᵢ.

Next, the internal controller 13-2 shown in FIG. 7 sets one bit of eight bits stored in the shift register 43 to be 1 by using, for example, the control signal Rₛₑₗ_{_}₁. For example, if the storage element which is the interest of read is MTJ₄, the internal controller 13-2 shown in FIG. 7 controls the shift register 43 such that eights stored in the shift register 43 become 00010000.

In this case, the read driver 44₄, of the read drivers 44₁ to 44₈, outputs the select potential V_{dd}_{_}ᵣ and remaining seven read drivers 44₁ to 44₃ and 44₅ to 44₈ output the nonselect potential V_{inhibit} r. In addition, φᵣₛₜ in FIG. 17 becomes active and the conductive line SBL is set at the ground potential Vₛₛ.

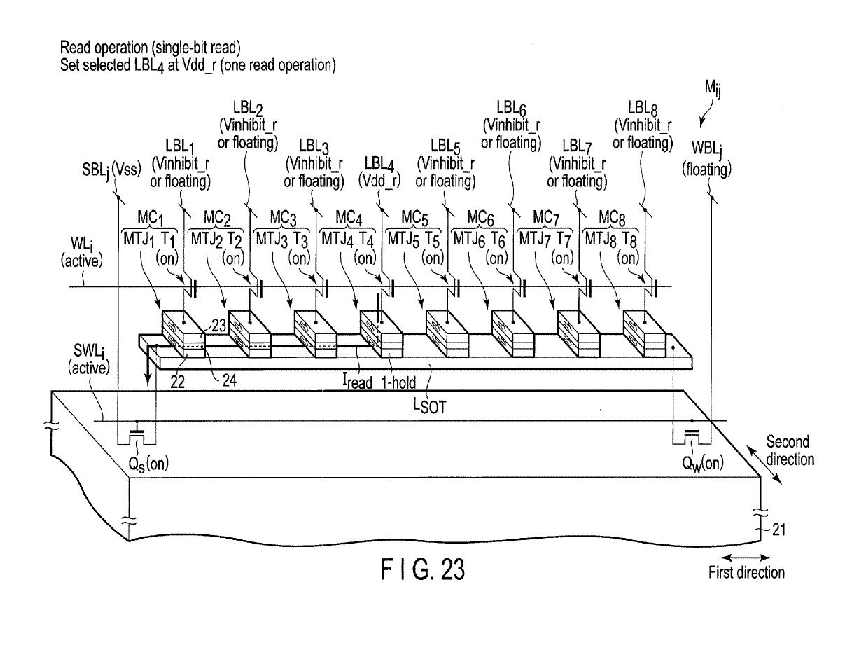

Therefore, for example, the read current I_{read} flows from the conductive line LBL₄ to the conductive line L_{SOT} via the storage element MTJ₄, as shown in FIG. 23. The data of the storage element MTJ₄ is thereby stored in the shift register 46 via the sense circuit 45 shown in FIG. 16A or 16B. As a result, the shift register 46 stores, for example, xxx1xxxx as the read data.

The valid data (read data) stored in the shift register 46 is transferred to the interface 13-1 shown in FIG. 7 as the read data DA₁.

The select potentials sequentially applied to the conductive lines LBL₁ to LBL₈ may be different potentials by preparing a plurality of (for example, eight) power lines. In this case, the influence that the parasitic resistance differs in accordance with the location of the selected storage element on the conductive line L_{SOT} can be canceled.

If the efficiency of the voltage effect of the voltage assist is adequately high, the floating potential can also be used as the nonselect potential. In this case, a plurality of read drivers do not need to be mounted, and the select potential V_{dd}_{_}ᵣ can be output to the predetermined conductive line and the read operation can be executed by changing one of the conductive lines LBL₁ to LBL₈ sequentially as the destination of the output of the single read driver.

(Layout)

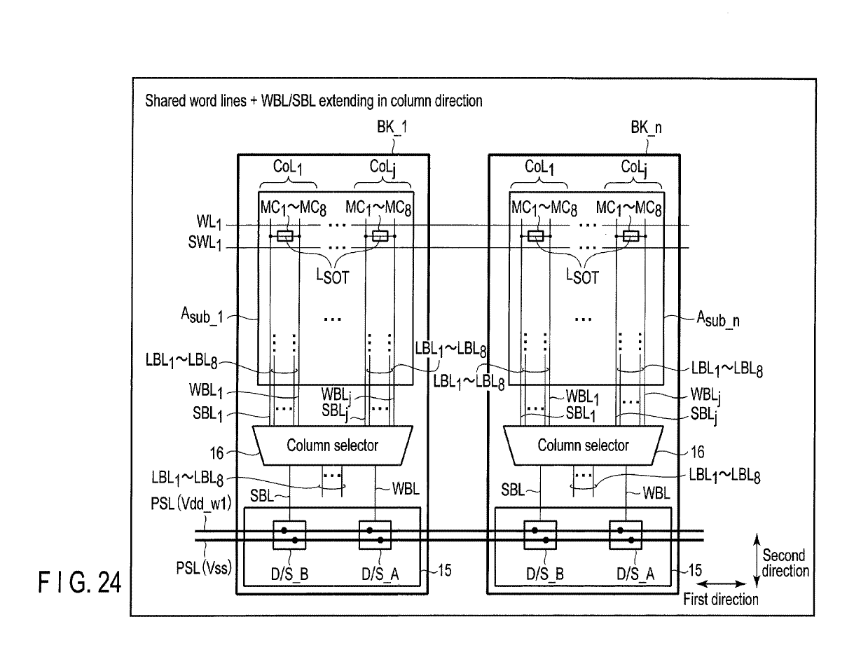

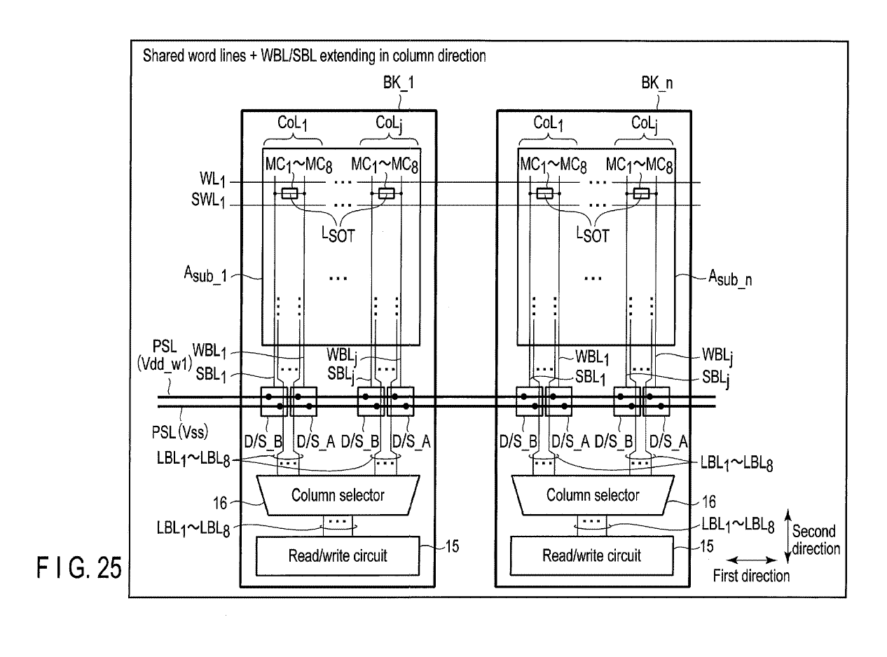

FIG. 24 is a diagram simply showing the SOT-MRAM explained with reference to FIGS. 7 to 23. FIGS. 25 to 28 show a modified example of the SOT-MRAM shown in FIG. 24. An example of the layout of the write drivers/sinkers D/S_A and D/S_B will be explained here.

The same elements as those shown in, for example, FIG. 7 are denoted by the same referential numbers in FIGS. 24 to 28 and their detailed explanations are omitted.

The SOT-MRAM shown in FIG. 24 has, for example, what is called a shared word line architecture in which the memory cells MC₁ to MC₈ accessed parallel at the multi-bit access share one conductive line (word line) WL₁ selecting the memory cells MC′ to MC₈.

In addition, the SOT-MRAM shown in FIG. 24 has what is called a column direction extending architecture in which the conductive lines WBL₁ to WBLⱼ and SBL₁ to SBLⱼ for urging the write current to flow to the conductive line L_{SOT} shared by the memory cells MC₁ to MC₈ extend in the second direction intersecting the first direction.

In this case, the write drivers/sinkers D/S_A and D/S_B are disposed in the read/write circuit 15 in each block (memory core) BK_k (k is one of 1 to n). The write drivers/sinkers D/S_A and D/S_B are shared by the columns CoL₁ to CoLⱼ.

In addition, the power lines PSL for supplying, for example, the drive potential V_{dd}_{_}_{W1} and the ground potential Vₛₛ to the write drivers/sinkers D/S_A and D/S_B are disposed above the read/write circuit 15 and extend in the first direction.

The SOT-MRAM shown in FIG. 25 has the shared word line architecture and the column direction extending architecture, similarly to the SOT-MRAM shown in FIG. 24.

However, the write drivers/sinkers D/S_A and D/S_B are provided for each column CoLₚ (p is one of 1 to j) in the block BK_k (k is one of 1 to n). In this case, the write drivers/sinkers D/S_A and D/S_B are laid out between sub-arrays A_{sub}_{_}₁ to A_{sub}_{_}ₙ and the column selector 16.

In addition, the power lines PSL for supplying, for example, the drive potential V_{dd}_{_}_{W1}and the ground potential Vₛₛ to the write drivers/sinkers D/S_A and D/S_B are disposed above the write drivers/sinkers D/S_A and D/S_B and extend in the first direction.

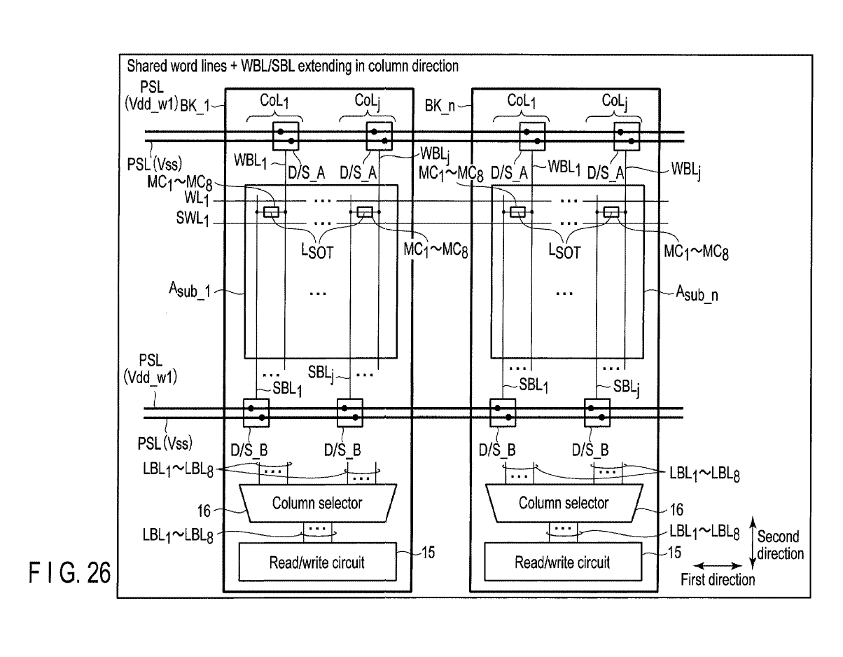

The SOT-MRAM shown in FIG. 26 has the shared word line architecture and the column direction extending architecture, similarly to the SOT-MRAM shown in FIG. 25.

However, the example shown in FIG. 26 is different from the example shown in FIG. 25 with respect to features that the write drivers/sinkers D/S_A are laid out at one of ends (i.e., the end portion on the side where the column selectors 16 do not exist) of the sub-arrays A_{sub}_{_}₁ to A_{sub}_{_}ₙ and that the write drivers/sinkers D/S_B are laid out at the other end (i.e., the end portion on the side where the column selectors 16 exist) of the sub-arrays A_{sub}_{_}₁ to A_{sub}_{_}ₙ.

In addition, the power lines PSL for supplying, for example, the drive potential V_{dd}_{_}_{W1} and the ground potential Vₛₛ to the write drivers/sinkers D/S_A are disposed above the write drivers/sinkers D/S_A and extend in the first direction. The power lines PSL for supplying, for example, the drive potential V_{dd}_{_}_{W1} and the ground potential Vₛₛ to the write drivers/sinkers D/S_B are disposed above the write drivers/sinkers D/S_B and extend in the first direction.

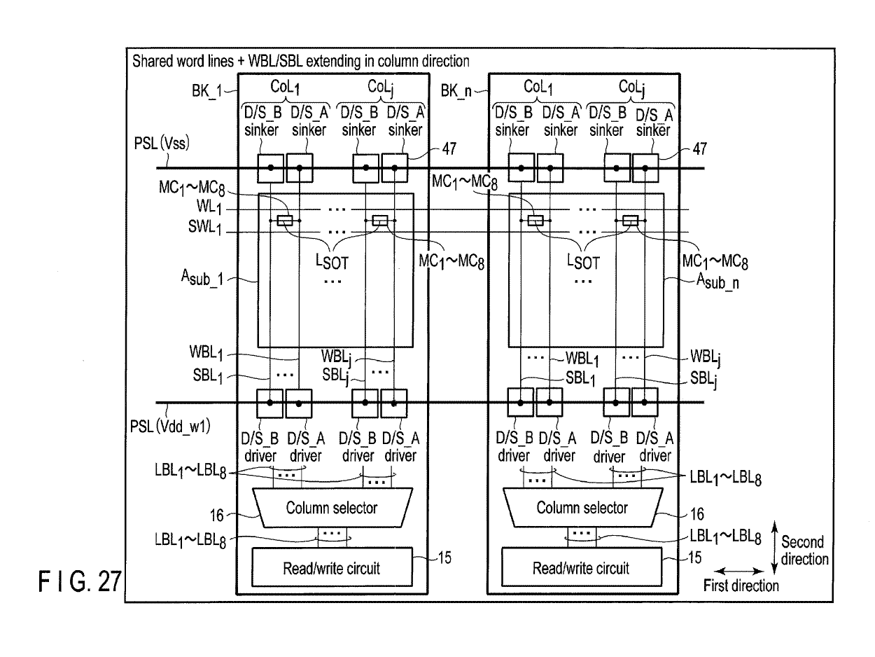

The SOT-MRAM shown in FIG. 27 has the shared word line architecture and the column direction extending architecture, similarly to the SOT-MRAM shown in FIG. 26.

However, the example shown in FIG. 27 is different from the example shown in FIG. 26 with respect to features that the write drivers/sinkers D/S_A are divided into D/S_A drivers and D/S_A sinkers and that the write drivers/sinkers D/S_B are divided into D/S_B drivers and D/S_B sinkers.

In addition, the D/S_A sinkers and the D/S_B sinkers are laid out at one of ends (i.e., the end portion on the side where the column selectors 16 do not exist) of the sub-arrays A_{sub}_{_}₁ to A_{sub}_{_}ₙ, and the D/S_A drivers and the D/S_B drivers are laid out at the other end (i.e., the end portion on the side where the column selectors 16 exist) of the sub-arrays A_{sub}_{_}₁ to A_{sub}_{_}ₙ.

The power lines PSL for supplying, for example, the ground potential Vₛₛ to the D/S_A sinkers and the D/S_B sinkers are disposed above the D/S_A sinkers and the D/S_B sinkers and extend in the first direction. The power lines PSL for supplying, for example, the drive potential V_{dd}_{_}_{W1} to the D/S_A drivers and the D/S_B drivers are disposed above the D/S_A drivers and the D/S_B drivers and extend in the first direction.

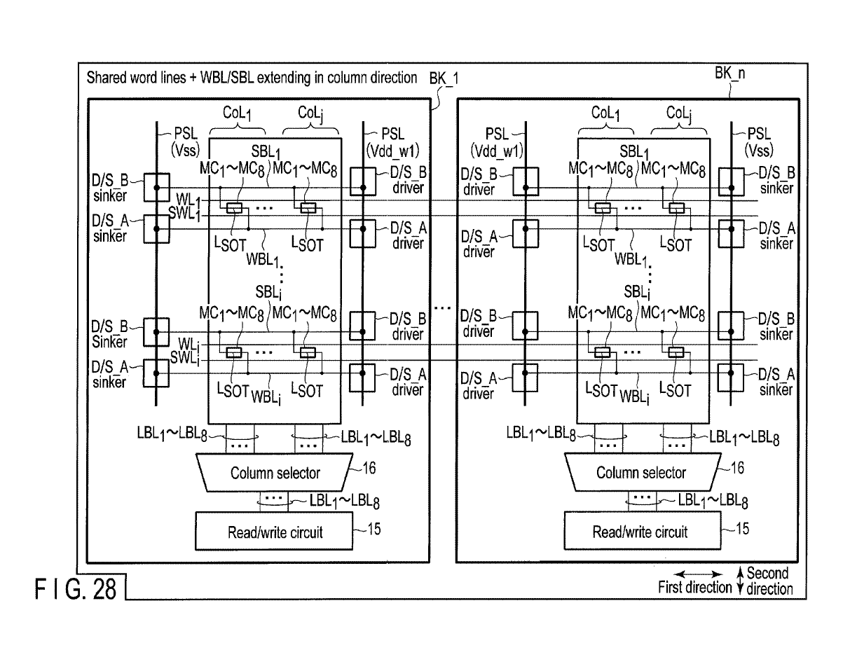

The SOT-MRAM shown in FIG. 28 has the shared word line architecture, similarly to the SOT-MRAM shown in FIG. 27.

However, the SOT-MRAM shown in FIG. 28 has what is called a row direction extending architecture in which the conductive lines WBL₁ to WBLⱼ and SBL₁ to SBLⱼ for urging the write current to flow to the conductive line L_{SOT} shared by the memory cells MC₁ to MC₈ extend in the first direction in which the conductive line WL₁ extends, as compared with the example shown in FIG. 27.

In this case, the D/S_A sinkers and the D/S_B sinkers are laid out at one of ends (i.e., the end portion in the first direction) of the sub-arrays A_{sub}_{_}₁ to A_{sub}_{_}ₙ, and the D/S_A drivers and the D/S_B drivers are laid out at the other end (i.e., the end portion in the first direction) of the sub-arrays A_{sub}_{_}₁ to A_{sub}_{_}ₙ.

As shown in this figure, for example, the D/S_A sinkers and the D/S_B sinkers are laid out at one of ends (i.e., the left end portion) of the sub-arrays A_{sub}_{_}₁ to A_{sub}_{_}ₙ, and the D/S_A drivers and the D/S_B drivers are laid out at the other end (i.e., the right end portion) of the sub-arrays A_{sub}_{_}₁ to A_{sub}_{_}ₙ, in the odd-numbered block BK_k (k is 1, 3, 5, . . . )

The D/S_A sinkers and the D/S_B sinkers are laid out at one of ends (i.e., the right end portion) of the sub-arrays A_{sub}_{_}₁ to A_{sub}_{_}ₙ, and the D/S_A drivers and the D/S_B drivers are laid out at the other end (i.e., the left end portion) of the sub-arrays A_{sub}_{_}₁ to A_{sub}_{_}ₙ, in the even-numbered block BK_k (k is 2, 4, 6, . . . )

The power lines PSL for supplying, for example, the ground potential Vₛₛ to the D/S_A sinkers and the D/S_B sinkers are disposed above the D/S_A sinkers and the D/S_B sinkers and extend in the second direction. The power lines PSL for supplying, for example, the drive potential V_{dd}_{_}_{W1} to the D/S_A drivers and the D/S_B drivers are disposed above the D/S_A drivers and the D/S_B drivers and extend in the second direction.

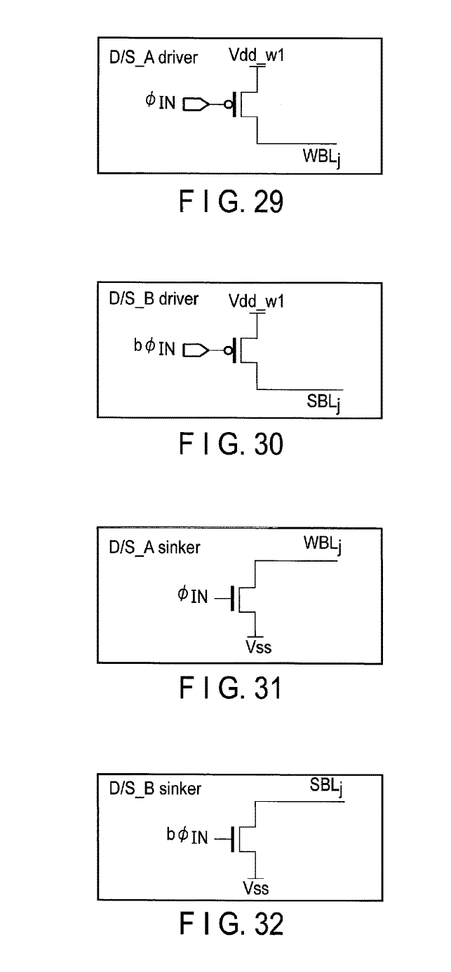

FIGS. 29 to 32 show examples of the D/SA driver, the D/S_B driver, the D/S_A sinker, and the D/S_B sinker shown in FIGS. 27 and 28.

The D/S_A driver comprises, for example, a P-channel FET controlled by a control signal φ_{IN}, and the D/S_B driver comprises, for example, a P-channel FET controlled by a control signal bφ_{IN}. The D/S_A sinker comprises, for example, an N-channel FET controlled by a control signal φ_{IN}, and the D/S_B sinker comprises, for example, an N-channel FET controlled by a control signal bφ_{IN}.

The control signal φ_{IN} corresponds to the control signal φ_{IN} output from the selector 36 in FIG. 16. The control signal bφ_{IN} is an inverted signal of the control signal φ_{IN}.

In the example shown in FIG. 27, of the examples shown in FIGS. 24 to 28, the write drivers/sinkers (the D/S_A driver, the D/S_B driver, the D/S_A sinker, and the D/S_B sinker) are provided for each column CoLp. In addition, the power line PSL for supplying Vₛₛ and the power line PSL for supplying V_{dd}_{_}_{W1} are disposed separately from each other. The example shown in FIG. 27 is therefore considered most desirable.

### Second Example

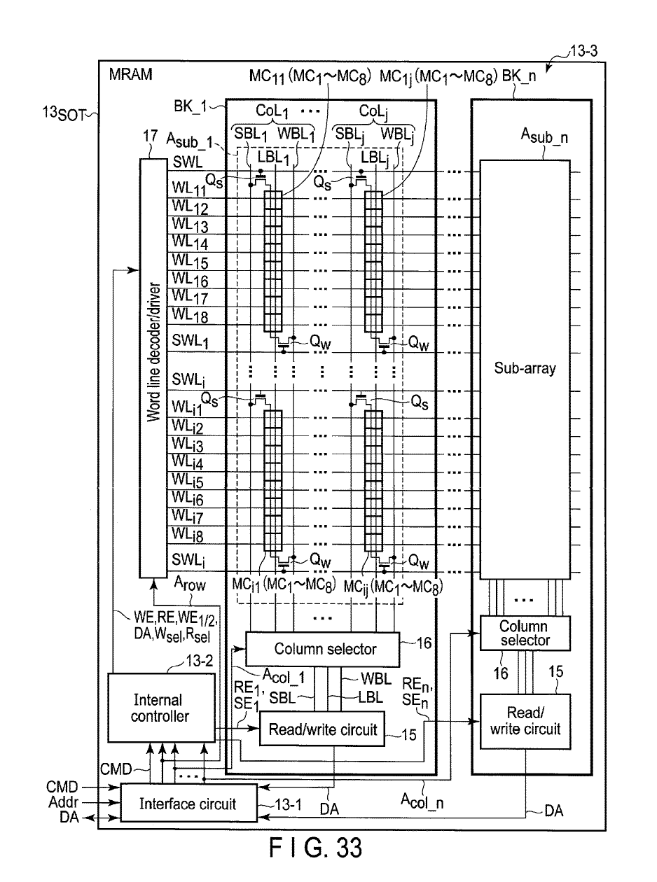

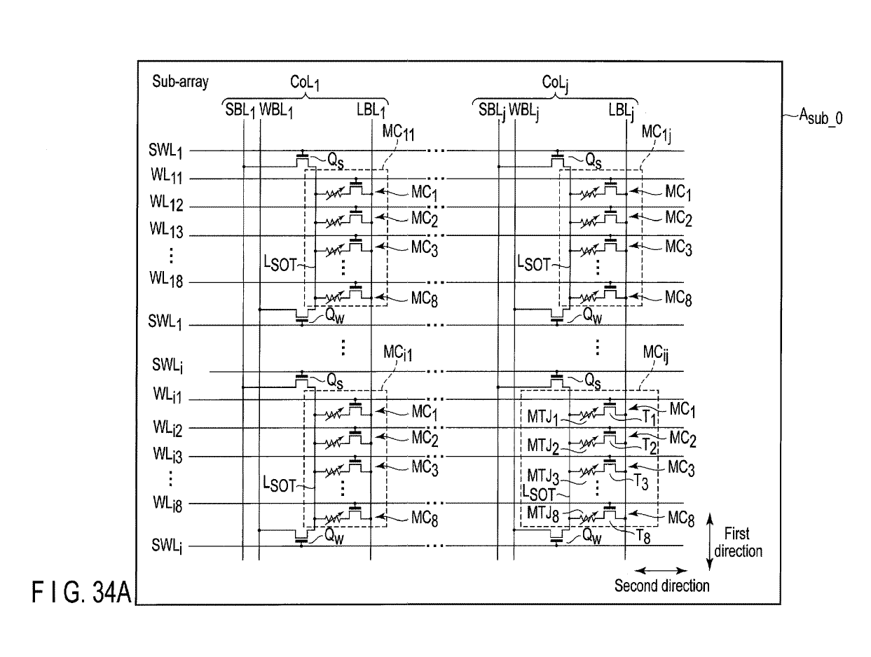

FIG. 33 shows a second example of the SOT-MRAM.

The SOT-MRAM 13_{SOT} comprises an interface 13-1, an internal controller 13-2, a memory cell array 13-3 and a word line decoder/driver 17. The memory cell array 13-3 comprises n blocks (memory cores) BK_1 to BK_n. n is a natural number of 2 or larger.

A command CMD is transferred to the internal controller 13-2 via the interface 13-1. The command CMD includes, for example, a first command to instruct the sequential access and a second command to instruct the random access.

For example, when the internal controller 13-2 receives the command CMD, the internal controller 13-2 outputs, for example, control signals WE, RE, WE1/2, Wₛₑₗ, Rₛₑₗ, RE₁ to REₙ, and SE₁ to SEₙ, to execute the command CMD. The meaning and roles of the control signals will be explained later.

An address signal Addr is transferred to the internal controller 13-2 via the interface 13-1. The address signal Addr is divided into a row address A_{row} and column addresses A_{col}_{_}₁ to A_{col}_{_}ₙ in the interface 13-1. The row address A_{row} is transferred to the word line decoder/driver 17. The column addresses A_{col}_{_}₁ to A_{col}_{_}ₙ are transferred to n blocks BK_1 to BK_n.

DA is read data or write data transmitted or received in the read operation or the write operation. The I/O width (bit width) between the interface 13-1 and each of the blocks BK_k (k is one of 1 to n) is N bits at the N-bit access or 1 bit at the single-bit access as explained above.

Each of the blocks BK_k includes a sub-array A_{sub}_{_}ₖ, a read/write circuit 15, and a column selector 16.

The column selector 16 selects one of j columns (j is a natural number of 2 or larger) CoL₁ to CoLⱼ and connects the selected column CoLₚ (p is one of 1 of j) to the read/write circuit 15. For example, if the selected column CoLₚ is CoL₁, conductive lines LBL₁, SBL₁ and WBL₁ are electrically connected to the read/write circuit 15 via the column selector 16, as conductive lines LBL, SBL and WBL.

The sub-array A_{sub}_{_}ₖ comprises, for example, memory cells M11 (MC₁ to MC₈) to M1j (MC₁ to MC₈), and Mᵢ₁ (MC₁ to MC₈) to Mᵢⱼ (MC₁ to MC₈).

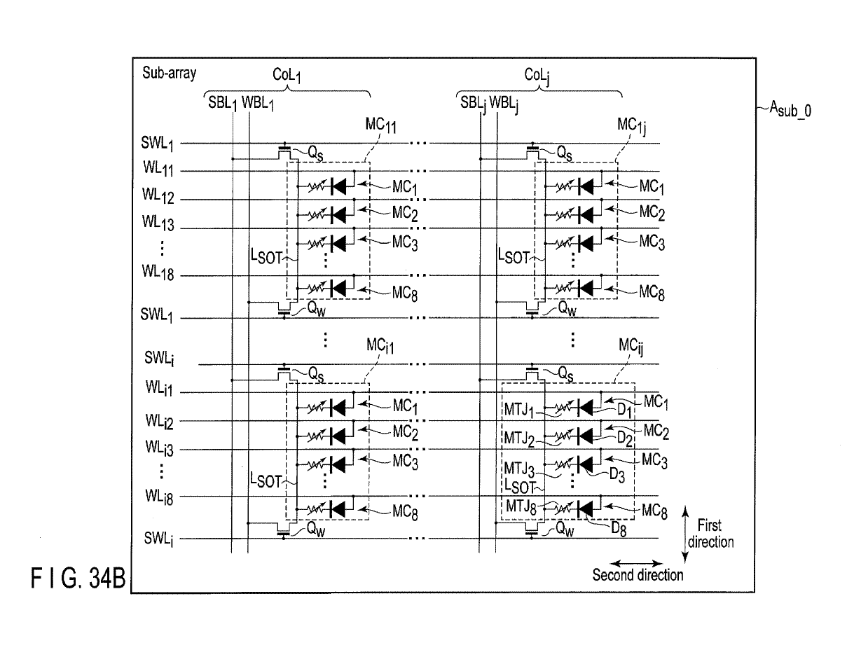

An example of the sub-array A_{sub}_{_}ₖ will be explained with an equivalent circuit of a sub-array A_{sub}_{_}₁ shown in FIG. 34A.

M₁₁ (MC₁ to MC₈) to M₁ⱼ (MC₁ to MC₈), Mᵢ₁ (MC₁ to MC₈) to Mᵢⱼ (MC₁ to MC₈), WL₁₁ to WL₁₈, WLᵢ₁ to WLᵢ₈, SWL₁ to SWLᵢ, SBL₁ to SBLⱼ, WBLⱼ to WBLⱼ, LBL₁ to LBL₈, Q_{W}, and Q_{S} shown in FIG. 34A correspond to M₁₁ (MC₁ to MC₈) to M₁ⱼ (MC₁ to MC₈), Mᵢ₁ (MC₁ to MC₈) to Mᵢⱼ (MC₁ to MC₈), WL₁₁ to WL₁₈, WLᵢ₁ to WLᵢ₈, SWL₁ to SWLᵢ, SBL₁ to SBLⱼ, WBL₁ to WBLⱼ, LBL₁ to LBLⱼ, Q_{W}, and Q_{S} shown in FIG. 33, respectively.

Conductive lines L_{SOT} extend in the first direction. The cell unit Mᵢⱼ corresponds to the conductive line L_{SOT} and comprises the memory cells MC₁ to MC₈. The number of memory cells MC₁ to MC₈ corresponds to N of the N-bit access. The number of memory cells MC₁ to MC₈ is eight in the present example but is not limited to this. For example, the number of memory cells MC₁ to MC₈ may be two or larger.

The memory cells MC₁ to MC₈ comprise storage elements MTJ₁ to MTJ₈ and transistors T₁ to T₈, respectively.

Each of the storage elements MTJ₁ to MTJ₈ is a magnetoresistive element. For example, each of the storage elements MTJ₁ to MTJ₈ comprises a first magnetic layer (storage layer) having a variable magnetization direction, a second magnetic layer (reference layer) having an invariable magnetization direction, and a nonmagnetic layer (tunnel barrier layer) between the first and second magnetic layers, and the first magnetic layer is in contact with the conductive line L_{SOT}.

In this case, the conductive line L_{SOT} desirably has the material and the thickness which enable the magnetization direction of the first magnetic layers of the storage elements MTJ₁ to MTJ₈ to be controlled by spin orbit coupling or the Rashba effect. For example, the conductive line L_{SOT} contains tantalum (Ta), tungsten (W), platinum (Pt) and the like and has a thickness in a range of 5 to 20 mm (for example, approximately 10 nm). The conductive line L_{SOT} may be formed in a multilayer structure of two or more layers including a layer of metals such as hafnium (Hf), magnesium (Mg), titanium (Ti) and the like in addition to a layer of the metals such as tantalum (Ta), tungsten (W), platinum (Pt) and the like. Furthermore, the conductive line L_{SOT} may be formed in a multilayer structure of two or more layers including layers formed of single metallic elements of the above but different in crystal structure or a layer in which a single metallic element of the above is oxidized or nitrided.

Each of transistors T₁ to T₈ is, for example, an N-channel FET. The transistors T₁ to T₈ are desirably so called vertical transistors which are disposed above the semiconductor substrate and in which channels (current paths) intersect the surface of the semiconductor substrate in the vertical direction.

The storage element MTJ_{d} (d is one of 1 to 8) comprises a first terminal (storage layer) and a second terminal (reference layer), and the first terminal is connected to the conductive line L_{SOT}. The transistor Td comprises a third terminal (source/drain), a fourth terminal (source/drain), a channel (current path) between the third and fourth terminals, and a control electrode (gate) which controls occurrence of a channel, and the third terminal is connected to a second terminal.

The conductive lines WL₁₁ to WL₁₈ and WLᵢ₁ to WLᵢ₈ extend in the second direction intersecting the first direction and are connected to the control electrodes of the transistors T₁ to T₈. The conductive lines LBL₁ to LBLⱼ extend in the first direction and are connected to the fourth terminals of the transistors T₁ to T₈, respectively.

Each of the conductive lines L_{SOT} has first and second end portions.

Each of the transistors Q_{S} comprises a channel (current path) connected between the first end portion of the conductive line L_{SOT} and the conductive lines SBL₁ to SBLⱼ, and a control terminal (gate) which controls generation of the channel. Each of the transistors Q_{W} comprises a channel (current path) connected between the second end portion of the conductive line L_{SOT} and the conductive lines SBL₁ to SBLⱼ, and a control terminal (gate) which controls generation of the channel.

The conductive lines SWL₁ to SWLᵢ extend in the second direction and are connected to the control electrodes of the transistors Q_{S} and Q_{W}. The conductive lines SBL₁ to SBLⱼ and WBL₁ to WBLⱼ extend in the first direction.

In the present embodiments, the transistor Q_{S} is connected to the first end portion of the conductive line L_{SOT} and the transistor Q_{W} is connected to the second end portion of the conductive line L_{SOT}, but one of them may be omitted.

In addition, the transistors T₁ to T₈ can be replaced with diodes D₁ to D₈ as shown in FIG. 34B.

According to the present embodiments, the architecture or the layout for putting SOT-MRAM to practical use is implemented. The nonvolatile MRAM which can be used in various systems can be thereby implemented.

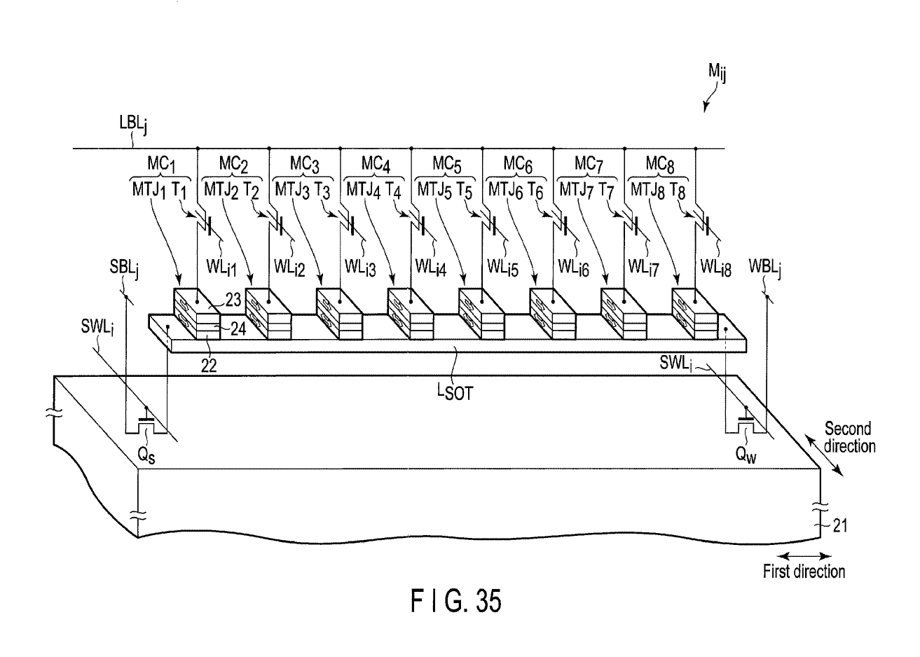

FIGS. 35 to 37 show examples of a device structure of the SOT-MRAM.

In these figures, Mᵢⱼ (MC₁ to MC₈, MTJ₁ to MTJ₈, T₁ to T₈), WLᵢ₁ to WLᵢ₈, SWLᵢ, SBLⱼ, LBLⱼ, Q_{W}, and Q_{S} correspond to Mᵢⱼ (MC₁ to MC₈, MTJ₁ to MTJ₈, T₁ to T₈), WLᵢ₁ to WLᵢ₈, SWLᵢ, SBLⱼ, WBLⱼ, LBLⱼ, Q_{W}, and Q_{S} shown in FIG. 33 and FIG. 34A, respectively.

In the example shown in FIG. 35, the conductive line L_{SOT} is disposed above the semiconductor substrate 21, and each of the transistors Q_{S} and Q_{W} is disposed as what is called a horizontal transistor (FET) in the surface area of the semiconductor substrate 21.

The storage elements MTJ₁ to MTJ₈ are disposed on the conductive line L_{SOT} and the transistors T₁ to T₈ are disposed on the storage elements MTJ₁ to MTJ₈, respectively. The transistors T₁ to T₈ are so called vertical transistors. In addition, the conductive lines LBLⱼ, SBLⱼ and WBLⱼ are disposed on the transistors T₁ to T₈.

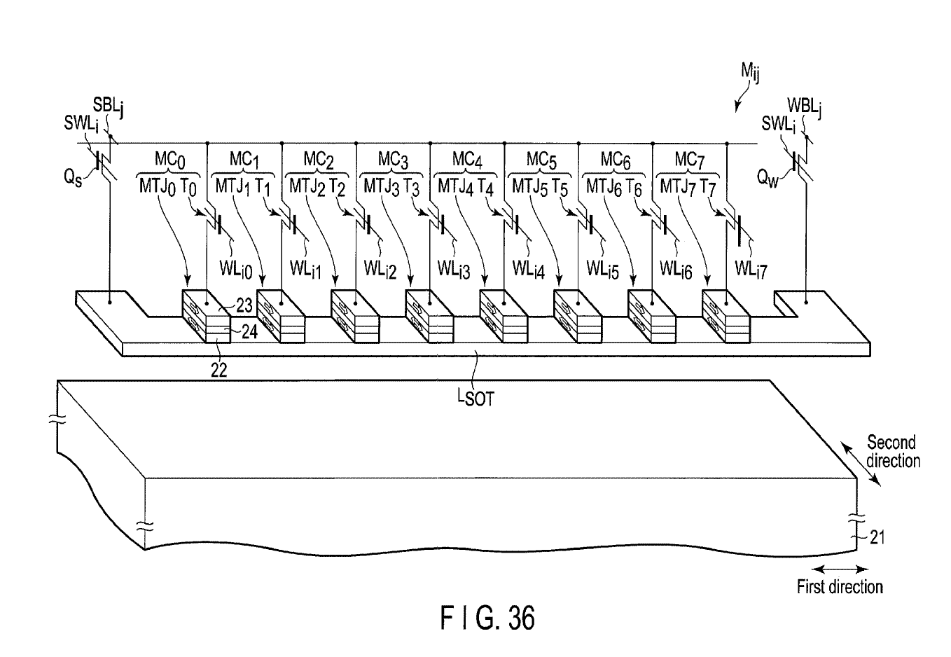

In the example shown in FIG. 36, the conductive line L_{SOT} is disposed above the semiconductor substrate 21, and the transistors Q_{S} and Q_{W} and the storage elements MTJ₁ to MTJ₈ are disposed on the conductive line L_{SOT}. The transistors T₁ to T₈ are disposed on the storage elements MTJ₁ to MTJ₈, respectively. The transistors Q_{S}, Q_{W}, and T₁ to T₈ are so called vertical transistors.

In addition, the conductive line LBLⱼ is disposed on the transistors T₁ to T₈, and the conductive lines SBLⱼ and WBLⱼ are disposed on the transistors Q_{S} and Q_{W}.

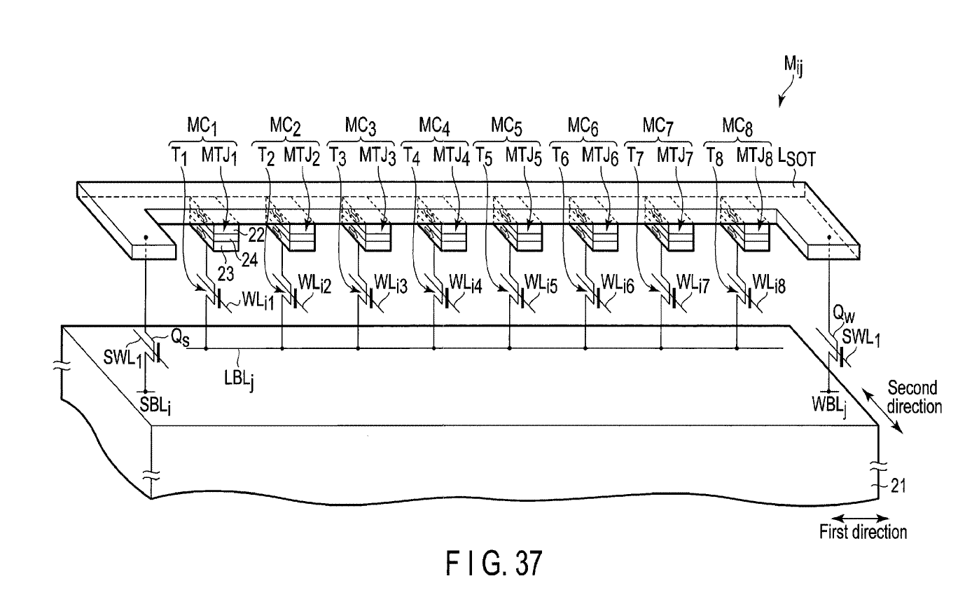

In the example shown in FIG. 37, the conductive lines LBLⱼ, SBLⱼ and WBLⱼ are disposed above the semiconductor substrate 21. The transistors T₁ to T₈ are disposed on the conductive line LBLⱼ, and the transistors Q_{S} and Q_{W} are disposed on the conductive lines SBLⱼ and WBLⱼ. The storage elements MTJ₁ to MTJ₈ are disposed on the transistors T₁ to T₈, respectively.

The conductive line L_{SOT} is disposed on the transistors T₁ to T₈, Q_{S} and Q_{W}. The transistors Q_{S}, Q_{W}, and T₁ to T₈ are so called vertical transistors.

In the examples of FIGS. 35 to 37, each of the storage elements MTJ₁ to MTJ₈ comprises a first magnetic layer (storage layer) 22 having a variable magnetization direction, a second magnetic layer (reference layer) 23 having an invariable magnetization direction, and a nonmagnetic layer (tunnel barrier layer) 24 between the first magnetic layer 22 and the second magnetic layer 23, and the first magnetic layer 22 is in contact with the conductive line L_{SOT}.

In addition, each of the first magnetic layer 22 and the second magnetic layer 23 has an easy-axis of magnetization in an in-plane direction along the surface of the semiconductor substrate 21 and in the second direction intersecting the first direction in which the conductive line L_{SOT} extends.

The structure explained with reference to FIGS. 12 to 14 can be employed as an example of the device structure of each memory cell shown in FIG. 35 and FIG. 36. In addition, the structure shown in FIGS. 12 to 14 may be turned upside down to obtain the device structure of each memory cell shown in FIG. 37.

The characteristic of the memory cell shown in FIGS. 12 to 14 is that the current path of the read current I_{read} used in the read operation is different from the current path of the write current I_{write} used in the write operation. As explained in the first example, even if both the read current I_{read} and the write current I_{write} become small due to microminiaturization of the memory cell or the like, the margin of both the currents can be sufficiently secured in consideration of the thermal stability Δ.

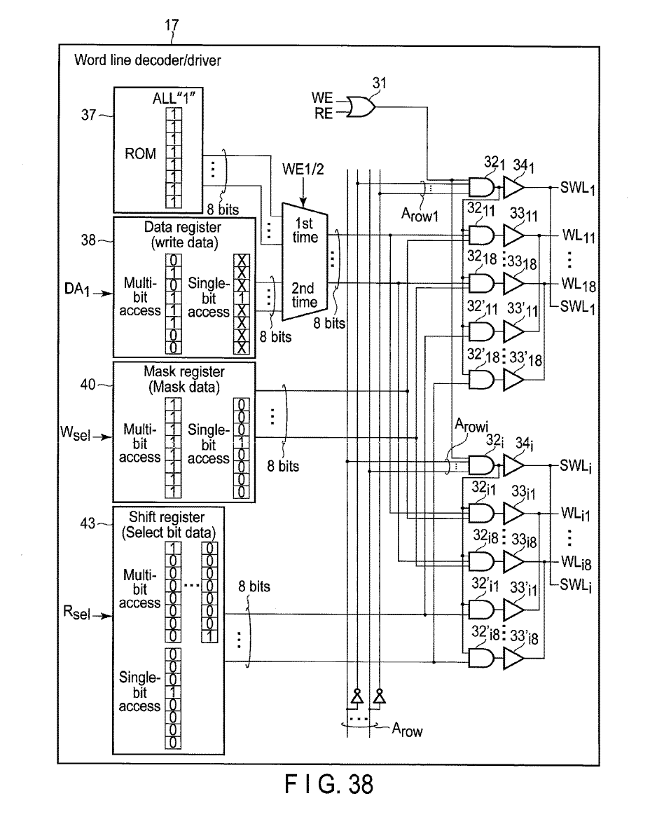

FIG. 38 shows an example of the word line decoder/driver shown in FIG. 33.

The word line decoder/driver 17 has a function of activating or deactivating the conductive lines WL₁₁ to WL₁₈, WLᵢ₁ to WLᵢ₈ and SWL₁ to SWLᵢ in the read operation or the write operation.

An OR circuit 31 and AND circuits 32₁ to 32ᵢ, 32₁₁ to 32₁₈, 32ᵢ₁ to 32ᵢ₈, 32′₁₁ to 32′₁₈, and 32′ᵢ₁ to 32′ᵢ₈ are decoder circuits.

In the read operation, for example, a read enable signal RE from the internal controller 13-2 shown in FIG. 33 becomes active (1). In the write operation, a write enable signal WE from the internal controller 13-2 shown in FIG. 33 becomes active (1).

The row address signal A_{row} has, for example, R bits (R is a natural number of 2 or more) and has a relationship i (number of rows)=2^{R}.

In the read operation or the write operation, all bits (R bits) of one of the row address signals A_{row1} to A_{rowi} become 1 when the row address signal A_{row} is input to the word line decoder/driver 17.

For example, if the row address signal A_{row} is 00 . . . 00 (all 0), the output signal of the AND circuit 32₁ becomes 1 since all the bits of the row address signal A_{row1} become 1. In this case, the drive circuit 34₁ sets the conductive line SWL₁ to be active. In addition, if the row address signal A_{row} is 11 . . . 11 (all 1), the output signal of the AND circuit 32i becomes 1 since all the bits of the row address signal A_{rowi} become 1. In this case, the drive circuit 34ᵢ sets the conductive line SWLᵢ to be active.

A ROM 37, a data register 38, a selector (multiplexer) 39 and a mask register 40 are elements used in the write operation. The ROM 37, the data register 38, the selector (multiplexer) 39 and the mask register 40 control setting the conductive lines WL₁₁ to WL₁₈ and WLᵢ₁ to WLᵢ₈ to be active/nonactive, in the row selected by the row address signal A_{row}. This will be explained later.

A shift register 43 is an element used in the read operation. The shift register 43 controls setting the conductive lines WL₁₁ to WL₁₈ and WLᵢ₁ to WLᵢ₈ to be active/nonactive, in the row selected by the row address signal A_{row}. This will also be explained later.

Drive circuits 33₁₁ to 33₁₈, 33ᵢ₁ to 33ᵢ₈, 33′₁₁ to 33′₁₈, and 33′ᵢ₁ to 33′ᵢ₈ correspond to AND circuits 32₁₁ to 32₁₈, 32ᵢ₁ to 32ᵢ₈, 32′₁₁ to 32′₁₈, and 32′ᵢ₁ to 32′ᵢ₈, respectively.

When an output signal of the AND circuit 32₁ is active (1), output signals of the AND circuits 32₁₁ to 32₁₈ and 32′₁₁ to 32′₁₈ can be active. In addition, when an output signal of the AND circuit 32ᵢ is active (1), output signals of the AND circuits 32ᵢ₁ to 32ᵢ₈ and 32′ᵢ₁ to 32′ᵢ₈ can be active.

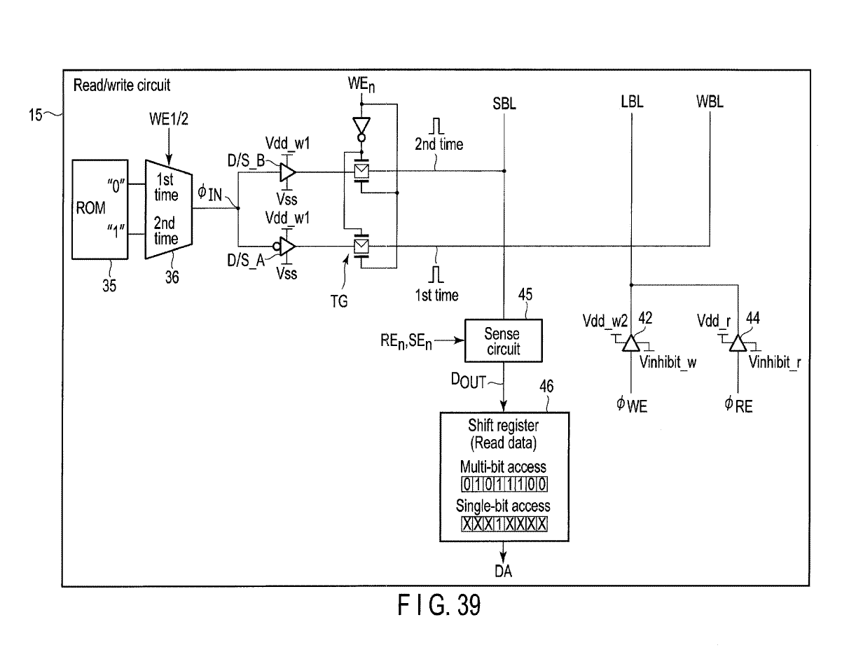

FIG. 39 shows an example of the read/write circuit shown in FIG. 33.

In the read operation or the write operation, the read/write circuit 15 selects one of the multi-bit access and the single-bit access and executes the read operation or the write operation, based on an instruction from the internal controller 13-2 shown in FIG. 33.

The read/write circuit 15 comprises a read circuit and a write circuit.

The write circuit comprises a ROM 35, a selector (multiplexer) 36, write drivers/sinkers D/SA and D/S_B, a transfer gate TG, and a voltage assist driver 42.

The write drivers/sinkers D/S_A and D/S_B have a function of urging one of a first write current and a second write current in mutually opposite directions to be generated in, for example, the conductive line L_{SOT} shown in FIGS. 35 to 37.

The first write current is a current for, for example, writing 0 to the storage elements MTJ₁ to MTJ₈ shown in FIGS. 35 to 37, i.e., setting a relationship between the magnetization directions of the first magnetic layer 22 and the second magnetic layer 23 of the storage elements MTJ₁ to MTJ₈ shown in FIGS. 35 to 37 to be in a parallel state, by the spin orbit coupling or the Rashba effect.

The second write current is a current for, for example, writing 1 to the storage elements MTJ₁ to MTJ₈ shown in FIGS. 35 to 37, i.e., setting the relationship between the magnetization directions of the first magnetic layer 22 and the second magnetic layer 23 of the storage elements MTJ₁ to MTJ₈ shown in FIGS. 35 to 37 to be in an antiparallel state, by the spin orbit coupling or the Rashba effect.

The voltage assist driver 42 has a function of applying a voltage for facilitating the write operation to the storage elements MTJ₁ to MTJ₈ in the 0/1-write operation using the first and second write currents.

For example, when the voltage assist driver 42 applies an assist potential V_{dd}_{_}_{W2} to, for example, LBLⱼ shown in FIGS. 35 to 37, a voltage which destabilizes the magnetization direction of the first magnetic layer (storage layer) 22 is selectively generated depending on turning on/off the transistors T₁ to T₈.

The read circuit comprises a sense circuit 45 and a shift register 46.

The read driver 44 has a function of applying a select potential V_{dd}_{_}ᵣ for urging the read current to be generated to, for example, the conductive line LBLⱼ shown in FIGS. 35 to 37.

For example, when the read driver 44 applies the select potential V_{dd}_{_}ᵣ to, for example, LBLⱼ shown in FIGS. 35 to 37, the read driver 44 can urge the read current to selectively flow to the storage elements MTJ₁ to MTJ₈ depending on turning on/off the transistors T₁ to T₈.

One sense circuit 45 is disposed in, for example, one read/write circuit 15. In other words, only one sense circuit 45 is disposed in one block (memory core) BK_k.

The sense circuit 45 comprises, for example, a sense amplifier SAₙ, a clamp transistor (for example, N-channel FET) Q_{clamp}, an equalizing transistor (for example, N-channel FET) Q_{equ}, and a reset transistor (for example, N-channel FET) Qᵣₛₜ as shown in FIG. 17.

The sense circuit 45 is not explained here since the circuit has been explained in the first example of the SOT MRAM.

Next, an example of the read operation and an example of the write operation using the word line decoder/driver 17 shown in FIG. 38 and the read/write circuit 15 shown in FIG. 39 will be explained.

*Write Operation

[Multi-Bit Access]

When the internal controller 13-2 shown in FIG. 33 receives, for example, the write command CMD of the sequential access, the internal controller 13-2 controls the write operation using the multi-bit access. The internal controller 13-2 executes the write operation using the multi-bit access by the first write operation and the second write operation.

The first write operation is an operation of writing the same data (for example, 0) at multi-bits (for example, 8 bits) which are the interests of write.

First, the write enable signal WE becomes 1 and the output signal of the OR circuit 31 becomes 1 in the word line decoder/driver 17 shown in FIG. 38. For example, if all the bits of the row address signal A_{row} are 1 (11 . . . 11), all the bits of the row address signal A_{rowi} become 1 and the output signal of the AND circuit 32ᵢ becomes 1. In this case, the drive circuit 34ᵢ activates the conductive line SWLᵢ.

In addition, the internal controller 13-2 shown in FIG. 33 sets, for example, the control signal WE1/2 at 0. The control signal WE1/2 is a signal for selecting one of the first write operation and the second write operation and, for example, when the control signal WE1/2 is 0, the first write operation is selected.

In other words, the selector 39 selects the ROM 37 and outputs all 1 (11111111) as the ROM data. In addition, the internal controller 13-2 shown in FIG. 33 sets the value of the mask register 40 at all 1 (11111111) by using, for example, the control signal Wₛₑₗ, at the multi-bit access.

Therefore, when an output signal of the AND circuit 32i is 1, all the AND circuits 32ᵢ₁ to 32ᵢ₈ output 1 as the output signals. In this case, the drivers 33ᵢ₁ to 33ᵢ₈ activate the conductive lines WLᵢ₁ to WLᵢ₈.

In contrast, the selector 36 selects and outputs 0 from the ROM 35 as the ROM data, in the read/write circuit 15 shown in FIG. 39. Therefore, the write driver/sinker D/S_A outputs, for example, the drive potential V_{dd}_{_}_{W1} as the write pulse signal and the write driver/sinker D/S_B outputs, for example, the ground potential Vₛₛ.

In addition, in the write operation, the transfer gate TG is on since the control signal WEₙ becomes active (high level).

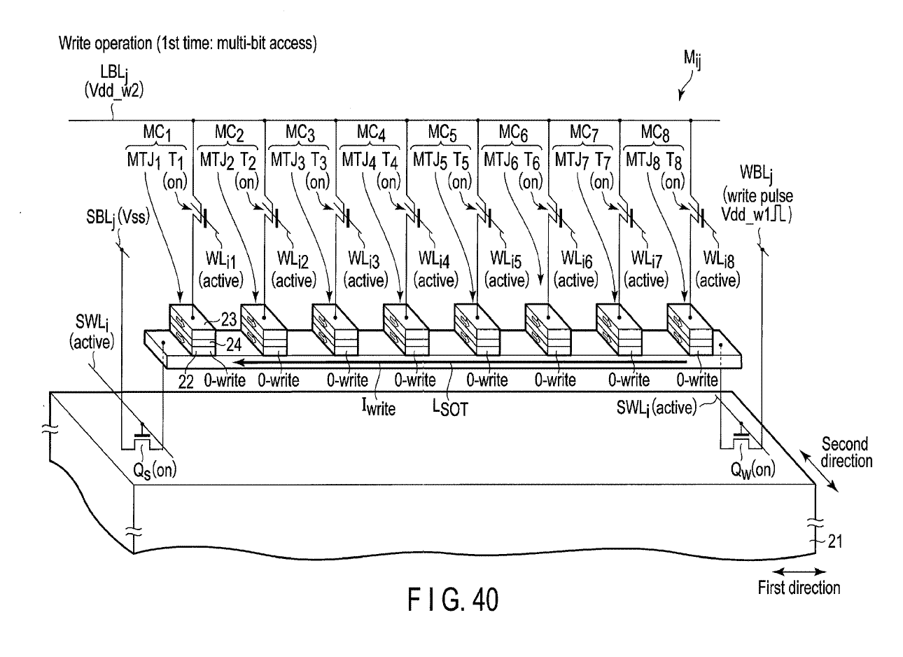

Therefore, the write pulse signal is applied to the conductive line WBL via the transfer gate TG and the ground potential V₅₅ is applied to the conductive line SBL via the transfer gate TG. At this time, if the column selected by the column selector 16 shown in FIG. 33 is assumed to be CoLⱼ, the write current (first write current) I_{write} flows from the conductive line WBLⱼ to the conductive line SBLⱼ, i.e., from the right side to the left side in the conductive line L_{SOT}, as shown in, for example, FIG. 40.

In addition, in the read/write circuit 15 shown in FIG. 39, the driver 42 applies the assist potential V_{dd}_{_}_{W2} to the conductive line LBL since the control signal φWE becomes active (1).

In the first write operation, all the transistors T₁ to T₈ are on since all the conductive lines WLᵢ₁ to WLᵢ₈ are activated as shown in, for example, FIG. 40. This means that the write current (first write current) I_{write} flows in a state in which the assist potential V_{dd}_{_}_{W2} is applied to all the storage elements MTJ₁ to MTJ₈.

As a result, the same data is written at all the multi-bits (for example, 8 bits) that are the interests of write, in the first write operation. However, it is assumed that 0 is written, i.e., all the storage elements MTJ₁ to MTJ₈ become in a parallel state in the first write operation.

The second write operation is an operation of urging the same data (for example, 0) written at multi-bits (for example, 8 bits) which are the interests of write, to be held (for example, if the write data is 0) or to be changed from 0 to 1 (for example, if the write data is 1) in accordance with the write data.

First, the internal controller 13-2 shown in FIG. 33 sets, for example, the control signal WE1/2 at 1. For example, when the control signal WE1/2 is 1, the second write operation is selected.

In this case, the selector 39 selects the data register 38 and outputs the write data (for example, 01011100) stored in the data register 38, in the word line decoder/driver 17 shown in FIG. 38. The write data is preliminarily stored in the data register 38 before the second write operation is executed. In addition, the internal controller 13-2 shown in FIG. 33 sets the value of the mask register 40 at all 1 (11111111) by using, for example, the control signal Wₛₑₗ, at the multi-bit access.

The AND circuits 32ᵢ₁ to 32ᵢ₈ therefore output the output signal (for example, 01011100) corresponding to the write data. At this time, for example, the drivers 33ᵢ₁ to 33₁₈ activate the corresponding conductive lines WLᵢ₁ to WLᵢ₈ when the write data is 1 or deactivate the corresponding conductive lines WLᵢ₁ to WLᵢ₈ when the write data is 0.

In addition, the selector 36 selects and outputs 1 from the ROM 35 as the ROM data, in the read/write circuit 15 shown in FIG. 39. Therefore, the write driver/sinker D/S_B outputs, for example, the drive potential V_{dd}_{_}_{W1} as the write pulse signal and the write driver/sinker D/S_A outputs, for example, the ground potential Vₛₛ.

The write pulse signal is applied to the conductive line SBL via the transfer gate TG and the ground potential Vₛₛ is applied to the conductive line WBL via the transfer gate TG. In addition, the driver 42 applies the assist potential V_{dd}_{_}_{W2} to the conductive line LBL since the control signal φ_{WE} becomes active (1).

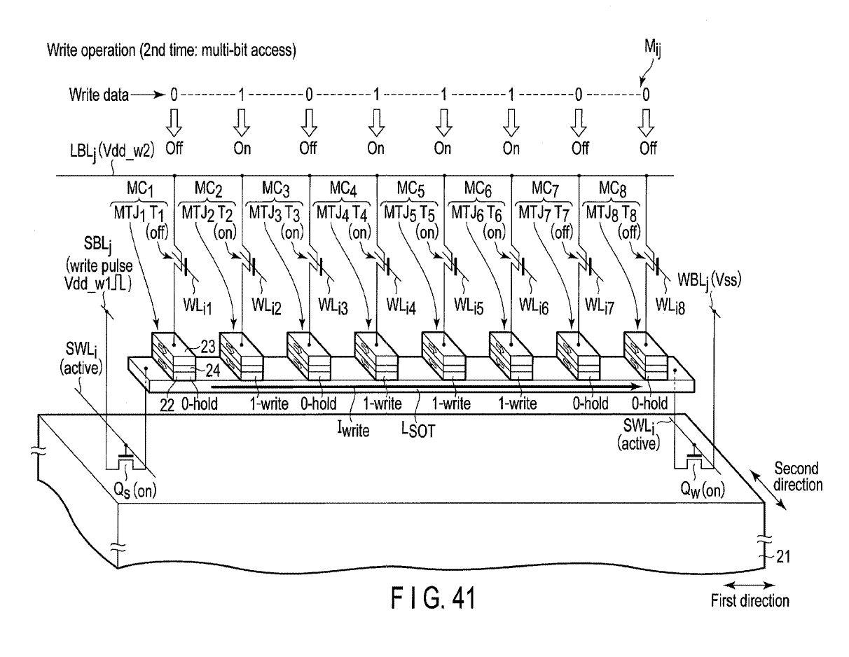

At this time, if the column selected by the column selector 16 shown in FIG. 33 is assumed to be CoLⱼ, the write current (second write current) I_{write} flows from the conductive line SBLⱼ to the conductive line WBLⱼ, i.e., from the left side to the right side in the conductive line L_{SOT}, as shown in, for example, FIG. 41.

In other words, for example, if the write data is 01011100, the transistors T₁, T₃, T₇, and T₈ become OFF and the transistors T₂, T₄, T₅, and T₆ become ON, as shown in FIG. 41. In addition, the write current (second write current) I_{write} flows from the conductive line SBLⱼ to the conductive line WBLⱼ in a state in which the assist potential V_{dd}_{_}_{W2} is applied to the storage elements MTJ₂, MTJ₄, MTJ₅, and MTJ₆.

As a result, 0 is held, i.e., 0 is written as the data of the storage elements MTJ₁, MTJ₃, MTJ₇ and MTJ₈, of the multi-bits (for example, 8 bits) which are the interests of write, in the second write operation. In addition, 0 is changed to 1, i.e., 1 is written as the data of the storage elements MTJ₂, MTJ₄, MTJ₅ and MTJ₆, of the multi-bits (for example, 8 bits) which are the interests of write.

However, it is assumed that 1 is selectively written to the storage elements MTJ₁ to MTJ₈, i.e., the state of the storage elements MTJ₁ to MTJ₈ is selectively changed from the parallel state to the antiparallel state, in the second write operation.

[Single-Bit Access]

When the internal controller 13-2 shown in FIG. 33 receives, for example, the write command CMD of the random access, the internal controller 13-2 controls the write operation using the single-bit access. The internal controller 13-2 executes the write operation using the single-bit access by the first write operation and the second write operation.

The first write operation is an operation of writing predetermined data (for example, 0) at the single bit which is the interest of write.

First, the output signal of the OR circuit 31 becomes 1 in the word line decoder/driver 17 shown in FIG. 38. For example, if all the bits of the row address signal A_{row} are 1 (11 . . . 11), the output signal of the AND circuit 32i becomes 1. The conductive lines SWLᵢ is therefore activated by the driver 34ᵢ.

Next, the internal controller 13-2 shown in FIG. 33 sets, for example, the control signal WE1/2 at 0. For example, when the control signal WE1/2 is 0, the first write operation is selected.

In this case, the selector 39 selects the ROM 37 and outputs all 1 (11111111) as the ROM data, in the word line decoder/driver 17 shown in FIG. 38. In addition, the internal controller 13-2 shown in FIG. 33 sets selected one bit, of eight bits stored in the mask register 40, at 1 by using, for example, the control signal Wₛₑₗ, at the single-bit access.

For example, when the storage element MTJ₄ is an interest of write, 1 bit corresponding to the storage element MTJ₄, of 8 bits stored in the mask register 40, is set at 1. In this case, 8 bits stored in the mask register 40 becomes, for example, 00010000.

Therefore, the AND circuit 32ᵢ₄, of the AND circuits 32ᵢ₁ to 32ᵢ₈, outputs 1 as the output signal and the remaining AND circuits 32ᵢ₁ to 32ᵢ₃ and 32ᵢ₅ to 32ᵢ₈ output 0 as the output signals. At this time, the driver 33ᵢ₄, of the drivers 33ᵢ₁ to 33ᵢ₈, activate the conductive line WLᵢ₄ and the remaining drivers 33₁₁ to 33ᵢ₃ and 33ᵢ₅ to 33ᵢ₈ deactivate the conductive lines WLᵢ₁ to WLᵢ₃ and WLᵢ₅ to WLᵢ₈.

In addition, the selector 36 selects and outputs 0 from the ROM 35 as the ROM data, in the read/write circuit 15 shown in FIG. 39. Therefore, the write driver/sinker D/S_A outputs, for example, the drive potential V_{dd}_{_}_{W1} as the write pulse signal and the write driver/sinker D/S_B outputs, for example, the ground potential Vₛₛ.

The write pulse signal is applied to the conductive line WBL via the transfer gate TG and the ground potential Vₛₛ is applied to the conductive line SBL via the transfer gate TG. In addition, the driver 42 applies the assist potential V_{dd}_{_}_{W2} to the conductive line LBL since the control signal φ_{WE} becomes active (1).

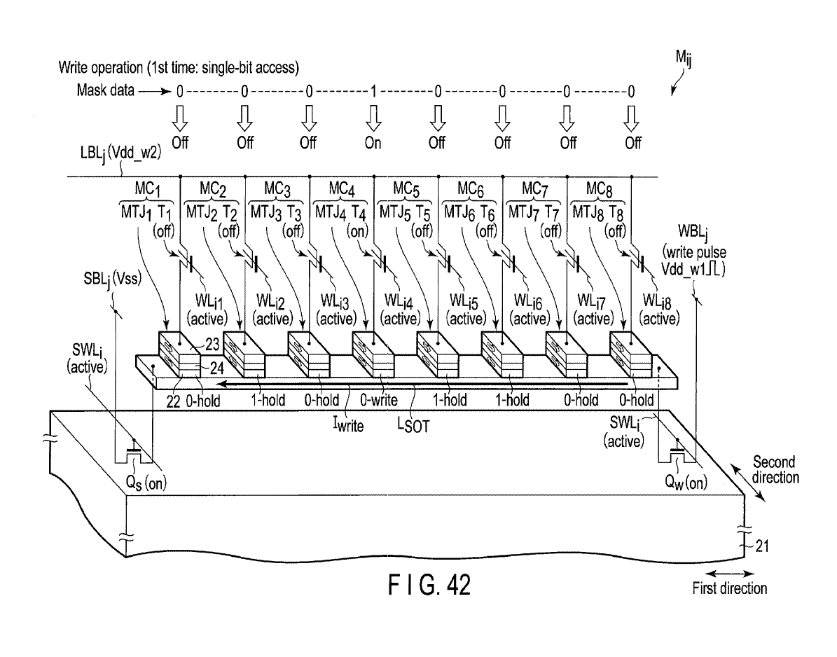

At this time, if the column selected by the column selector 16 shown in FIG. 33 is assumed to be CoLⱼ, the write current (first write current) I_{write} flows from the conductive line WBLⱼ to the conductive line SBLⱼ, i.e., from the right side to the left side in the conductive line L_{SOT}, as shown in, for example, FIG. 42.

In other words, for example, the write current (first write current) I_{write} flows from the conductive line WBLⱼ to the conductive line SBLⱼ in a state in which the assist potential V_{dd}_{_}_{W2} is applied to the storage element MTJ₄ and the assist potential V_{dd}_{_}_{W2} is not applied to the storage elements MTJ₁ to MTJ₃ and MTJ₅ to MTJ₈, as shown in FIG. 42.

As a result, the single bit which is the interest of write, for example, predetermined data (for example, 0) is written to the storage element MTJ₄, in the first write operation.

In addition, the already written data is held in remaining seven bits that are not the interests of write, for example, the storage elements MTJ₁ to MTJ₃ and MTJ₅ to MTJ₈, by the above mask processing. In other words, the data in the storage elements MTJ₁ to MTJ₃ and MTJ₅ to MTJ₈ is not changed to 0, but the data in the storage elements MTJ₁ to MTJ₃ and MTJ₅ to MTJ₈ is protected, in the first write operation.

The second write operation is an operation of urging the predetermined data (for example, 0) written at the single bit which is the interest of write, to be held (for example, if the write data is 0) or to be changed from 0 to 1 (for example, if the write data is 1) in accordance with the write data.

First, the conductive lines WLᵢ₄ and SWLᵢ are held in the activated state in the word line decoder/driver 17 shown in FIG. 38.

Next, the internal controller 13-2 shown in FIG. 33 sets, for example, the control signal WE1/2 at 1. For example, when the control signal WE1/2 is 1, the second write operation is selected.

In this case, the selector 36 selects and outputs 1 from the ROM 35 as the ROM data, in the read/write circuit 15 shown in FIG. 39. Therefore, the write driver/sinker D/S_B outputs, for example, the drive potential V_{dd}_{_}_{w1} as the write pulse signal and the write driver/sinker D/S_A outputs, for example, the ground potential Vₛₛ.

The write pulse signal is applied to the conductive line SBL via the transfer gate TG and the ground potential Vₛₛ is applied to the conductive line WBL via the transfer gate TG. In addition, the driver 42 applies the assist potential V_{dd}_{_}_{W2} to the conductive line LBL since the control signal φ_{WE} becomes active (1).

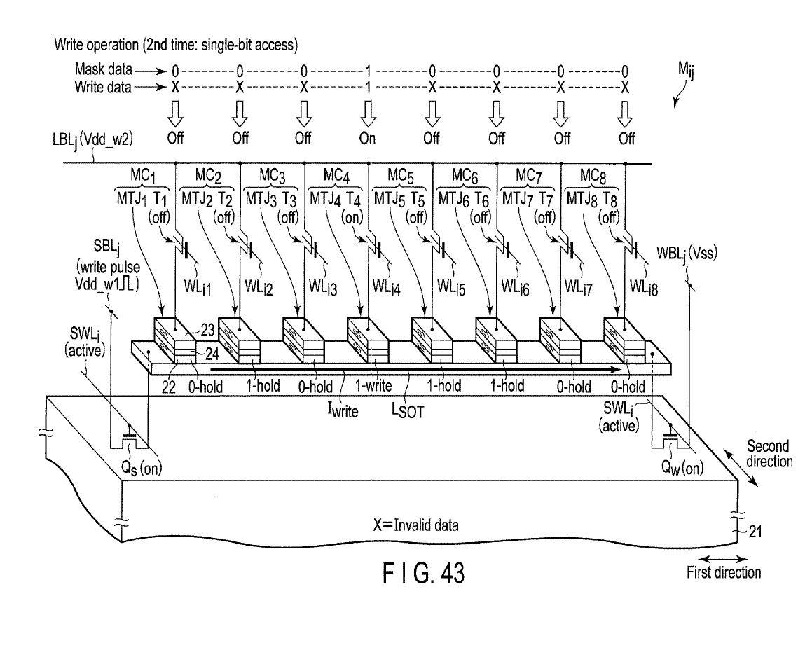

At this time, if the column selected by the column selector 16 shown in FIG. 33 is assumed to be CoLⱼ, the write current (second write current) I_{write} flows from the conductive line SBLⱼ to the conductive line WBLⱼ, i.e., from the left side to the right side in the conductive line L_{SOT}, as shown in, for example, FIG. 43.

In addition, the selector 39 outputs the write data (for example, xxx1xxxx) stored in the data register 38, in the word line decoder/driver 17 shown in FIG. 38. In this example, x represents invalid data. The write data is preliminarily stored in the data register 38 before the second write operation is executed. In addition, the internal controller 13-2 shown in FIG. 33 sets selected one bit, of eight bits stored in the mask register 40, at 1 by using, for example, the control signal Wₛₑₗ, at the single-bit access.

For example, when the storage element MTJ₄ is an interest of write in the first write operation, 1 bit corresponding to the storage element MTJ₄, of 8 bits stored in the mask register 40, is set at 1 in the second write operation, too. In other words, 8 bits stored in the mask register 40 becomes, for example, 00010000.

The AND circuit 32ᵢ₄, of the AND circuits 32ᵢ₁ to 32ᵢ₈, therefore outputs the output signal (for example, 1) corresponding to the write data. At this time, for example, the driver 33ᵢ₄ activates the conductive line WLᵢ₄ when the write data is 1 or deactivates the conductive line WLᵢ₄ when the write data is 0.

In addition, the AND circuits 32ᵢ₁ to 32ᵢ₃ and 32ᵢ₅ to 32ᵢ₈, of the AND circuits 32ᵢ₁ to 32ᵢ₈, output, for example, 0. At this time, the drivers 33ᵢ₁ to 33₁₃ and 33₁₅ to 33ᵢ₈ deactivate, for example, the conductive lines WLᵢ₁ to WLᵢ₃ and WLᵢ₅ to WLᵢ₈.

In other words, for example, when the write data is xxx1xxxx and the mask data is 00010000, the write current (second write current) I_{write} flows from the conductive line SBLⱼ to the conductive line WBLⱼ in a state in which the assist potential V_{dd}_{_}_{W2} is applied to the storage element MTJ₄ and the assist potential V_{dd}_{_}_{W2} is not applied to the storage elements MTJ₁ to MTJ₃ and MTJ₅ to MTJ₈, as shown in FIG. 43.

As a result, the predetermined data (for example, 0) is changed to 1, i.e., 1 is written as the single bit which is the interest of write, for example, the data of the storage element MTJ₄, in the second write operation. In contrast, when the write data is 0, the predetermined data (for example, 0) is held, i.e., 0 is written as the data of the storage elements MTJ₄.

In addition, the already written data is held in remaining seven bits that are not the interests of write, for example, the storage elements MTJ₁ to MTJ₃ and MTJ₅ to MTJ₈, by the above mask processing. In other words, the data in the storage elements MTJ₁ to MTJ₃ and MTJ₅ to MTJ₈ is not changed to 1, but the data in the storage elements MTJ₁ to MTJ₃ and MTJ₅ to MTJ₈ is protected, in the second write operation, too.

*Read Operation

[Multi-Bit Access]

When the internal controller 13-2 shown in FIG. 7 receives, for example, the read command CMD of the sequential access, the internal controller 13-2 controls the read operation using the multi-bit access.

First, the read enable signal RE becomes 1 and the output signal of the OR circuit 31 becomes 1 in the word line decoder/driver 17 shown in FIG. 38. For example, if all the bits of the row address signal A_{row} are 1 (11 . . . 11), the output signal of the AND circuit 32ᵢ becomes 1. The conductive lines SWLᵢ is therefore activated by the driver 34ᵢ.

Next, the internal controller 13-2 shown in FIG. 7 sets one bit of eight bits stored in the shift register 43 to be 1 sequentially by using, for example, the control signal Rₛₑₗ. In this case, the drivers 33′ᵢ₁ to 33′ᵢ₈ sequentially activate the conductive lines WLᵢ₁ to WLᵢ₈.

For example, the conductive lines WLᵢ₁ to WLᵢ₈ are activated one by one and seven conductive lines other than the activated conductive line WL_{id} (d is one of 1 to 8) are deactivated. In addition, φᵣₛₜ in FIG. 17 becomes active and the conductive line SBL is set at the ground potential Vₛₛ.

In addition, in the read/write circuit 15 shown in FIG. 39, the driver 44 applies the select potential V_{dd}_{_}ᵣ to the conductive line LBL since the control signal φ_{RE} becomes active (1).

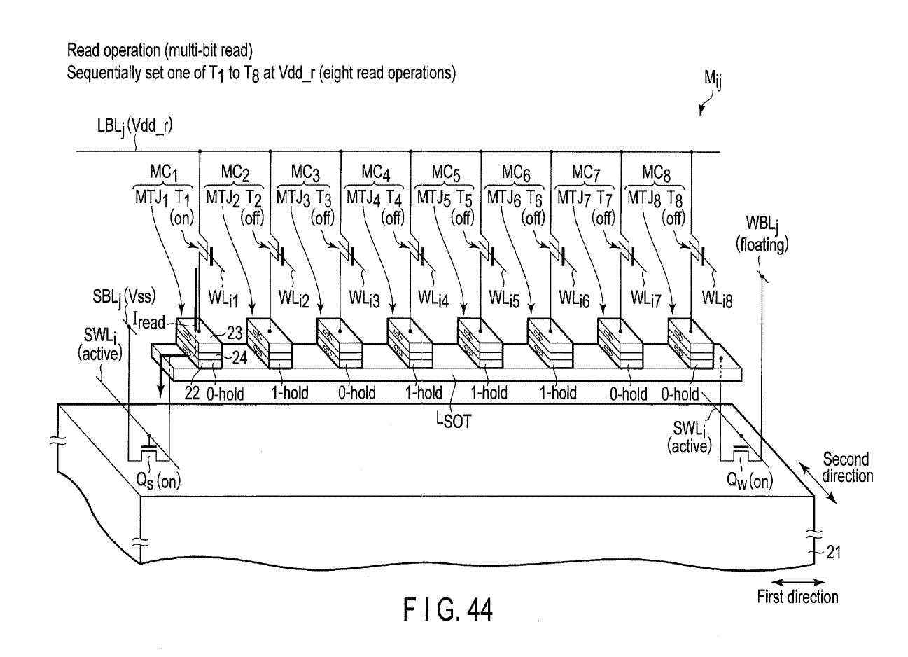

In this case, for example, if the transistor T₁ in the memory cell MC₁ is turned on, the read current I_{read} flows from the conductive line LBLⱼ to the conductive line L_{SOT} via the storage element MTJ₁, as shown in FIG. 44. The data of the storage element MTJ₁ is thereby stored in the shift register 46 via the sense circuit 45 shown in FIG. 39.

Similarly to this, the data of the storage elements MTJ₂ to MTJ₈ is sequentially stored in the shift register 46 via the sense circuit 45 shown in FIG. 39 by sequentially setting the transistors T₂ to T₈ to be turned on.

As a result, the multi-bits (for example, 8 bits) that are the interests of sequential access are stored in the shift register 46 as the read data (for example, 01011100), by eight read operations. The multi-bits are wholly transferred to the interface 13-2 shown in FIG. 33 as the read data DA.

[Single-Bit Access]

When the internal controller 13-2 shown in FIG. 7 receives, for example, the read command CMD of the random access, the internal controller 13-2 controls the read operation using the single-bit access.

First, the read enable signal RE becomes 1 and the output signal of the OR circuit 31 becomes 1 in the word line decoder/driver 17 shown in FIG. 38. For example, if all the bits of the row address signal A_{row} are 1 (11 . . . 11), the output signal of the AND circuit 32i becomes 1. The conductive lines SWLᵢ is therefore activated by the driver 34ᵢ.

Next, the internal controller 13-2 shown in FIG. 7 sets one bit which is the interest of read, of eight bits stored in the shift register 43 to be 1 by using, for example, the control signal Rₛₑₗ. For example, if the storage element which is the interest of read is MTJ₄, the internal controller 13-2 shown in FIG. 7 controls the shift register 43 such that eights stored in the shift register 43 become 00010000.

In this case, the driver 33′ᵢ₄, of the drivers 33′ᵢ₁ to 33′₁₋₈, activate the conductive line WLᵢ₄ and the remaining seven drivers 33′ᵢ₁ to 33′ᵢ₃ and 33′ᵢ₅ to 33′ᵢ₈ deactivate the conductive lines WLᵢ₁ to WLᵢ₈ and WLᵢ₅ to WLᵢ₈. In addition, φᵣₛₜ in FIG. 17 becomes active and the conductive line SBL is set at the ground potential Vₛₛ.

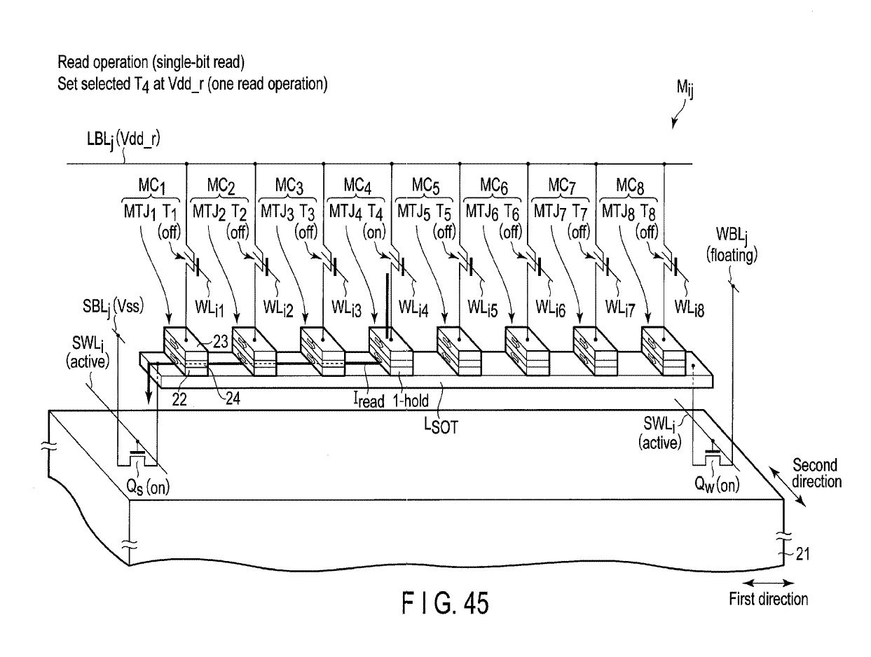

Therefore, for example, the read current I_{read} flows from the conductive line LBLⱼ to the conductive line L_{SOT} via the transistor T₄ and the storage element MTJ₄, as shown in FIG. 45. The data of the storage element MTJ₄ is thereby stored in the shift register 46 via the sense circuit 45 shown in FIG. 39. As a result, the shift register 46 stores, for example, xxx1xxxx as the read data.

The valid data (read data) stored in the shift register 46 is transferred to the interface 13-1 shown in FIG. 33 as the read data DA.

### Third Example

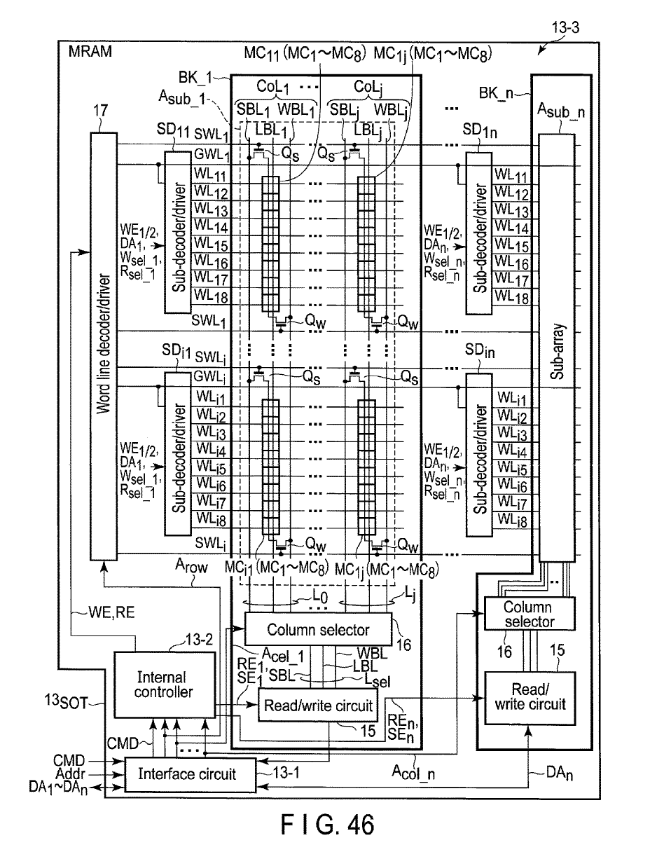

FIGS. 46 to 48 show SOT-MRAM of a third example.

This modified example is characterized by employing so called a divided word line structure in the second example, i.e., the SOT-MRAM shown in FIGS. 33 to 45.

FIG. 46 shows a third example of the SOT-MRAM.

The SOT-MRAM 13_{SOT} comprises an interface 13-1, an internal controller 13-2, a memory cell array 13-3, a word line decoder/driver 17 and sub-decoders/drivers SD₁₁ to SD₁ₙ and SDᵢ₁ to SDᵢₙ. The memory cell array 13-3 comprises n blocks (memory cores) BK_1 to BK_n. n is a natural number of 2 or larger.

A command CMD is transferred to the internal controller 13-2 via the interface 13-1. The command CMD includes, for example, a first command to instruct the sequential access and a second command to instruct the random access.

When the internal controller 13-2 receives the command CMD, the internal controller 13-2 outputs, for example, control signals WE, RE, WE1/2, Wₛₑₗ_{_}₁ to Wₛₑₗ_{_}ₙ, Rₛₑₗ_{_}₁ to Rₛₑₗ_{_}ₙ, RE₁ to REₙ, and SE₁ to SEₙ, to execute the command CMD.

An address signal Addr is transferred to the internal controller 13-2 via the interface 13-1. The address signal Addr is divided into a row address A_{row} and column addresses A_{col}_{_}₁ to A_{col}_{_}ₙ in the interface 13-1. The row address A_{row} is transferred to the word line decoder/driver 17. The column addresses A_{col}_{_}₁ to A_{col}_{_}ₙ are transferred to n blocks BK_1 to BK_n.

DA₁ to DAₙ are read data or write data transmitted or received in the read operation or the write operation. The I/O width (bit width) between the interface 13-1 and each of the blocks BK_k (k is one of 1 to n) is N bits at the N-bit access or 1 bit at the single-bit access as explained above.

Each of the blocks BK_k includes a sub-array A_{sub}_{_}ₖ, a read/write circuit 15, and a column selector 16.

The column selector 16 selects one of j columns (j is a natural number of 2 or larger) CoL₁ to CoLⱼ and connects the selected column CoLₚ (p is one of 1 of j) to the read/write circuit 15. For example, if the selected column CoLₚ is CoL₁, conductive lines LBL₁, SBL₁ and WBLⱼ are electrically connected to the read/write circuit 15 via the column selector 16, as conductive lines LBL, SBL and WBL.

The sub-array A_{sub}_{_}ₖ comprises, for example, memory cells M₁₁ (MC₁ to MC₈) to M₁ⱼ (MC₁ to MC₈), and Mᵢ₁ (MC₁ to MC₈) to Mᵢⱼ (MC₁ to MC₈). The sub-array A_{sub}_{_}ₖ is not explained here since the sub-array is the same as the sub-array A_{sub}_{_}₁ in the second example, for example, FIG. 34A or 34B.

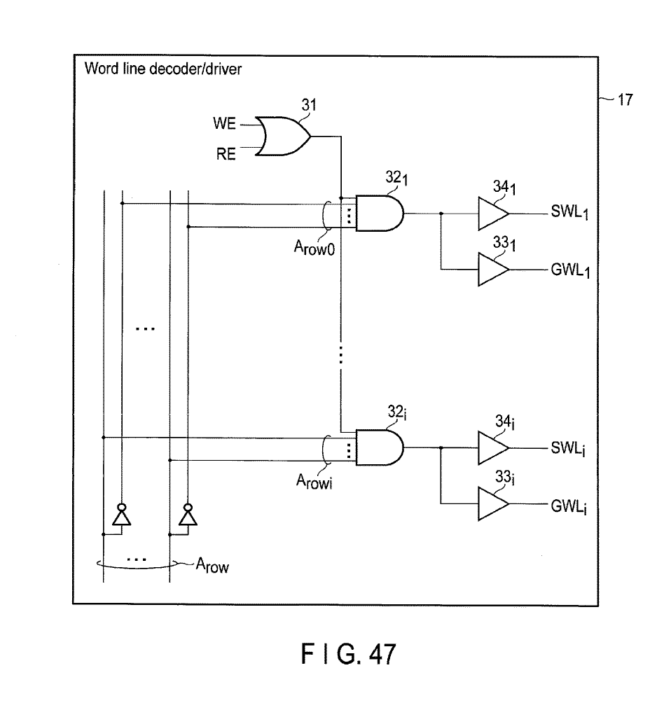

FIG. 47 shows an example of the word line decoder/driver shown in FIG. 46.

The word line decoder/driver 17 has a function of activating or deactivating conductive lines SWL₁ to SWLᵢ and global conductive lines GWL₁ to GWLᵢ in the read operation or the write operation.

An OR circuit 31 and AND circuits 32₁ to 32ᵢ are decoder circuits.

In the read operation, for example, a read enable signal RE from the internal controller 13-2 shown in FIG. 46 becomes active (1). In the write operation, a write enable signal WE from the internal controller 13-2 shown in FIG. 46 becomes active (1).

The row address signal A_{row} has, for example, R bits (R is a natural number of 2 or more) and has a relationship i (number of rows)=2^{R}.

In the read operation or the write operation, all bits (R bits) of one of the row address signals A_{row1} to A_{rowi} become 1 when the row address signal A_{row} is input to the word line decoder/driver 17.

For example, if the row address signal A_{row} is 00 . . . 00 (all 0), the output signal of the AND circuit 321 becomes 1 since all the bits of the row address signal A_{row1} become 1. In this case, the drive circuit 331 sets the global conductive line GWL₁ to be active and the drive circuit 34₁ sets the conductive line SWL₁ to be active.

In addition, if the row address signal A_{row} is 11 . . . 11 (all 1), the output signal of the AND circuit 32ᵢ becomes 1 since all the bits of the row address signal A_{rowi} become 1. In this case, the drive circuit 33ᵢ sets the global conductive line GWLᵢ to be active and the drive circuit 34ᵢ sets the conductive line SWLᵢ to be active.

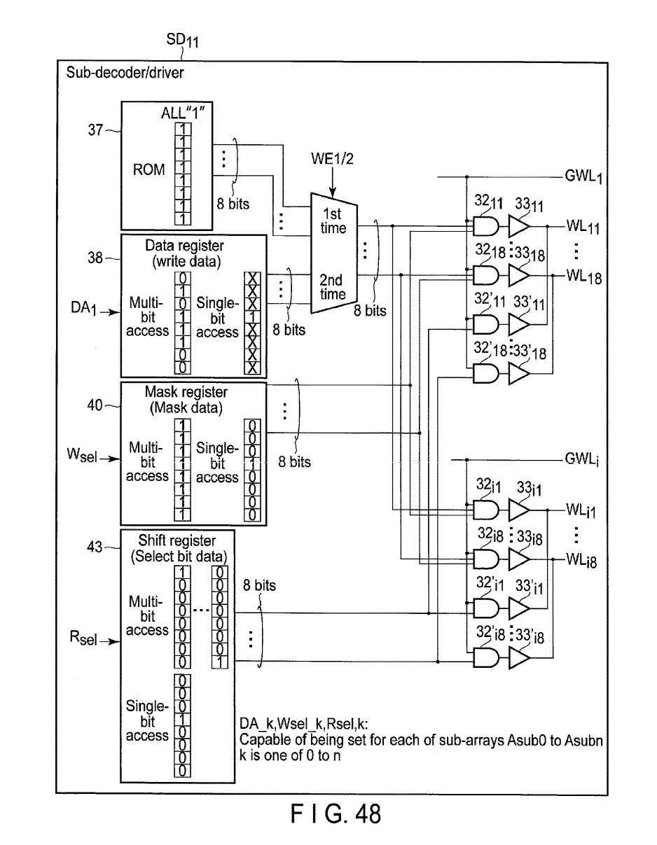

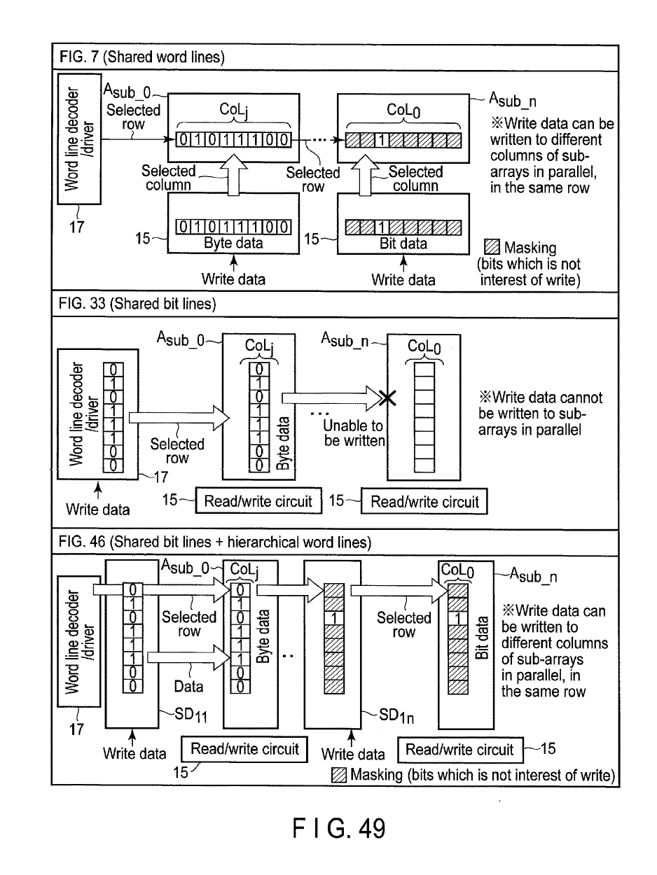

FIG. 48 shows an example of the sub-decoder/driver shown in FIG. 46.

The sub-decoder/driver SD₁₁ has a function of activating or deactivating the conductive lines WL₁₁ to WL₁₈ and WLᵢ₁ to WLᵢ₈ in the read operation or the write operation.

A ROM 37, a data register 38, a selector (multiplexer) 39 and a mask register 40 are elements used in the write operation. The ROM 37, the data register 38, the selector (multiplexer) 39 and the mask register 40 control setting the conductive lines WL₁₁ to WL₁₈ and WLᵢ₁ to WLᵢ₈ to be active/nonactive, in the row selected by the row address signal A_{row}.

A shift register 43 is an element used in the read operation. The shift register 43 controls setting the conductive lines WL₁₁ to WL₁₈ and WLᵢ₁ to WLᵢ₈ to be active/nonactive, in the row selected by the row address signal A_{row}.

Drive circuits 33₁₁ to 33₁₈, 33₁₁ to 33ᵢ₈, 33′₁₁ to 33′₁₈, and 33′ᵢ₁ to 33′ᵢ₈ correspond to AND circuits 32₁₁ to 32₁₈, 32ᵢ₁ to 32ᵢ₈, 32′₁₁ to 32′₁₈, and 32′ᵢ₁ to 32′ᵢ₈, respectively.

When an output signal of the AND circuit 32₁ shown in FIG. 47 is active (1) and the global conductive line GWL₁ is activated, output signals of the AND circuits 32₁₁ to 32₁₈ and 32′₁₁ to 32′₁₈ can be active. In addition, when an output signal of the AND circuit 32ᵢ shown in FIG. 47 is active (1) and the global conductive line GWLᵢ is activated, output signals of the AND circuits 32ᵢ₁ to 32ᵢ₈ and 32′ᵢ₁ to 32′ᵢ₈ can be active.

The read/write circuit 15 shown in FIG. 46 is not explained here since the circuit is the same as the read/write circuit 15 shown in FIG. 39 explained in the second example.

In addition, an example of the read operation and an example of the write operation using the word line decoder/driver 17 shown in FIG. 47, the sub-decoder/driver SD₁₁ shown in FIG. 48 and the read/write circuit 15 shown in FIG. 39 are not explained here since the examples are the same as the example of the read operation and the example of the write operation explained in the second example.

In the second example (shared bit line architecture), the write data cannot be written parallel to the sub-arrays A_{sub}_{_}₁ to A_{sub}_{_}ₙ. In contrast, in the third example (shared bit line architecture and divided word line structure), the write data can be written parallel for the sub-arrays A_{sub}_{_}₁ to A_{sub}_{_}ₙ.

FIG. 49 shows a comparison among the first example (FIG. 7), the second example (FIG. 33) and the third example (FIG. 46).

In the first example (shared word line architecture) shown in FIG. 7, the write data is written to the memory cells MC₁ to MC₈ by, for example, controlling the electric potentials of the conductive lines LBL₁ to LBL₈ from the column side. In the first example shown in FIG. 7, the write data can be therefore written parallel to the sub-arrays A_{sub}_{_}₁ to A_{sub}_{_}ₙ.

In the sub-arrays A_{sub}_{_}₁ to A_{sub}_{_}ₙ, however, the memory cells MC₁ to MC₈ which are the interests of write are limited in the same row selected by the word line decoder/driver 17.

In contrast, in the second example (shared word line architecture) shown in FIG. 33, the write data is written to the memory cells MC₁ to MC₈ by, for example, controlling the electric potentials of the conductive lines WLᵢ₁ to WLᵢ₈ from the row side. In the second example shown in FIG. 33, the write data cannot be therefore written parallel to the sub-arrays A_{sub}_{_}₁ to A_{sub}_{_}ₙ.

It is the third example which solves the problem of the second example.

In the third example (shared bit line architecture and divided word line structure) shown in FIG. 46, the write data is written to the memory cells MC₁ to MC₈ by, for example, controlling the electric potentials of the conductive lines WLᵢ₁ to WLᵢ₈ from the row side. In the third example unlike the second example, however, for example, the sub-decoders/drivers SD₁₁ to SD₁ₙ are provided to correspond to the sub-arrays A_{sub}_{_}₁ to A_{sub}_{_}ₙ, respectively.

Therefore, the write data is written to the memory cells MC₁ to MC₈ by, for example, controlling the electric potentials of the conductive lines WLᵢ₁ to WLᵢ₈ for each of the sub-arrays A_{sub}_{_}₁ to A_{sub}_{_}ₙ by using the sub-arrays A_{sub}_{_}₁ to A_{sub}_{_}ₙ.

In other words, the write data can be written parallel to the sub-arrays A_{sub}_{_}₁ to A_{sub}_{_}ₙ in the third example shown in FIG. 46.

In the sub-arrays A_{sub}_{_}₁ to A_{sub}_{_}ₙ, however, the memory cells MC₁ to MC₈ which are the interests of write are limited in the same row selected by the word line decoder/driver 17.

(Layout)

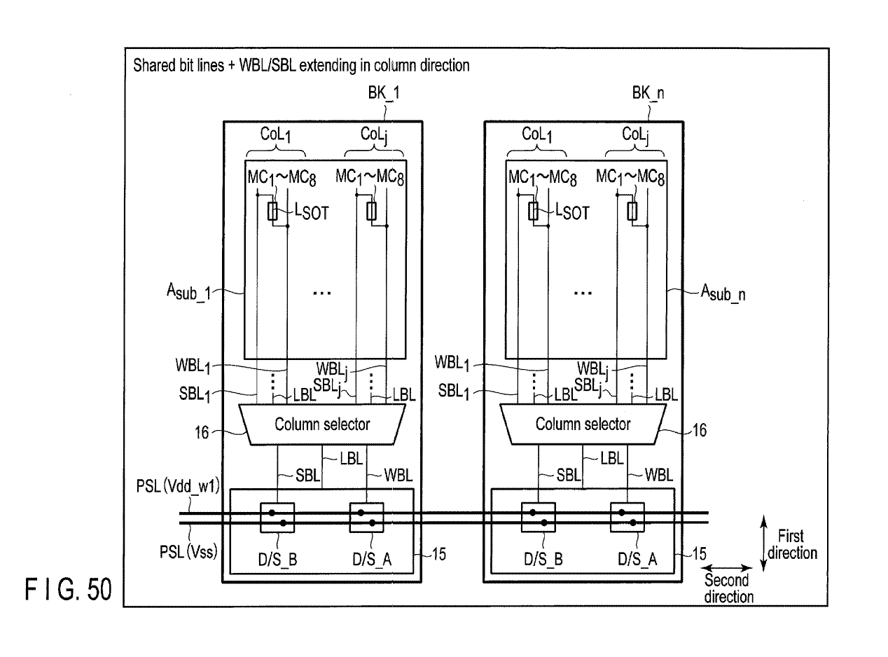

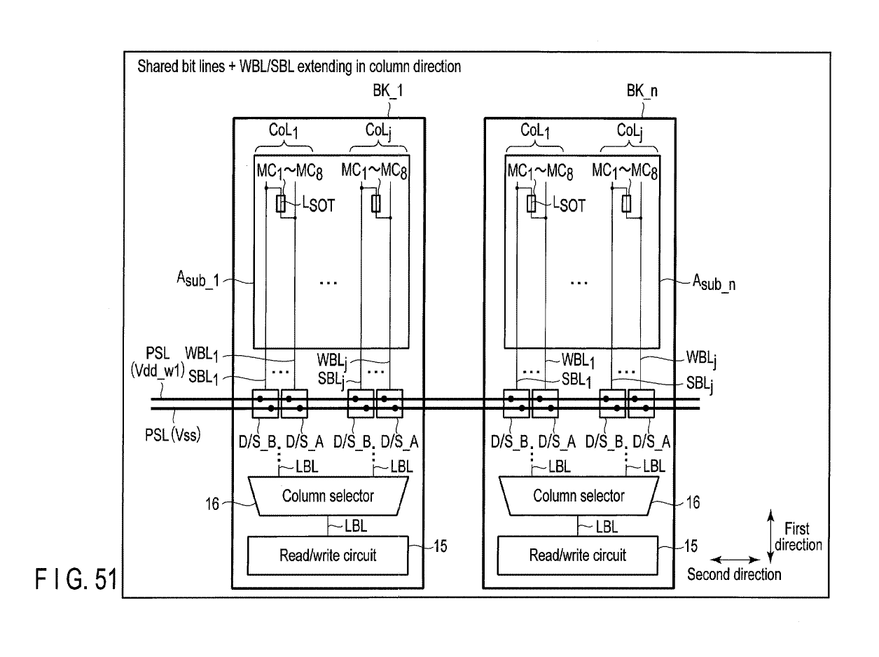

FIG. 50 is a diagram simply showing the SOT-MRAM explained with reference to FIGS. 33 to 49. FIGS. 51 to 54 show a modified example of the SOT-MRAM shown in FIG. 50. An example of the layout of the write drivers/sinkers D/S_A and D/S_B will be explained here.

The same elements as those shown in, for example, FIG. 33 or FIG. 46 are denoted by the same referential numbers in FIGS. 50 to 54 and their detailed explanations are omitted.

The SOT-MRAM shown in FIG. 50 has, for example, what is called a shared bit line architecture in which the memory cells MC₁ to MC₈ accessed parallel at the multi-bit access share one conductive line (bit line) LBL selecting the memory cells MC₁ to MC₈.

In addition, the SOT-MRAM shown in FIG. 50 has what is called a column direction extending architecture in which the conductive lines WBL₁ to WBLⱼ and SBL₁ to SBLⱼ for urging the write current to flow to the conductive line L_{SOT} shared by the memory cells MC₁ to MC₈ extend in the first direction in which the conductive line LBL₁ extends.

In this case, the write drivers/sinkers D/S_A and D/S_B are disposed in the read/write circuit 15 in each block (memory core) BK_k (k is one of 1 to n). The write drivers/sinkers D/S_A and D/S_B are shared by the columns CoL₁ to CoLⱼ.

In addition, the power lines PSL for supplying, for example, the drive potential V_{dd}_{_}_{W1} and the ground potential Vₛₛ to the write drivers/sinkers D/S_A and D/S_B are disposed above the read/write circuit 15 and extend in the second direction intersecting the first direction.

The SOT-MRAM shown in FIG. 51 has the shared bit line architecture and the column direction extending architecture, similarly to the SOT-MRAM shown in FIG. 50.

However, the write drivers/sinkers D/S_A and D/S_B are provided for each column CoLₚ (p is one of 1 to j) in the block BK_k (k is one of 1 to n). In this case, the write drivers/sinkers D/S_A and D/S_B are laid out between sub-arrays A_{sub}_{_}₁ to A_{sub}_{_}ₙ and the column selector 16.

In addition, the power lines PSL for supplying, for example, the drive potential V_{dd}_{_}_{W1} and the ground potential Vₛₛ to the write drivers/sinkers D/S_A and D/S_B are disposed above the write drivers/sinkers D/S_A and D/S_B and extend in the second direction.

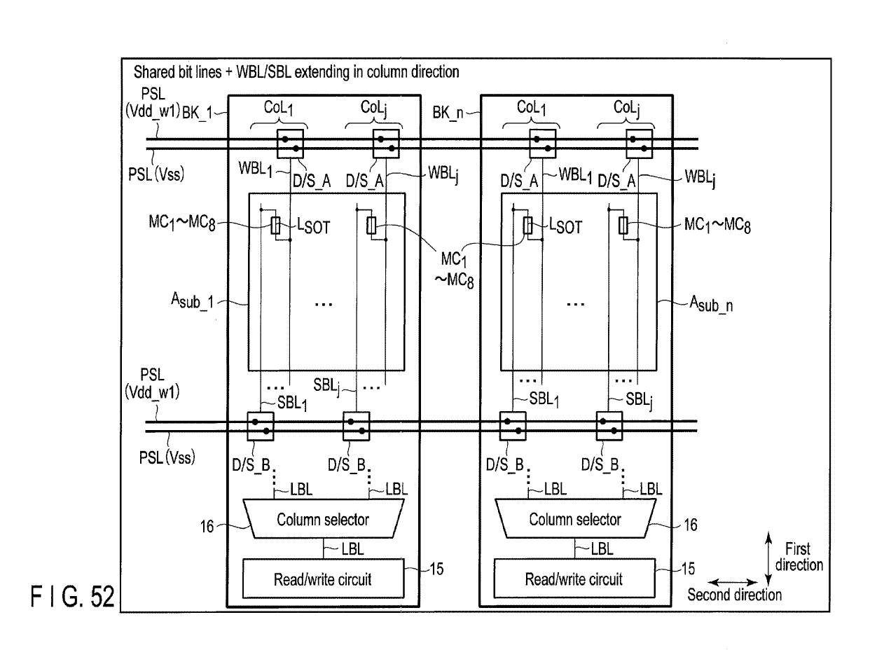

The SOT-MRAM shown in FIG. 52 has the shared bit line architecture and the column direction extending architecture, similarly to the SOT-MRAM shown in FIG. 51.

However, the example shown in FIG. 52 is different from the example shown in FIG. 51 with respect to features that the write drivers/sinkers D/S_A are laid out at one of ends (i.e., the end portion on the side where the column selectors 16 do not exist) of the sub-arrays A_{sub}_{_}₁ to A_{sub}_{_}ₙ and that the write drivers/sinkers D/S_B are laid out at the other end (i.e., the end portion on the side where the column selectors 16 exist) of the sub-arrays A_{sub}_{_}₁ to A_{sub}_{_}ₙ.

In addition, the power lines PSL for supplying, for example, the drive potential V_{dd}_{_}_{W1} and the ground potential Vₛₛ to the write drivers/sinkers D/S_A are disposed above the write drivers/sinkers D/S_A and extend in the second direction. The power lines PSL for supplying, for example, the drive potential V_{dd}_{_}_{W1} and the ground potential Vₛₛ to the write drivers/sinkers D/S_B are disposed above the write drivers/sinkers D/S_B and extend in the second direction.

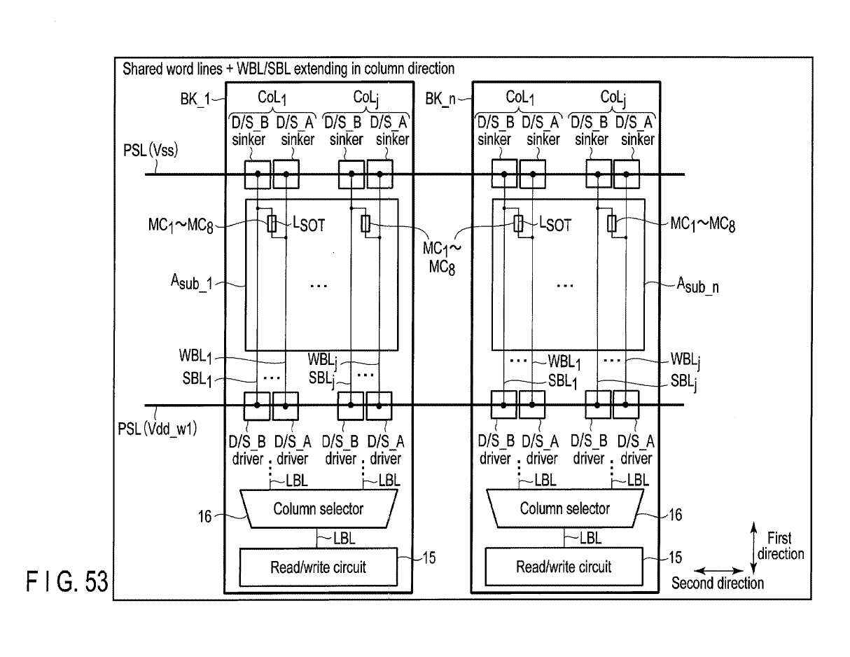

The SOT-MRAM shown in FIG. 53 has the shared bit line architecture and the column direction extending architecture, similarly to the SOT-MRAM shown in FIG. 52.

However, the example shown in FIG. 53 is different from the example shown in FIG. 52 with respect to features that the write drivers/sinkers D/S_A are divided into D/S_A drivers and D/S_A sinkers and that the write drivers/sinkers D/S_B are divided into D/S_B drivers and D/S_B sinkers.

In addition, the D/S_A sinkers and the D/S_B sinkers are laid out at one of ends (i.e., the end portion on the side where the column selectors 16 do not exist) of the sub-arrays A_{sub}_{_}₁ to A_{sub}_{_}ₙ, and the D/S_A drivers and the D/S_B drivers are laid out at the other end (i.e., the end portion on the side where the column selectors 16 exist) of the sub-arrays A_{sub}_{_}₁ to A_{sub}_{_}ₙ.

The power line PSL for supplying, for example, the ground potential Vₛₛ to the D/S_A sinkers and the D/S_B sinkers is disposed above the D/S_A sinkers and the D/S_B sinkers and extend in the second direction. The power line PSL for supplying, for example, the drive potential V_{dd}_{_}_{W1} to the D/S_A drivers and the D/S_B drivers is disposed above the D/S_A drivers and the D/S_B drivers and extend in the second direction.

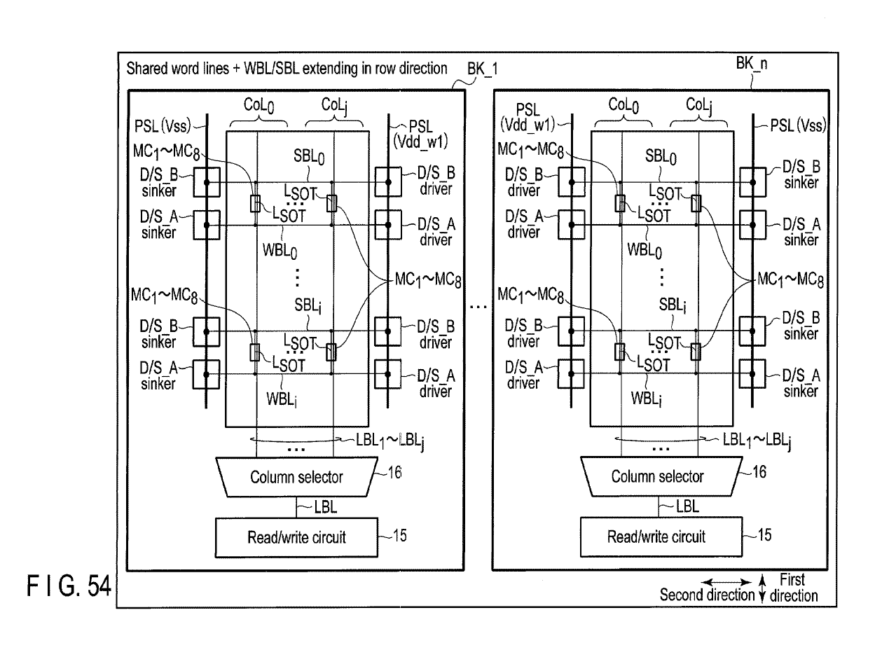

The SOT-MRAM shown in FIG. 54 has the shared bit line architecture, similarly to the SOT-MRAM shown in FIG. 53.

However, the SOT-MRAM shown in FIG. 54 has what is called a row direction extending architecture in which the conductive lines WBL₁ to WBLⱼ and SBL₁ to SBLⱼ for urging the write current to flow to the conductive line L_{SOT} shared by the memory cells MC₁ to MC₈ extend in the second direction intersecting the first direction in which the conductive lines LBL₁ to LBLⱼ extend, as compared with the example shown in FIG. 53.

In this case, the D/S_A sinkers and the D/S_B sinkers are laid out at one of ends (i.e., the end portion in the second direction) of the sub-arrays A_{sub}_{_}₁ to A_{sub}_{_}ₙ, and the D/S_A drivers and the D/S_B drivers are laid out at the other end (i.e., the end portion in the second direction) of the sub-arrays A_{sub}_{_}₁ to A_{sub}_{_}ₙ.

As shown in this figure, for example, the D/S_A sinkers and the D/S_B sinkers are laid out at one of ends (i.e., the left end portion) of the sub-arrays A_{sub}_{_}₁ to A_{sub}_{_}ₙ, and the D/S_A drivers and the D/S_B drivers are laid out at the other end (i.e., the right end portion) of the sub-arrays A_{sub}_{_}₁ to A_{sub}_{_}ₙ, in the odd-numbered block BK_k (k is 1, 3, 5, . . . )

The D/S_A sinkers and the D/S_B sinkers are laid out at one of ends (i.e., the right end portion) of the sub-arrays A_{sub}_{_}₁ to A_{sub}_{_}ₙ, and the D/S_A drivers and the D/S_B drivers are laid out at the other end (i.e., the left end portion) of the sub-arrays A_{sub}_{_}₁ to A_{sub}_{_}ₙ, in the even-numbered block BK_k (k is 2, 4, 6, . . . )

The power lines PSL for supplying, for example, the ground potential Vₛₛ to the D/S_A sinkers and the D/S_B sinkers are disposed above the D/S_A sinkers and the D/S_B sinkers and extend in the second direction. The power lines PSL for supplying, for example, the drive potential V_{dd}_{_}_{W1} to the D/S_A drivers and the D/S_B drivers are disposed above the D/S_A drivers and the D/S_B drivers and extend in the first direction.

The D/S_A drivers, the D/S_B drivers, the D/S_A sinkers, and the D/S_B sinkers shown in FIGS. 53 and 54 are not explained here since the drivers and the sinkers are the same as, for example, the D/S_A drivers, the D/S_B drivers, the D/S_A sinkers, and the D/S_B sinkers in the first example, i.e., FIGS. 29 to 32.

In the example shown in FIG. 53, of the examples shown in FIGS. 50 to 54, the write drivers/sinkers (the D/S_A driver, the D/S_B driver, the D/S_A sinker, and the D/S_B sinker) are provided for each column CoLₚ. In addition, the power line PSL for supplying Vₛₛ and the power line PSL for supplying V_{dd}_{_}_{W1} are disposed separately from each other. The example shown in FIG. 53 is therefore considered most desirable.

### CONCLUSION

According to the above embodiments, the nonvolatile MRAM which can be used in various systems can be thereby implemented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory comprising:
a first conductive line extending in a first direction, and including a first portion, a second portion, a third portion provided between the first and second portions, and a fourth portion provided between the second and third portions;
a first storage element including a first terminal and a second terminal, the first terminal being connected to the third portion;
a first transistor including a third terminal, a fourth terminal, and a first electrode controlling a first current path between the third and fourth terminals, the third terminal being connected to the second terminal;
a second storage element including a fifth terminal and a sixth terminal, the fifth terminal being connected to the fourth portion;
a second transistor including a seventh terminal, an eighth terminal, and a second electrode controlling a second current path between the seventh and eighth terminals, the seventh terminal being connected to the sixth terminal;
a second conductive line extending in the first direction and connected to the first and second electrodes;
a third conductive line extending in a second direction crossing to the first direction and connected to the fourth terminal; and
a fourth conductive line extending in the second direction and connected to the eighth terminal.

2. The memory of claim 1, further comprising:
a first circuit applying a first potential to the second conductive line to generate the first and second current paths;
a second circuit applying a second potential or a third potential different from the second potential to the third conductive line and applying the second potential or the third potential to the fourth conductive line; and
a third circuit causing a write current to flow between the first and second portions.

3. The memory of claim 1, further comprising:
a circuit selecting a first mode of accessing both the first and second storage elements or a second mode of accessing one of the first and second storage elements.

4. The memory of claim 3, wherein
the circuit comprises a register for selecting one of the first and second modes.

5. The memory of claim 1, wherein
each of the first and second transistors is a transistor provided above a substrate and having the first and second current paths extending in a direction intersecting a surface of the substrate.

6. The memory of claim 1, wherein
the first storage element comprises a first magnetic layer, a second magnetic layer, and a first nonmagnetic layer provided between the first and second magnetic layers,
the first magnetic layer is connected to the third portion,
the second storage element comprises a third magnetic layer, a fourth magnetic layer, and a second nonmagnetic layer provided between the third and fourth magnetic layers, and
the third magnetic layer is connected to the fourth portion.

7. A nonvolatile memory comprising:
a first conductive line extending in a first direction and including a first portion, a second portion, a third portion provided between the first and second portions, and a fourth portion provided between the second and third portions;
a first storage element comprising a first terminal and a second terminal, the first terminal being connected to the third portion;
a first transistor comprising a third terminal, a fourth terminal, and a first electrode controlling a first current path between the third and fourth terminals, the third terminal being connected to the second terminal;
a second storage element comprising a fifth terminal and a sixth terminal, the fifth terminal being connected to the fourth portion;
a second transistor comprising a seventh terminal, an eighth terminal, and a second electrode controlling a second current path between the seventh and eighth terminals, the seventh terminal being connected to the sixth terminal;
a second conductive line extending in a second direction intersecting the first direction and connected to the first electrode;
a third conductive line extending in the second direction and connected to the second electrode; and
a fourth conductive line extending in the first direction and connected to the fourth and eighth terminals.

8. The memory of claim 7, further comprising:
a first circuit applying a first potential to the second conductive line to generate the first current path or a second potential to the second conductive line not to generate the first current path, and applying the first potential to the third conductive line to generate the second current path or the second potential to the third conductive line not to generate the second current path;
a second circuit applying a third potential to the fourth conductive line; and
a third circuit causing a write current to flow between the first and second portions.

9. The memory of claim 7, further comprising:
a circuit selecting a first mode of accessing both the first and second storage elements or a second mode of accessing one of the first and second storage elements.

10. The memory of claim 9, wherein
the circuit comprises a register for selecting one of the first and second modes.

11. The memory of claim 7, wherein
each of the first and second transistors is a transistor provided above a substrate and having the first and second current paths extending in a direction intersecting a surface of the substrate.

12. The memory of claim 7, wherein
the first storage element comprises a first magnetic layer, a second magnetic layer, and a first nonmagnetic layer provided between the first and second magnetic layers,
the first magnetic layer is connected to the third portion,
the second storage element comprises a third magnetic layer, a fourth magnetic layer, and a second nonmagnetic layer provided between the third and fourth magnetic layers, and
the third magnetic layer is connected to the fourth portion.

13. A nonvolatile memory comprising:
a first conductive line extending in a first direction and including a first portion, a second portion, a third portion provided between the first and second portions, and a fourth portion provided between the second and third portions;
a first storage element comprising a first magnetic layer, a second magnetic layer, and a first nonmagnetic layer provided between the first and second magnetic layers, the first magnetic layer being connected to the third portion;
a first transistor comprising a first terminal, a second terminal, and a first electrode controlling a first current path between the first and second terminals, the first terminal being connected to the second magnetic layer;
a second storage element comprising a third magnetic layer, a fourth magnetic layer, and a second nonmagnetic layer provided between the third and fourth magnetic layers, the third magnetic layer being connected to the fourth portion;
a second transistor comprising a third terminal, a fourth terminal, and a second electrode controlling a second current path between the third and fourth terminals, the third terminal being connected to the fourth magnetic layer;
a second conductive line extending in the first direction and connected to the first and second electrodes;
a third conductive line extending in a second direction intersecting the first direction and connected to the second terminal; and
a fourth conductive line extending in the second direction and connected to the fourth terminal.

14. The memory of claim 13, further comprising:
a first circuit applying a first potential to the second conductive line to generate the first and second current paths;
a second circuit applying a second potential or a third potential different from the second potential to the third conductive line and applying the second potential or the third potential to the fourth conductive line; and
a third circuit causing a write current to flow between the first and second portions.

15. The memory of claim 13, further comprising:
a circuit selecting a first mode of accessing both the first and second storage elements or a second mode of accessing one of the first and second storage elements.

16. The memory of claim 15, wherein
the circuit comprises a register for selecting one of the first and second modes.

17. A nonvolatile memory comprising:
a first conductive line extending in a first direction and including a first portion, a second portion, a third portion provided between the first and second portions, and a fourth portion provided between the second and third portions;
a first storage element comprising a first magnetic layer, a second magnetic layer, and a first nonmagnetic layer provided between the first and second magnetic layers, the first magnetic layer being connected to the third portion;
a first transistor comprising a first terminal, a second terminal, and a first electrode controlling a first current path between the first and second terminals, the first terminal being connected to the second magnetic layer;
a second storage element comprising a third magnetic layer, a fourth magnetic layer, and a second nonmagnetic layer provided between the third and fourth magnetic layers, the third magnetic layer being connected to the fourth portion;
a second transistor comprising a third terminal, a fourth terminal, and a second electrode controlling a second current path between the third and fourth terminals, the third terminal being connected to the fourth magnetic layer;
a second conductive line extending in a second direction intersecting the first direction and connected to the first electrode;
a third conductive line extending in the second direction and connected to the second electrode; and
a fourth conductive line extending in the first direction and connected to the second and fourth terminals.

18. The memory of claim 17, further comprising:
a first circuit applying a first potential to the second conductive line to generate the first current path or a second potential to the second conductive line not to generate the first current path, and applying the first potential to the third conductive line to generate the second current path or the second potential to the third conductive line not to generate the second current path;
a second circuit applying a third potential to the fourth conductive line; and
a third circuit causing a write current to flow between the first and second portions.

19. The memory of claim 17, further comprising:
a circuit selecting a first mode of accessing both the first and second storage elements or a second mode of accessing one of the first and second storage elements.

20. The memory of claim 19, wherein
the circuit comprises a register for selecting one of the first and second modes.
